(19) United States
(12) Patent Application Publication
(10) Pub. No.: US 2013/0193382 A1
(43) Pub. Date: Aug. 1, 2013

(54) COMPOUNDS FOR ELECTRONIC DEVICES

(71) Applicants: Arne Buesing, Frankfurt am Main (DE); Thomas Eberle, Landau (DE); Irina Martynova, Griesheim (DE); Teresa Mujica-Fernaud, Darmstadt (DE)

(72) Inventors: Arne Buesing, Frankfurt am Main (DE); Thomas Eberle, Landau (DE); Irina Martynova, Griesheim (DE); Teresa Mujica-Fernaud, Darmstadt (DE)

(73) Assignee: MERCK PATENT GmbH, Damstadt (DE)

(21) Appl. No.: 13/879,187

(22) PCT Filed: Sep. 6, 2011
(86) PCT No.: PCT/EP2011/004653

§ 371 Date: Apr. 12, 2013

(30) Foreign Application Priority Data
Oct. 15, 2010 (DE) 10 2010 048 607.8

(51) Int. Cl. H01L 51/00

(52) U.S. Cl. CPC H01L 51/0035; H01L 51/0036
USPC 252/500; 564/426; 558/420; 546/104; 546/18; 548/440; 549/460; 549/43; 546/285; 544/294; 568/17; 568/14; 564/15; 568/36; 568/30; 556/413; 556/415; 528/422; 528/401; 528/417; 528/380; 528/423; 528/398; 528/399; 528/391; 528/38

(57) ABSTRACT

The present invention relates to compounds of the formula (I) and to the use thereof in electronic devices. The invention furthermore relates to electronic devices, preferably organic electroluminescent devices (OLEDs), comprising one or more com-pounds of the formula (I). The invention again furthermore relates to the preparation of compounds of the formula (I) and to formulations comprising one or more compounds of the formula (I).

The present invention relates to compounds of the formula (I) and to the use thereof in electronic devices. The invention furthermore relates to electronic devices, preferably organic electroluminescent devices (OLEDs), comprising one or more compounds of the formula (I). The invention again furthermore relates to the preparation of compounds of the formula (I) and to formulations comprising one or more compounds of the formula (I).

The structure of organic electroluminescent devices (OLEDs) in which organic semiconductors, such as the compounds according to the invention, are employed as functional materials is described, for example, in U.S. Pat. No. 4,539,507, U.S. Pat. No. 5,151,629, EP 0676461 and WO 98/27136.

There is generally an ongoing demand for alternative functional materials for use in the above-mentioned devices. In particular, there is a demand for functional materials which facilitate an improvement in the performance data of the organic devices, especially in the following areas:
1. There continues to be improvement potential in the efficiency of fluorescent OLEDs. This applies, in particular, to deep-blue-emitting OLEDs.
2. There is improvement potential in the operating lifetime, in particular in the case of blue-fluorescent OLEDs.
3. The operating voltage is comparatively high, in particular in the case of fluorescent OLEDs, and should therefore be reduced further in order to improve the power efficiency. This is of major importance, in particular, for mobile applications.

Emitter materials which are known in the prior art are, inter alia, arylvinylamines (cf. WO 04/013073, WO 04/016575 and WO 04/018587). Also known are indenofluorenamine compounds, for example in accordance with WO 06/122630, and benzoindenofluorenamine compounds, for example in accordance with WO 08/006449.

However, there continues to be a demand for emitter materials (dopant compounds) for use in electronic devices, in particular for blue-emitting emitter materials. In particular, there is again a demand for emitter materials which have a small difference between the excitation and emission wavelength (Stokes shift). A small Stokes shift is favoured, inter alia, by the smallest possible proportion of flexible units in the molecule, i.e. the smallest possible number of degrees of rotational freedom. There continues to be a demand for emitter materials which emit light having blue or deep-blue colour coordinates with high colour purity. It is furthermore desirable to have available materials which have a high glass-transition temperature and are thermally stable. Furthermore, many blue-emitting materials have high crystallinity. Crystal formation can occur during device operation and thus result in a loss of brightness and in a reduction in the device lifetime. It is therefore desirable to have available non-crystalline materials.

Emitter materials which are known in the prior art are furthermore arylamines containing condensed aryl groups, for example anthracenamines, benzanthracenamines and chrysenamines.

U.S. Pat. No. 5,153,073 discloses pyrene derivatives which carry one or two diarylamino groups and no further substituents on the pyrene skeleton. The said patent discloses the use of the compounds as functional materials for electroluminescent devices, in particular blue-fluorescent electroluminescent devices. Compared with the compounds disclosed in U.S. Pat. No. 5,153,073, there is a need for improvement with respect to the power efficiency and operating lifetime.

Furthermore, the application WO 08/136,522 discloses pyrene derivatives which are substituted by one or more diarylamino groups which have at least one nitrogen-containing heterocyclic ring or a substituent containing P, Si, Ge or B.

Compared with the pyrene derivatives disclosed in this application, there is a need for improvement with respect to the performance data of the organic electronic device comprising the derivatives, in particular with respect to the energy efficiency and emission colour.

In the course of the present invention, it has now been found that compounds of the formula (I) defined below are highly suitable as emitter materials for use in electronic devices and provide good properties, in particular in the critical points mentioned above.

The present invention thus relates to a compound of the formula (I)

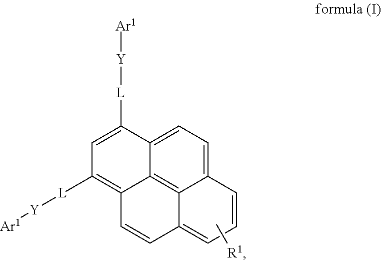

where the following applies to the symbols occurring:
Y is on each occurrence, identically or differently, —N(Ar¹)—, —P(Ar¹)—, —P(═O)(Ar¹)—, —S—, —S(═O)— or —S(═O)₂—;
L is on each occurrence, identically or differently, a single bond or a group Ar²;
Ar¹ is on each occurrence, identically or differently, an aromatic ring system having 6 to 30 aromatic ring atoms or a heteroaromatic ring system having 5 to 30 aromatic ring atoms, which may be substituted by one or more radicals R², where two groups Ar¹ which are bonded to the same group Y may be connected to one another via a single bond or a divalent group selected from —C(R²)₂—, —R²C═CR²—, —Si(R²)₂—, —C(═O)—, —C(═NR²)—, —O—, —S— or —NR²—, and where the groups Ar₁ are not substituted by a radical containing B, Si, Ge or P, and where furthermore Ar¹ does not represent a heteroaryl group containing one or more nitrogen atoms in the aromatic ring;
Ar² is on each occurrence, identically or differently, an aromatic ring system having 6 to 30 aromatic ring atoms, which may be substituted by one or more radicals R², or a heteroaromatic ring system having 5 to 30 aromatic ring atoms, which may be substituted by one or more radicals R²;
R¹ is on each occurrence, identically or differently, F, D, C(═O)R³, CN, Si(R³)₃, N(R³)₂, NO₂, a straight-chain alkyl or alkoxy group having 1 to 20 C atoms or a branched or cyclic alkyl or alkoxy group having 3 to 20 C atoms or an alkenyl or alkynyl group having 2 to 20 C atoms, where the above-mentioned groups may each be substituted by one or more radicals R³ and where one or more adjacent or non-adjacent CH₂ groups in the above-mentioned groups may be replaced by Si(R³)₂, C═O, C═NR³, —C(═O)O—, —C(═O)NR³—, NR³, —O—, —S—, SO or SO₂ and where one or more H atoms in the above-mentioned groups may be replaced by D, F, Cl, Br, I, CN or NO₂, or an aryl group having 6 to 20 aromatic ring atoms, which may be substituted by one or more radicals R³, or a heteroaryl group having 5 to 20 aromatic ring atoms, which may be substituted by one or more radicals R³, where R¹ is bonded at one or more of positions 6, 7 and 8 of the pyrene and where 1, 2 or 3 groups R¹ are present, and where furthermore, for R¹═N(R³)₂, this radical R¹ cannot be bonded at one or more of the two positions 6 and 8 of the pyrene;
R² is on each occurrence, identically or differently, H, D, F, Cl, Br, I, B(OR³)₂, CHO, C(═O)R³, CR³═C(R³)₂, CN, C(═O)OR³, C(═O)N(R³)₂, Si(R³)₃, N(R³)₂, NO₂, P(═O)(R³)₂, OSO₂R³, OR³, S(═O)R³, S(═O)₂R³, a straight-chain alkyl, alkoxy or thioalkyl group having 1 to 20 C atoms or a branched or cyclic alkyl, alkoxy or thioalkyl group having 3 to 20 C atoms or an alkenyl or alkynyl group having 2 to 20 C atoms, where the above-mentioned groups may each be substituted by one or more radicals R³ and where one or more adjacent or non-adjacent CH₂ groups in the above-mentioned groups may be replaced by —R³C═CR³—, —C≡C—, Si(R³)₂, Ge(R³)₂, Sn(R³)₂, C═O, C═S, C═Se, C═NR³, —C(═O)O—, —C(═O)NR³—, NR³, P(═O)(R³), —O—, —S—, SO or SO₂ and where one or more H atoms in the above-mentioned groups may be replaced by D, F, Cl, Br, I, CN or NO₂, or an aromatic or heteroaromatic ring system having 5 to 60 aromatic ring atoms, which may in each case be substituted by one or more radicals R³, or an aryloxy or heteroaryloxy group having 5 to 60 aromatic ring atoms, which may be substituted by one or more radicals R³, where two or more radicals R² may be linked to one another and may form an aliphatic, heteroaliphatic, aromatic or heteroaromatic ring;
R³ is on each occurrence, identically or differently, H, D, F, Cl, Br, I, B(OR⁴)₂, CHO, C(═O)R⁴, CR⁴═C(R⁴)₂, CN, C(═O)OR⁴, C(═O)N(R⁴)₂, Si(R⁴)₃, N(R⁴)₂, NO₂, P(═O)(R⁴)₂, OSO₂R⁴, OR⁴, S(═O)R⁴, S(═O)₂R⁴, a straight-chain alkyl, alkoxy or thioalkyl group having 1 to 20 C atoms or a branched or cyclic alkyl, alkoxy or thioalkyl group having 3 to 20 C atoms or an alkenyl or alkynyl group having 2 to 20 C atoms, where the above-mentioned groups may each be substituted by one or more radicals R⁴ and where one or more adjacent or non-adjacent CH₂ groups in the above-mentioned groups may be replaced by —R⁴C═CR⁴—, —C═C—, Si(R⁴)₂, Ge(R⁴)₂, Sn(R⁴)₂, C═O, C═S, C═Se, C═NR⁴, —C(═O)O—, —C(═O)NR⁴—, NR⁴, P(═O)(R⁴), —O—, —S—, SO or SO₂ and where one or more H atoms in the above-mentioned groups may be replaced by D, F, Cl, Br, I, CN or NO₂, or an aromatic or heteroaromatic ring system having 5 to 60 aromatic ring atoms, which may in each case be substituted by one or more radicals R⁴, or an aryloxy or heteroaryloxy group having 5 to 60 aromatic ring atoms, which may be substituted by one or more radicals R⁴, where two or more radicals R³ may be linked to one another and may form an aliphatic, heteroaliphatic, aromatic or heteroaromatic ring;
R⁴ is on each occurrence, identically or differently, H, D, F or an aliphatic, aromatic and/or heteroaromatic organic radical having 1 to 20 C atoms, in which, in addition, one or more H atoms may be replaced by D or F; two or more substituents R⁴ here may also be linked to one another and form an aliphatic, heteroaliphatic, aromatic or heteroaromatic ring;
   where furthermore the pyrene may be substituted at all free positions by one or more radicals R².

In the picture below, the positions 6, 7 and 8 of the pyrene ring in the compound of the formula (I) are each marked with arrows.

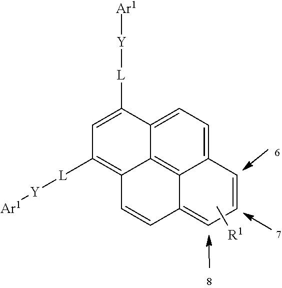

In the present application, the following further basic definitions apply:

An aryl group in the sense of this invention contains 6 to 60 C atoms; a heteroaryl group in the sense of this invention contains 1 to 60 C atoms and at least one heteroatom, with the proviso that the sum of C atoms and heteroatoms is at least 5. The heteroatoms are preferably selected from N, O and/or S.

An aryl group or heteroaryl group here is taken to mean either a simple aromatic ring, i.e. benzene, or a simple heteroaromatic ring, for example pyridine, pyrimidine or thiophene, or a condensed (fused) aromatic or heteroaromatic polycyclic group, for example naphthalene, phenanthrene, quinoline or carbazole. A condensed (fused) aromatic or heteroaromatic polycyclic group in the sense of the present application consists of two or more simple aromatic or heteroaromatic rings which are condensed with one another.

An aryl or heteroaryl group, which may in each case be substituted by the above-mentioned radicals R² or R³ and which may be linked to the aromatic or heteroaromatic ring system via any desired positions, is taken to mean, in particular, groups derived from benzene, naphthalene, anthracene, phenanthrene, pyrene, dihydropyrene, chrysene, perylene, fluoranthene, benzanthracene, benzophenanthrene, tetracene, pentacene, benzopyrene, furan, benzofuran, isobenzofuran, dibenzofuran, thiophene, benzothiophene, isobenzothiophene, dibenzothiophene, pyrrole, indole, isoindole, carbazole, pyridine, quinoline, isoquinoline, acridine, phenanthridine, benzo-5,6-quinoline, benzo-6,7-quinoline, benzo-7,8-quinoline, phenothiazine, phenoxazine, pyrazole, indazole, imidazole, benzimidazole, naphthimidazole, phenanthrimidazole, pyridimidazole, pyrazinimidazole, quinoxalinimidazole, oxazole, benzoxazole, naphthoxazole, anthroxazole, phenanthroxazole, isoxazole, 1,2-thiazole, 1,3-thiazole, benzothiazole, pyridazine, benzopyridazine, pyrimidine, benzopyrimidine, quinoxaline, pyrazine, phenazine, naphthyridine, azacarbazole, benzocarboline, phenanthroline, 1,2,3-triazole, 1,2,4-triazole, benzotriazole, 1,2,3-oxadiazole, 1,2,4-oxadiazole, 1,2,5-oxadiazole, 1,3,4-oxadiazole, 1,2,3-thiadiazole, 1,2,4-thiadiazole, 1,2,5-thiadiazole, 1,3,4-thiadiazole, 1,3,5-triazine, 1,2,4-triazine, 1,2,3-triazine, tetrazole, 1,2,4,5-tetrazine, 1,2,3,4-tetrazine, 1,2,3,5-tetrazine, purine, pteridine, indolizine and benzothiadiazole.

An aromatic ring system in the sense of this invention contains 6 to 60 C atoms in the ring system. A heteroaromatic ring system in the sense of this invention contains 5 to 60 aromatic ring atoms, at least one of which is a heteroatom. The heteroatoms are preferably selected from N, O and/or S.

An aromatic or heteroaromatic ring system in the sense of this invention is intended to be taken to mean a system which does not necessarily contain only aryl or heteroaryl groups, but instead in which, in addition, a plurality of aryl or heteroaryl groups may be connected by a non-aromatic unit (preferably less than 10% of the atoms other than H), such as, for example, an sp³-hybridised C, Si, N or O atom, an sp³-hybridised C or N atom or an sp-hybridised C atom. Thus, for example, systems such as 9,9′-spirobifluorene, 9,9′-diarylfluorene, 9,9′-dialkylfluorene, triarylamine, diaryl ether, stilbene, etc., are also intended to be taken to be aromatic ring systems in the sense of this invention, as are systems in which two or more aryl groups are connected, for example, by a linear or cyclic alkyl, alkenyl or alkynyl group or by a silyl group. Furthermore, systems in which two or more aryl or heteroaryl groups are linked to one another via single bonds are also taken to be aromatic or heteroaromatic ring systems in the sense of this invention, such as, for example, systems such as biphenyl, terphenyl or diphenyltriazine.

An aromatic or heteroaromatic ring system having 5-60 aromatic ring atoms, which may also in each case be substituted by radicals as defined above and which may be linked to the aromatic or heteroaromatic group via any desired positions, is taken to mean, in particular, groups derived from benzene, naphthalene, anthracene, benzanthracene, phenanthrene, benzophenanthrene, pyrene, chrysene, perylene, fluoranthene, naphthacene, pentacene, benzopyrene, biphenyl, biphenylene, terphenyl, terphenylene, fluorene, spirobifluorene, dihydrophenanthrene, dihydropyrene, tetrahydropyrene, cis- or trans-indenofluorene, truxene, isotruxene, spirotruxene, spiroisotruxene, furan, benzofuran, isobenzofuran, dibenzofuran, thiophene, benzothiophene, isobenzothiophene, dibenzothiophene, pyrrole, indole, isoindole, carbazole, indolocarbazole, indenocarbazole, pyridine, quinoline, isoquinoline, acridine, phenanthridine, benzo-5,6-quinoline, benzo-6,7-quinoline, benzo-7,8-quinoline, phenothiazine, phenoxazine, pyrazole, indazole, imidazole, benzimidazole, naphthimidazole, phenanthrimidazole, pyridimidazole, pyrazinimidazole, quinoxalinimidazole, oxazole, benzoxazole, naphthoxazole, anthroxazole, phenanthroxazole, isoxazole, 1,2-thiazole, 1,3-thiazole, benzothiazole, pyridazine, benzopyridazine, pyrimidine, benzopyrimidine, quinoxaline, 1,5-diazaanthracene, 2,7-diazapyrene, 2,3-diazapyrene, 1,6-diazapyrene, 1,8-diazapyrene, 4,5-diazapyrene, 4,5,9,10-tetraazaperylene, pyrazine, phenazine, phenoxazine, phenothiazine, fluorubin, naphthyridine, azacarbazole, benzocarboline, phenanthroline, 1,2,3-triazole, 1,2,4-triazole, benzotriazole, 1,2,3-oxadiazole, 1,2,4-oxadiazole, 1,2,5-oxadiazole, 1,3,4-oxadiazole, 1,2,3-thiadiazole, 1,2,4-thiadiazole, 1,2,5-thiadiazole, 1,3,4-thiadiazole, 1,3,5-triazine, 1,2,4-triazine, 1,2,3-triazine, tetrazole, 1,2,4,5-tetrazine, 1,2,3,4-tetrazine, 1,2,3,5-tetrazine, purine, pteridine, indolizine and benzothiadiazole or combinations of these groups.

For the purposes of the present invention, a straight-chain alkyl group having 1 to 40 C atoms or a branched or cyclic alkyl group having 3 to 40 C atoms or an alkenyl or alkynyl group having 2 to 40 C atoms, in which, in addition, individual H atoms or CH₂ groups may be substituted by the groups mentioned above under the definition of the radicals R¹ and R², is preferably taken to mean the radicals methyl, ethyl, n-propyl, i-propyl, n-butyl, i-butyl, s-butyl, t-butyl, 2-methylbutyl, n-pentyl, s-pentyl, cyclopentyl, neopentyl, n-hexyl, cyclohexyl, neohexyl, n-heptyl, cycloheptyl, n-octyl, cyclooctyl, 2-ethylhexyl, trifluoromethyl, pentafluoroethyl, 2,2,2-trifluoroethyl, ethenyl, propenyl, butenyl, pentenyl, cyclopentenyl, hexenyl, cyclohexenyl, heptenyl, cycloheptenyl, octenyl, cyclooctenyl, ethynyl, propynyl, butynyl, pentynyl, hexynyl or octynyl. An alkoxy or thioalkyl group having 1 to 40 C atoms is preferably taken to mean methoxy, trifluoromethoxy, ethoxy, n-propoxy, i-propoxy, n-butoxy, i-butoxy, s-butoxy, t-butoxy, n-pentoxy, s-pentoxy, 2-methylbutoxy, n-hexoxy, cyclohexyloxy, n-heptoxy, cycloheptyloxy, n-octyloxy, cyclooctyloxy, 2-ethylhexyloxy, pentafluoroethoxy, 2,2,2-trifluoroethoxy, methylthio, ethylthio, n-propylthio, i-propylthio, n-butylthio, i-butylthio, s-butylthio, t-butylthio, n-pentylthio, s-pentylthio, n-hexylthio, cyclohexylthio, n-heptylthio, cycloheptylthio, n-octylthio, cyclooctylthio, 2-ethylhexylthio, trifluoromethylthio, pentafluoroethylthio, 2,2,2-trifluoroethylthio, ethenylthio, propenylthio, butenylthio, pentenylthio, cyclopentenylthio, hexenylthio, cyclohexenylthio, heptenylthio, cycloheptenylthio, octenylthio, cyclooctenylthio, ethynylthio, propynylthio, butynylthio, pentynylthio, hexynylthio, heptynylthio or octynylthio.

In a preferred embodiment of the invention, the compound of the formula (I) conforms to one of the following formulae (I-1) to (I-10)

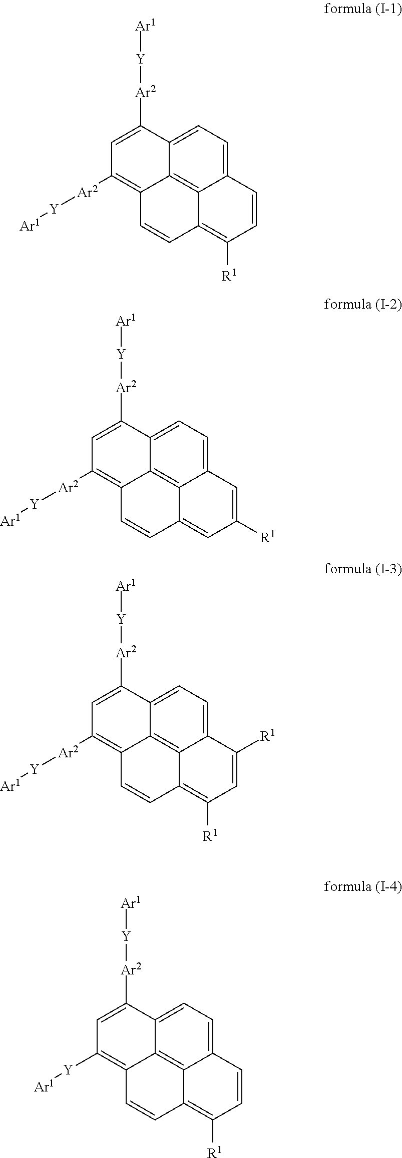

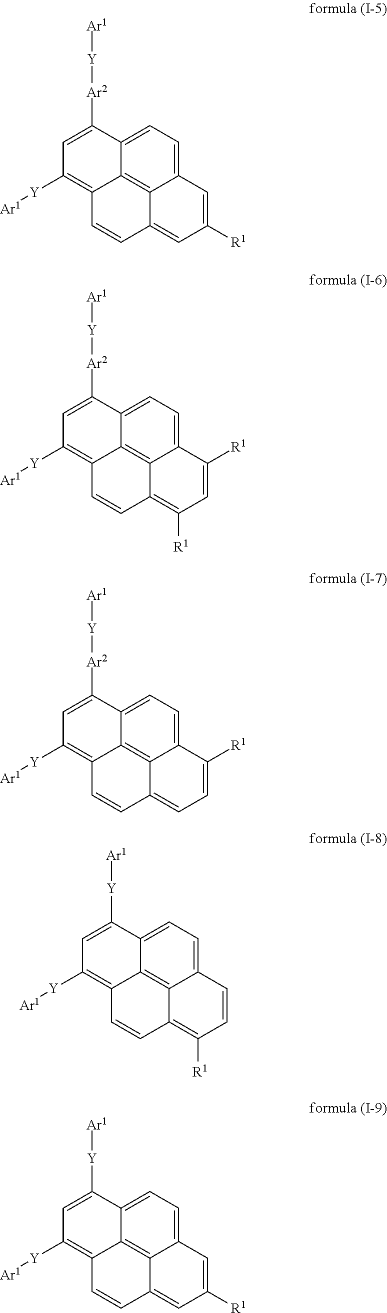

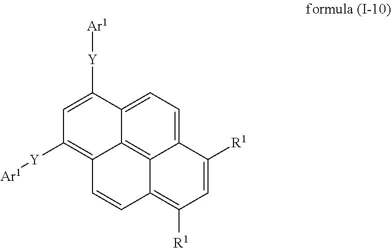

where the symbols occurring are as defined above and furthermore the pyrene may be substituted at all free positions by one or more radicals R².

Of the compounds of the formulae (I-1) to (I-10), particular preference is given to the compounds of the formulae (I-2), (I-5) and (I-9), very particularly preferably the compounds of the formula (I-9).

Furthermore, the group Y is preferably selected on each occurrence, identically or differently, from —N(Ar¹)— and —P(Ar¹)— and particularly preferably selected from —N(Ar¹)—.

Particularly preferred embodiments of the compounds of the formula (I) are therefore compounds of the following formulae (I-1a) to (I-10a)

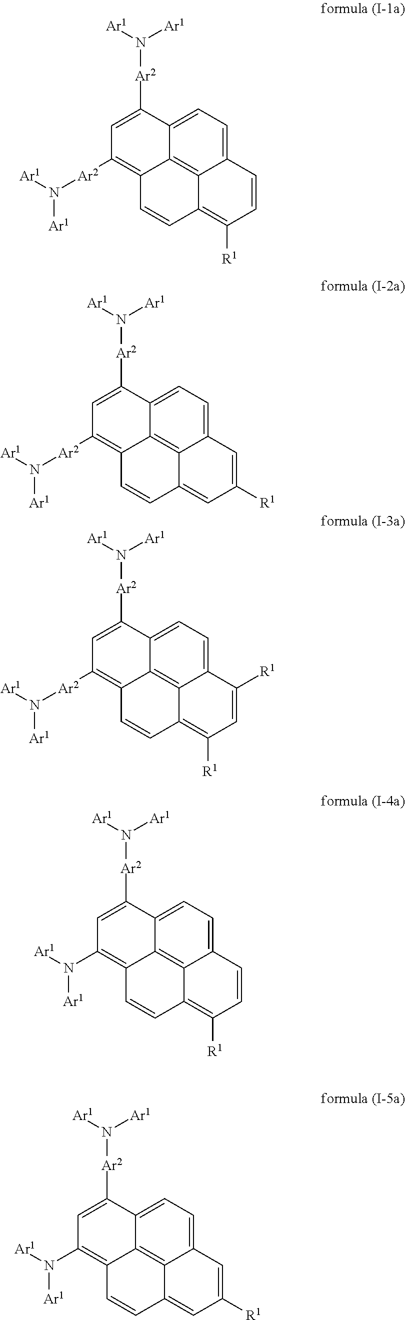

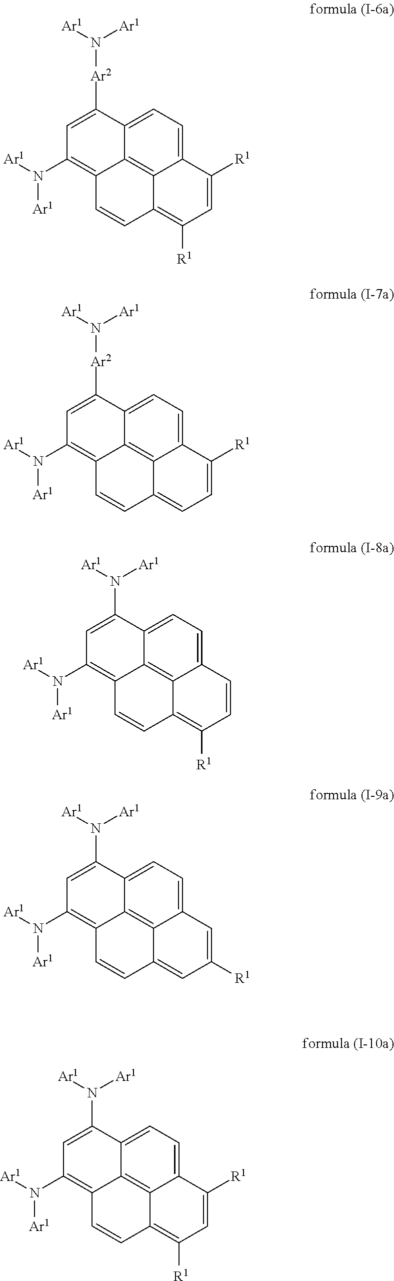

where the symbols occurring are as defined above and furthermore the pyrene may be substituted at all free positions by one or more radicals R².

Of the compounds of the formulae (I-1a) to (I-10a), particular preference is given to the compounds formulae (I-2), (I-5) and (I-9), very particularly preferably the compounds of the formula (I-9a).

In a preferred embodiment of the invention, Ar¹ represents an aromatic ring system having 6 to 20 aromatic ring atoms, which may be substituted by one or more radicals R², where two groups Ar¹ which are bonded to the same group Y may be connected to one another via a single bond or a divalent group selected from —C(R²)₂—, —C(═O)—, —O—, —S— or —NR²—, and where furthermore Ar¹ is not substituted by a radical containing B, Si, Ge or P.

In a particularly preferred embodiment of the invention, Ar¹ represents an aryl group having 6 to 18 aromatic ring atoms, which may be substituted by one or more radicals R², where two groups Ar¹ which are bonded to the same group Y may be connected to one another via a single bond or a divalent group selected from —C(R²)₂—, —C(═O)—, —O—, —S— or —NR²—, where a five-membered ring or a six-membered ring is formed, and where furthermore Ar¹ is not substituted by a radical containing B, Si, Ge or P.

In a further particularly preferred embodiment of the invention, Ar¹ is selected on each occurrence, identically or differently, from the following groups, which may be substituted by one or more radicals R²: phenyl, biphenyl, terphenyl, naphthyl, anthracenyl, benzanthracenyl, pyrenyl, phenanthrenyl, benzophenanthrenyl, fluorenyl, spirobifluorenyl and indenofluorenyl, where furthermore Ar¹ is not substituted by a radical containing B, Si, Ge or P.

In a further particularly preferred embodiment, the groups Ar¹ carry exclusively substituents R² which are selected from H, D, F, Cl, Br, I, C(═O)R³, CN, C(═O)OR³, C(═O)N(R³)₂, N(R³)₂, NO₂, OSO₂R³, S(═O)R³, S(═O)₂R³, straight-chain alkyl, alkoxy or thioalkyl groups having 1 to 20 C atoms or branched or cyclic alkyl, alkoxy or thioalkyl groups having 3 to 20 C atoms or alkenyl or alkynyl groups having 2 to 20 C atoms, where the above-mentioned groups may each be substituted by one or more radicals R³ and where one or more adjacent or non-adjacent CH₂ groups in the above-mentioned groups may be replaced by C═O, C═S, C═NR³, —C(═O)O—, —C(═O)NR³—, NR³, —O—, —S—, SO or SO₂ and where one or more H atoms in the above-mentioned groups may be replaced by D, F, Cl, Br, I, CN or NO₂, or aromatic ring systems having 5 to 30 aromatic ring atoms, which may in each case be substituted by one or more radicals R³, where two or more radicals R² may be linked to one another and may form an aliphatic, heteroaliphatic, aromatic or heteroaromatic ring.

In a further preferred embodiment of the invention, Ar² is on each occurrence, identically or differently, an aromatic ring system having 6 to 20 aromatic ring atoms, which may be substituted by one or more radicals R², or a heteroaromatic ring system having 5 to 20 aromatic ring atoms, which may be substituted by one or more radicals R².

It is furthermore preferred for Ar² to be selected from divalent groups of the following formulae Ar²-1 to Ar²-19

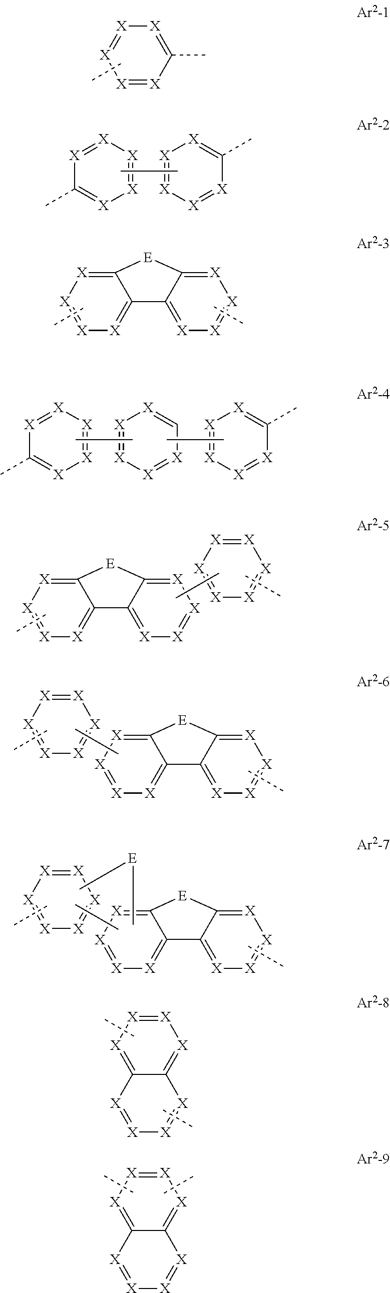

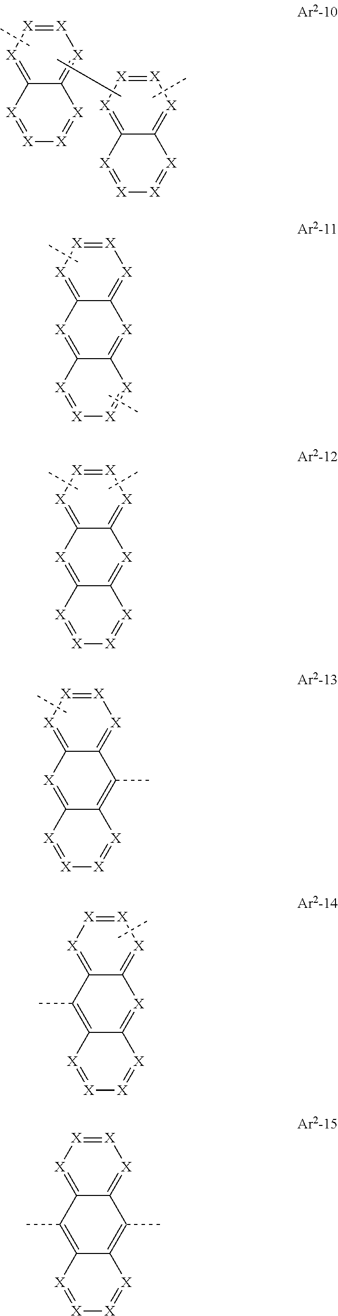

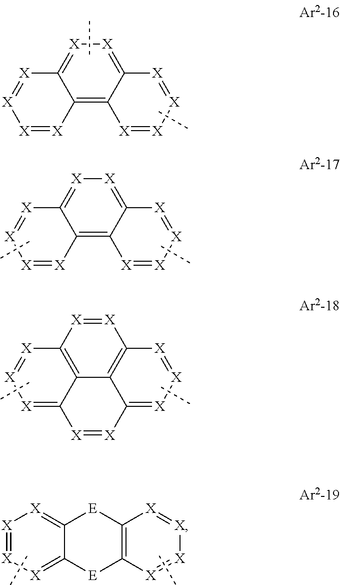

where
X is on each occurrence, identically or differently, CR² or N if no dashed or continuous line or a group E is bonded at the relevant position and is equal to C if a dashed or continuous line or a group E is bonded at the relevant position;
E is on each occurrence, identically or differently, a divalent group selected from —C(R²)₂—, —R²C═CR²—, —Si(R²)₂—, —C(═O)—, —O—, —S—, —S(═O)—, —S(═O)₂— and —NR²—;
   where R² is as defined above;
   and where the two bonds to the group Y and to the pyrene are represented by the two dashed lines, and where the left-hand dashed line denotes the bond from the group Ar² to the pyrene and the right-hand dashed line denotes the bond from the group Ar² to the group Y.

In a preferred embodiment of the invention,
E is on each occurrence, identically or differently, a divalent group selected from —C(R²)₂—, —C(═O)—, —O—, —S— and —NR²—.

It is furthermore preferred for not more than 2 adjacent groups X in the groups Ar²-1 to Ar²-19 to be equal to N. It is particularly preferred for 0, 1 or 2 groups X per group of the formula Ar²-1 to Ar²-19 to be equal to N.

Ar² is particularly preferably selected divalent groups of the following formulae Ar²-20 to Ar²-63

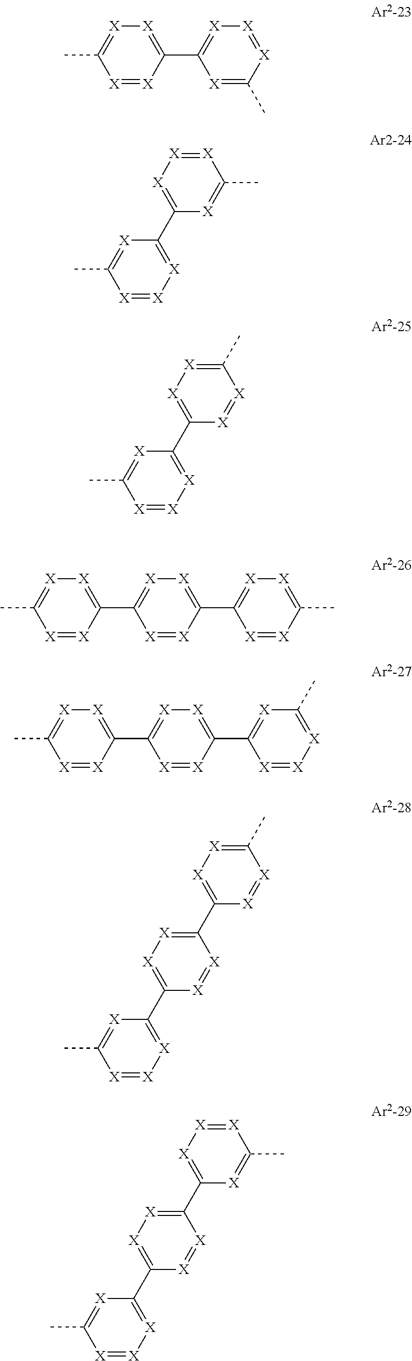

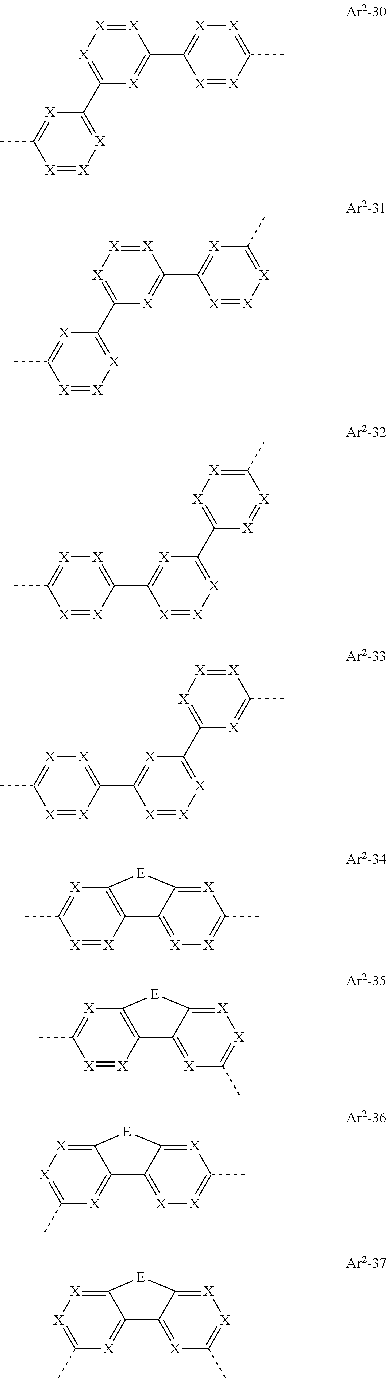

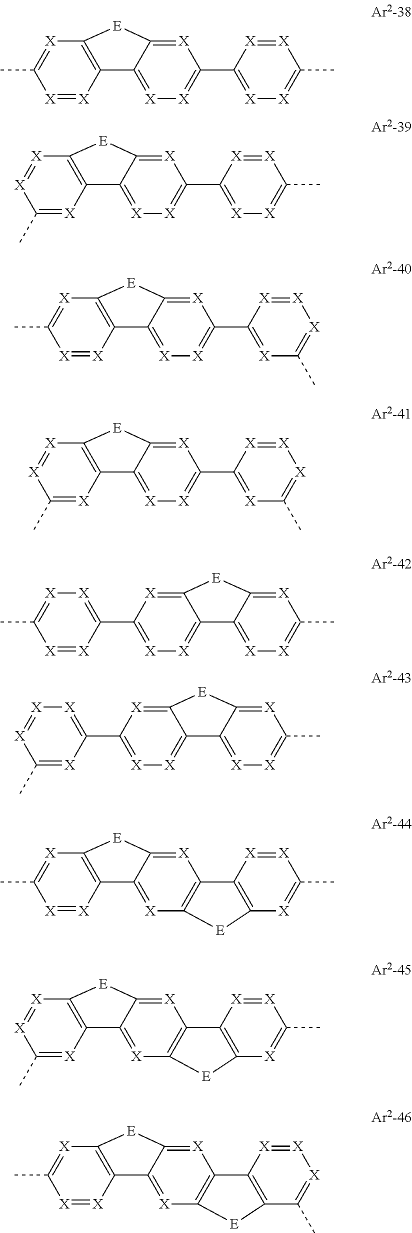

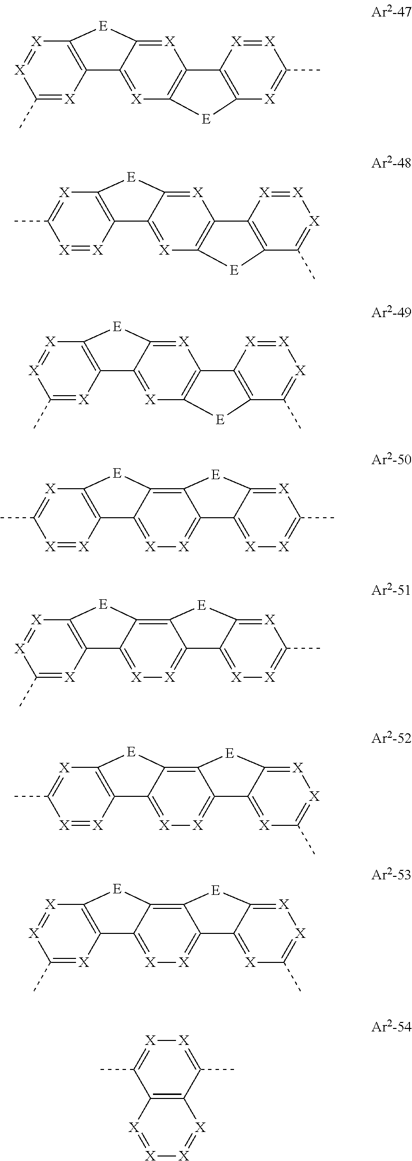

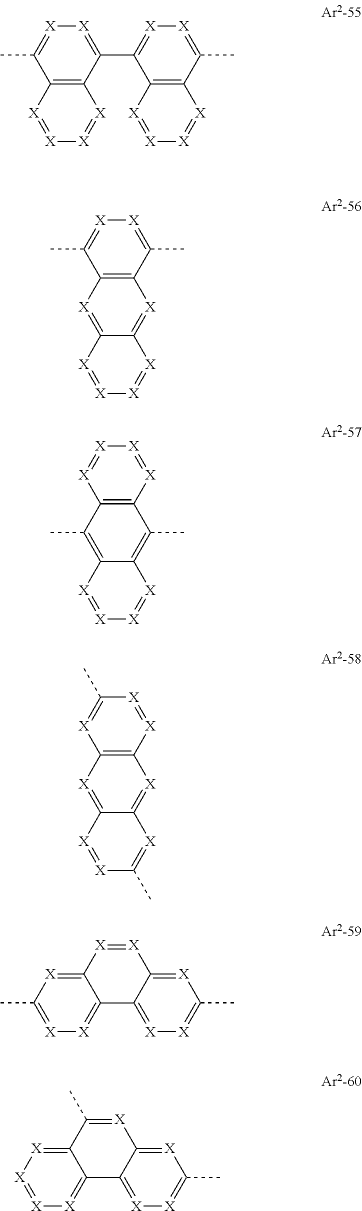

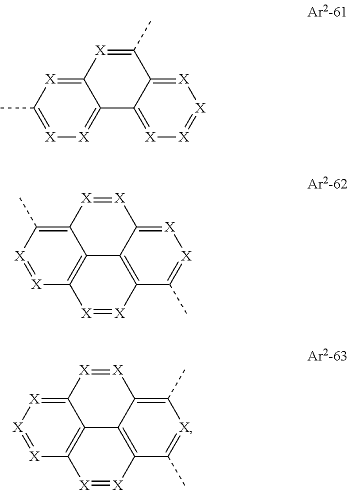

where
X is on each occurrence, identically or differently, CR² or N;
E is on each occurrence, identically or differently, a divalent group selected from —C(R²)₂—, —C(═O)—, —O—, —S— and —NR²—;
   where R² is as defined above;
   and where the two bonds to the radical of the formula (I) are represented by the two dashed lines, and where the left-hand dashed line denotes the bond from the group Ar² to the pyrene and the right-hand dashed line denotes the bond from the group Ar² to the group Y.

It is furthermore preferred for not more than 2 adjacent groups X in the groups Ar²-20 to Ar²-63 to be equal to N. It is particularly preferred for 0, 1 or 2 groups X per group of the formula Ar²-20 to Ar²-63 to be equal to N.

According to a further preferred embodiment of the invention, one or two groups R¹ are present in the compound of the formula (I). Particularly preferably, precisely one group R¹ is present in the compound of the formula (I).

Likewise preferably, a group R¹ is bonded in the 7-position on the pyrene in the compound of the formula (I).

According to a further preferred embodiment, the positions 6, 7 and 8 are either substituted by a group R¹ or by hydrogen, where, as already defined above, at least one of positions 6, 7 and 8 is substituted by a group R¹.

According to a further preferred embodiment, R¹ is selected on each occurrence, identically or differently, from F, C(═O)R³, N(R³)₂, a straight-chain alkyl or alkoxy group having 1 to 10 C atoms or a branched or cyclic alkyl or alkoxy group having 3 to 10 C atoms or an alkenyl or alkynyl group having 2 to 10 C atoms, where the above-mentioned groups may each be substituted by one or more radicals R³ and where one or more adjacent or non-adjacent CH₂ groups in the above-mentioned groups may be replaced by C=O, —C(═O)O—, —C(═O)NR³—, NR³, —O—, —S—, SO or SO₂ and where one or more H atoms in the above-mentioned groups may be replaced by D, F, CN or NO₂, or an aryl group having 6 to 18 aromatic ring atoms, which may be substituted by one or more radicals R³, or a heteroaryl group having 5 to 18 aromatic ring atoms, which may be substituted by one or more radicals R³; where furthermore, for R¹═N(R³)₂, this radical R¹ cannot be bonded at positions 6 and 8 of the pyrene.

R¹ is particularly preferably selected on each occurrence, identically or differently, from a straight-chain alkyl group having 1 to 10 C atoms or a branched or cyclic alkyl group having 3 to 10 C atoms, where the above-mentioned groups may each be substituted by one or more radicals R³ and where one or more adjacent or non-adjacent CH₂ groups in the above-mentioned groups may be replaced by C=O, —C(═O)O—, —C(═O)NR³—, NR³, —O— or —S— and where one or more H atoms in the above-mentioned groups may be replaced by D, F or CN, or an aryl group having 6 to 10 aromatic ring atoms, which may be substituted by one or more radicals R³.

According to a further preferred embodiment, groups R² which are bonded to the pyrene ring are selected on each occurrence, identically or differently, from H, D, F, CN, Si(R³)₃, N(R³)₂, a straight-chain alkyl or alkoxy group having 1 to 20 C atoms or a branched or cyclic alkyl or alkoxy group having 3 to 20 C atoms, where the above-mentioned groups may each be substituted by one or more radicals R³ and where one or more adjacent or non-adjacent CH₂ groups in the above-mentioned groups may be replaced by —C≡C—, —R³C═CR³—, Si(R³)₂, C═O, C═NR³, —NR³—, —O—, —S—, —C(═O)0- or —C(═O)NR³—, or an aromatic or heteroaromatic ring system having 5 to 20 aromatic ring atoms, which may in each case be substituted by one or more radicals R³, where two or more radicals R² may be linked to one another and may form an aliphatic, heteroaliphatic, aromatic or heteroaromatic ring.

According to a particularly preferred embodiment of the invention, all groups R² which are bonded to the pyrene ring are equal to H.

According to a further preferred embodiment, R³ is selected on each occurrence, identically or differently, from H, D, F, CN, Si(R⁴)₃, N(R⁴)₂, a straight-chain alkyl or alkoxy group having 1 to 20 C atoms or a branched or cyclic alkyl or alkoxy group having 3 to 20 C atoms, where the above-mentioned groups may each be substituted by one or more radicals R⁴ and where one or more adjacent or non-adjacent CH₂ groups in the above-mentioned groups may be replaced by —C≡C—, —R⁴C═CR⁴—, Si(R⁴)₂, C═O, C═NR⁴, —NR⁴—, —O—, —S—, —C(═O)O— or —C(═O)NR⁴—, or an aromatic or heteroaromatic ring system having 5 to 20 aromatic ring atoms, which may in each case be substituted by one or more radicals R⁴, where two or more radicals R² may be linked to one another and may form an aliphatic, heteroaliphatic, aromatic or heteroaromatic ring.

It is furthermore preferred for the purposes of the present invention for the above-mentioned preferred embodiments of the groups Y, Ar¹, Ar², R¹, R² and R³ to occur combined with the preferred formulae (I-1) to (I-10) and (I-1a) to (I-10a).

Examples of compounds of the formula (I) are shown in the following table.

| | |
|---|---|
| 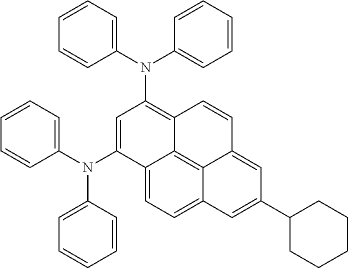 [SMILES: c1ccc(N(c2ccccc2)c2cc(N(c3ccccc3)c3ccccc3)c3ccc4cc(C5CCCCC5)cc5ccc2c3c54)cc1] | 1 |
| 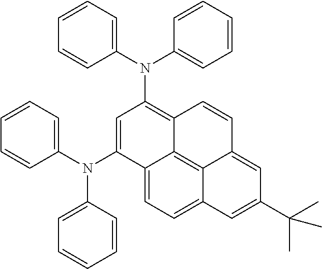 [SMILES: CC(C)(C)c1cc2ccc3c(N(c4ccccc4)c4ccccc4)cc(N(c4ccccc4)c4ccccc4)c4ccc(c1)c2c34] | 2 |
| 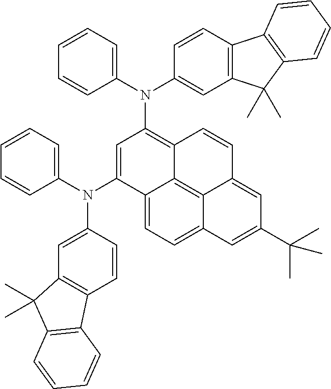 [SMILES: CC(C)(C)c1cc2ccc3c(N(c4ccccc4)c4ccc5c(c4)C(C)(C)c4ccccc4-5)cc(N(c4ccccc4)c4ccc5c(c4)C(C)(C)c4ccccc4-5)c4ccc(c1)c2c34] | 3 |
| 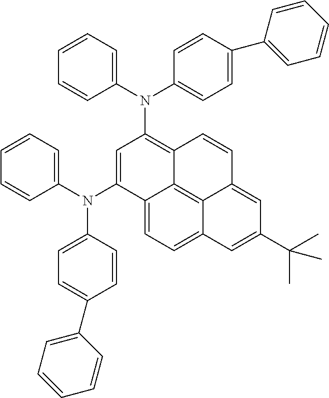 [SMILES: CC(C)(C)c1cc2ccc3c(N(c4ccccc4)c4ccc(-c5ccccc5)cc4)cc(N(c4ccccc4)c4ccc(-c5ccccc5)cc4)c4ccc(c1)c2c34] | 4 |
| 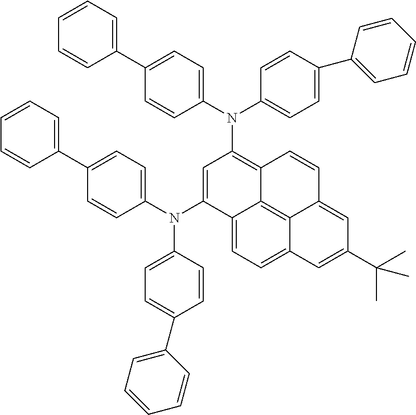 [SMILES: CC(C)(C)c1cc2ccc3c(N(c4ccc(-c5ccccc5)cc4)c4ccc(-c5ccccc5)cc4)cc(N(c4ccc(-c5ccccc5)cc4)c4ccc(-c5ccccc5)cc4)c4ccc(c1)c2c34] | 5 |
| 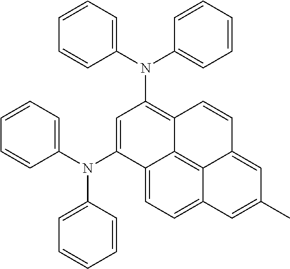 [SMILES: Cc1cc2ccc3c(N(c4ccccc4)c4ccccc4)cc(N(c4ccccc4)c4ccccc4)c4ccc(c1)c2c34] | 6 |
| 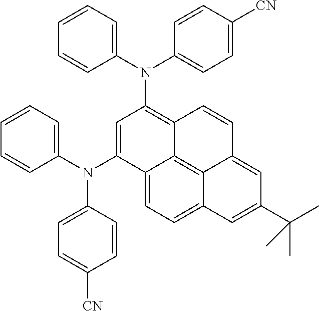 [SMILES: CC(C)(C)c1cc2ccc3c(N(c4ccccc4)c4ccc(C#N)cc4)cc(N(c4ccccc4)c4ccc(C#N)cc4)c4ccc(c1)c2c34] | 7 |
| 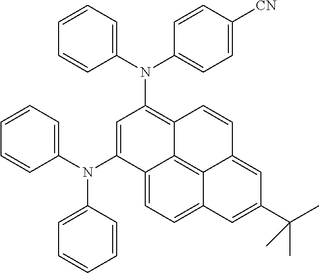 [SMILES: CC(C)(C)c1cc2ccc3c(N(c4ccccc4)c4ccccc4)cc(N(c4ccccc4)c4ccc(C#N)cc4)c4ccc(c1)c2c34] | 8 |
| 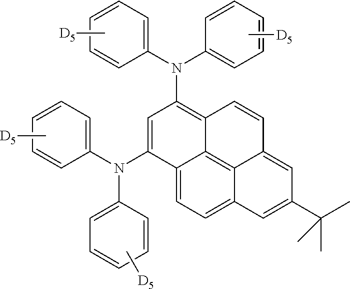 | 9 |
| 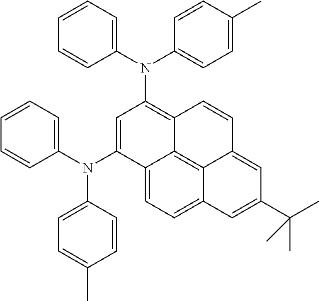 [SMILES: Cc1ccc(N(c2ccccc2)c2cc(N(c3ccccc3)c3ccc(C)cc3)c3ccc4cc(C(C)(C)C)cc5ccc2c3c54)cc1] | 10 |
| 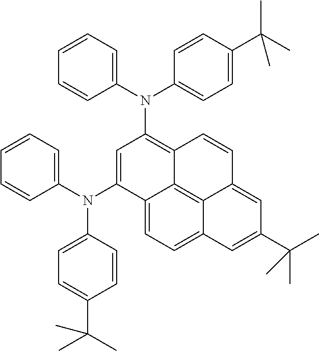 [SMILES: CC(C)(C)c1ccc(N(c2ccccc2)c2cc(N(c3ccccc3)c3ccc(C(C)(C)C)cc3)c3ccc4cc(C(C)(C)C)cc5ccc2c3c54)cc1] | 11 |
| 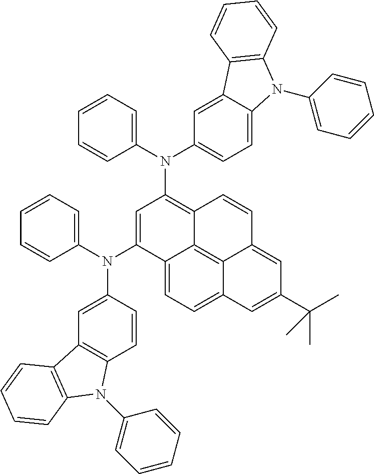 [SMILES: CC(C)(C)c1cc2ccc3c(N(c4ccccc4)c4ccc5c(c4)c4ccccc4n5-c4ccccc4)cc(N(c4ccccc4)c4ccc5c(c4)c4ccccc4n5-c4ccccc4)c4ccc(c1)c2c34] | 12 |
| 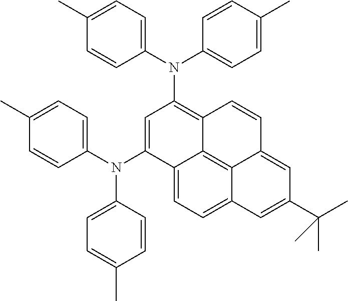 [SMILES: Cc1ccc(N(c2ccc(C)cc2)c2cc(N(c3ccc(C)cc3)c3ccc(C)cc3)c3ccc4cc(C(C)(C)C)cc5ccc2c3c54)cc1] | 13 |
| 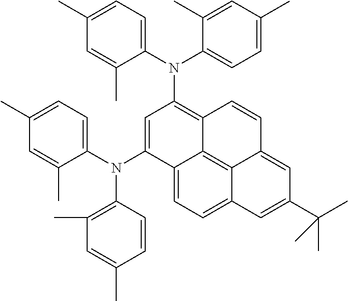 [SMILES: Cc1ccc(N(c2ccc(C)cc2C)c2cc(N(c3ccc(C)cc3C)c3ccc(C)cc3C)c3ccc4cc(C(C)(C)C)cc5ccc2c3c54)c(C)c1] | 14 |
| 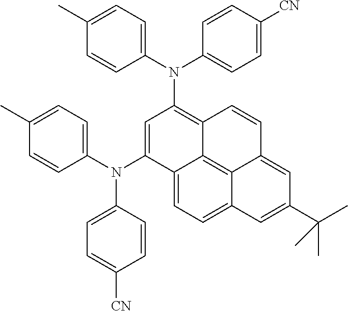 | 15 |
| 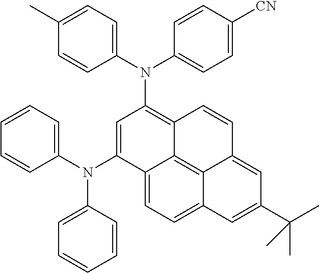 [SMILES: Cc1ccc(N(c2ccc(C#N)cc2)c2cc(N(c3ccccc3)c3ccccc3)c3ccc4cc(C(C)(C)C)cc5ccc2c3c45)cc1] | 16 |
| 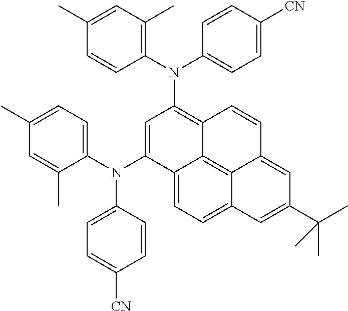 [SMILES: Cc1ccc(N(c2ccc(C#N)cc2)c2cc(N(c3ccc(C#N)cc3)c3ccc(C)cc3C)c3ccc4cc(C(C)(C)C)cc5ccc2c3c54)c(C)c1] | 17 |
| 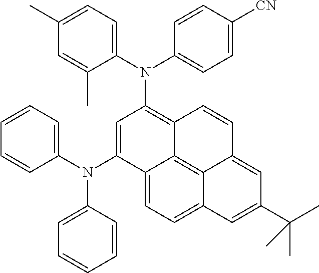 [SMILES: Cc1ccc(N(c2ccc(C#N)cc2)c2cc(N(c3ccccc3)c3ccccc3)c3ccc4cc(C(C)(C)C)cc5ccc2c3c45)c(C)c1] | 18 |
| 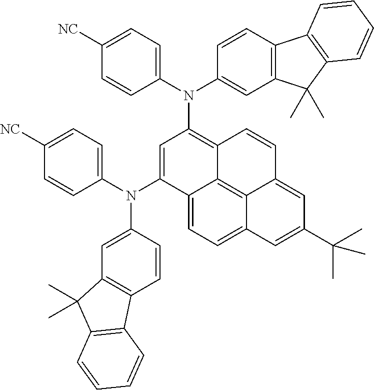 [SMILES: CC(C)(C)c1cc2ccc3c(N(c4ccc(C#N)cc4)c4ccc5c(c4)C(C)(C)c4ccccc4-5)cc(N(c4ccc(C#N)cc4)c4ccc5c(c4)C(C)(C)c4ccccc4-5)c4ccc(c1)c2c34] | 19 |
| 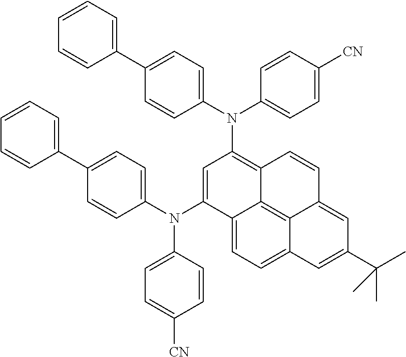 [SMILES: CC(C)(C)c1cc2ccc3c(N(c4ccc(C#N)cc4)c4ccc(-c5ccccc5)cc4)cc(N(c4ccc(C#N)cc4)c4ccc(-c5ccccc5)cc4)c4ccc(c1)c2c34] | 20 |
| 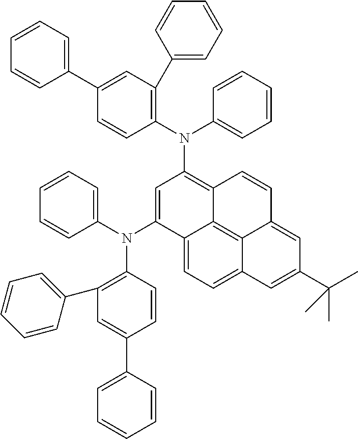 [SMILES: CC(C)(C)c1cc2ccc3c(N(c4ccccc4)c4ccc(-c5ccccc5)cc4-c4ccccc4)cc(N(c4ccccc4)c4ccc(-c5ccccc5)cc4-c4ccccc4)c4ccc(c1)c2c34] | 21 |
| 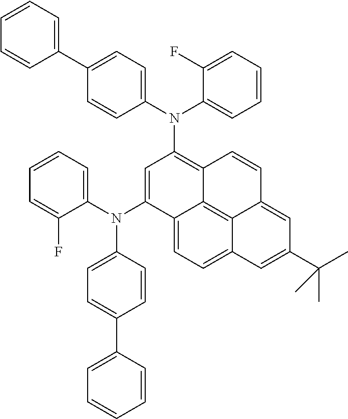 [SMILES: CC(C)(C)c1cc2ccc3c(N(c4ccc(-c5ccccc5)cc4)c4ccccc4F)cc(N(c4ccc(-c5ccccc5)cc4)c4ccccc4F)c4ccc(c1)c2c34] | 22 |
| 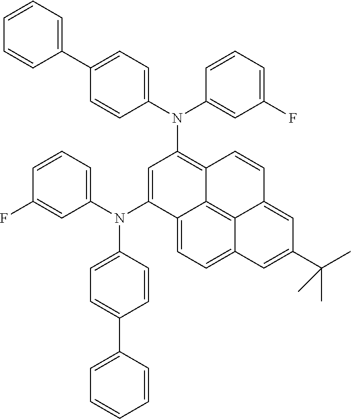 [SMILES: CC(C)(C)c1cc2ccc3c(N(c4ccc(-c5ccccc5)cc4)c4cccc(F)c4)cc(N(c4ccc(-c5ccccc5)cc4)c4cccc(F)c4)c4ccc(c1)c2c34] | 23 |
| 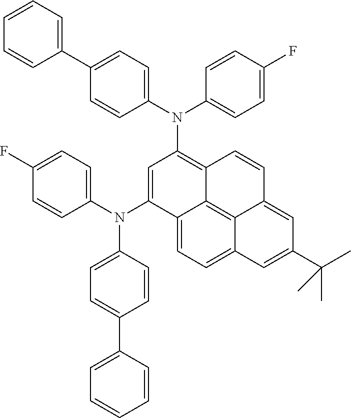 [SMILES: CC(C)(C)c1cc2ccc3c(N(c4ccc(F)cc4)c4ccc(-c5ccccc5)cc4)cc(N(c4ccc(F)cc4)c4ccc(-c5ccccc5)cc4)c4ccc(c1)c2c34] | 24 |
| 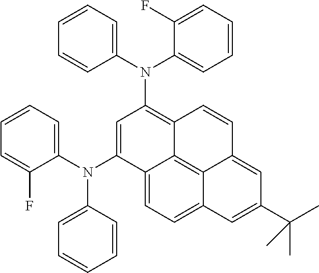 [SMILES: CC(C)(C)c1cc2ccc3c(N(c4ccccc4)c4ccccc4F)cc(N(c4ccccc4)c4ccccc4F)c4ccc(c1)c2c34] | 25 |
| 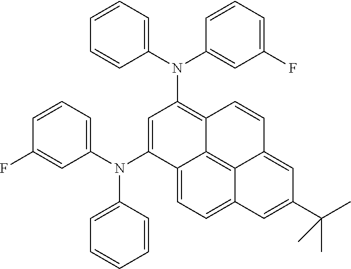 [SMILES: CC(C)(C)c1cc2ccc3c(N(c4ccccc4)c4cccc(F)c4)cc(N(c4ccccc4)c4cccc(F)c4)c4ccc(c1)c2c34] | 26 |
| 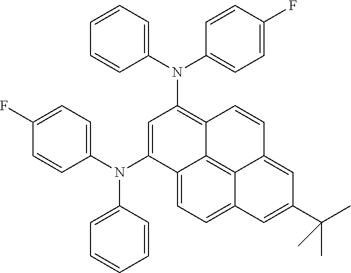 [SMILES: CC(C)(C)c1cc2ccc3c(N(c4ccccc4)c4ccc(F)cc4)cc(N(c4ccccc4)c4ccc(F)cc4)c4ccc(c1)c2c34] | 27 |
| 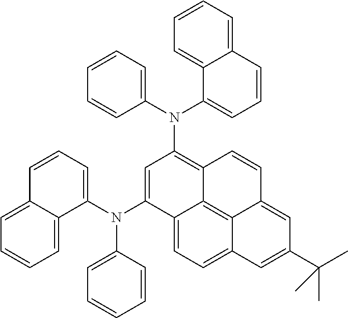 [SMILES: CC(C)(C)c1cc2ccc3c(N(c4ccccc4)c4cccc5ccccc45)cc(N(c4ccccc4)c4cccc5ccccc45)c4ccc(c1)c2c34] | 28 |
| 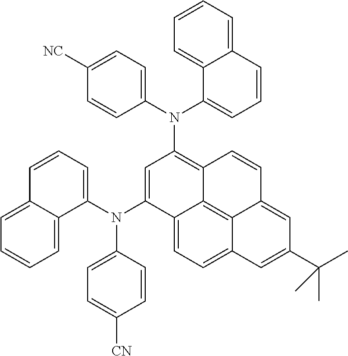 [SMILES: CC(C)(C)c1cc2ccc3c(N(c4ccc(C#N)cc4)c4cccc5ccccc45)cc(N(c4ccc(C#N)cc4)c4cccc5ccccc45)c4ccc(c1)c2c34] | 29 |
| 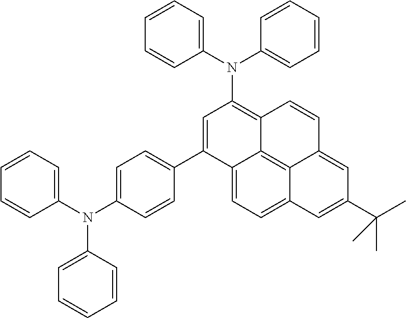 [SMILES: CC(C)(C)c1cc2ccc3c(-c4ccc(N(c5ccccc5)c5ccccc5)cc4)cc(N(c4ccccc4)c4ccccc4)c4ccc(c1)c2c34] | 30 |
| 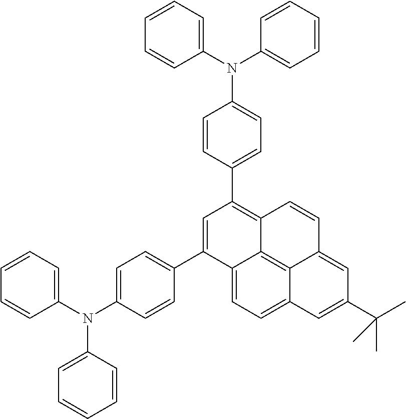 [SMILES: CC(C)(C)c1cc2ccc3c(-c4ccc(N(c5ccccc5)c5ccccc5)cc4)cc(-c4ccc(N(c5ccccc5)c5ccccc5)cc4)c4ccc(c1)c2c34] | 31 |
| 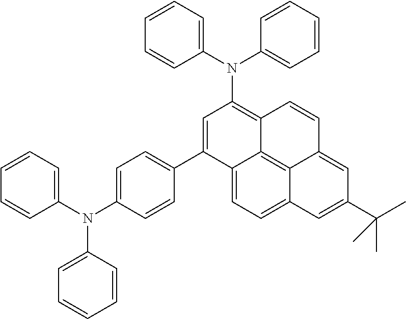 [SMILES: CC(C)(C)c1cc2ccc3c(-c4ccc(N(c5ccccc5)c5ccccc5)cc4)cc(N(c4ccccc4)c4ccccc4)c4ccc(c1)c2c34] | 32 |
| 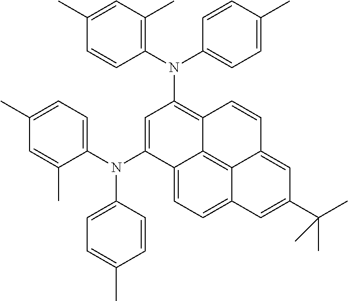 [SMILES: Cc1ccc(N(c2ccc(C)cc2C)c2cc(N(c3ccc(C)cc3)c3ccc(C)cc3C)c3ccc4cc(C(C)(C)C)cc5ccc2c3c54)cc1] | 33 |
| 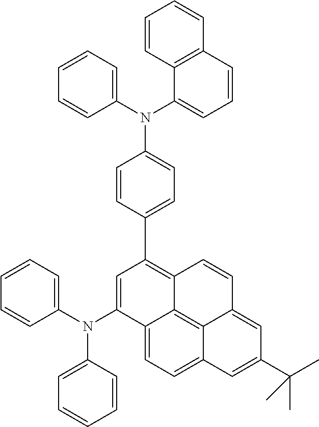 [SMILES: CC(C)(C)c1cc2ccc3c(-c4ccc(N(c5ccccc5)c5cccc6ccccc56)cc4)cc(N(c4ccccc4)c4ccccc4)c4ccc(c1)c2c34] | 34 |
| 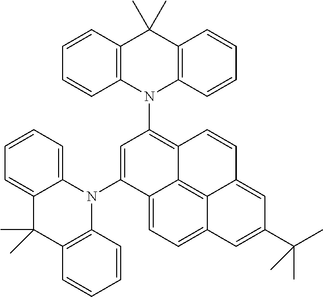 [SMILES: CC(C)(C)c1cc2ccc3c(N4c5ccccc5C(C)(C)c5ccccc54)cc(N4c5ccccc5C(C)(C)c5ccccc54)c4ccc(c1)c2c34] | 35 |
| 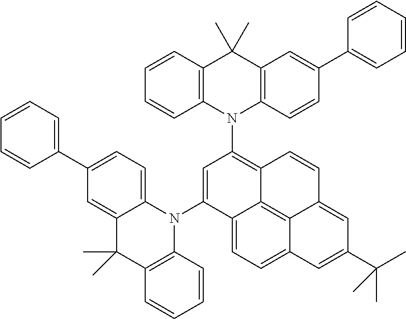 [SMILES: CC(C)(C)c1cc2ccc3c(N4c5ccccc5C(C)(C)c5cc(-c6ccccc6)ccc54)cc(N4c5ccccc5C(C)(C)c5cc(-c6ccccc6)ccc54)c4ccc(c1)c2c34] | 36 |
| 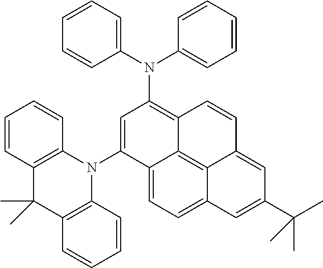 [SMILES: CC(C)(C)c1cc2ccc3c(N(c4ccccc4)c4ccccc4)cc(N4c5ccccc5C(C)(C)c5ccccc54)c4ccc(c1)c2c34] | 37 |
| 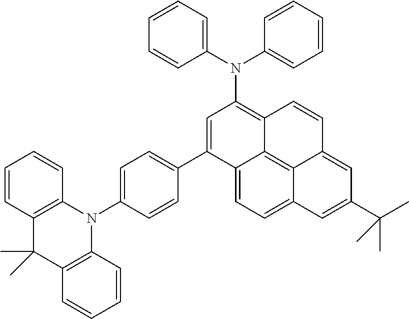 [SMILES: CC(C)(C)c1cc2ccc3c(-c4ccc(N5c6ccccc6C(C)(C)c6ccccc65)cc4)cc(N(c4ccccc4)c4ccccc4)c4ccc(c1)c2c34] | 38 |
| 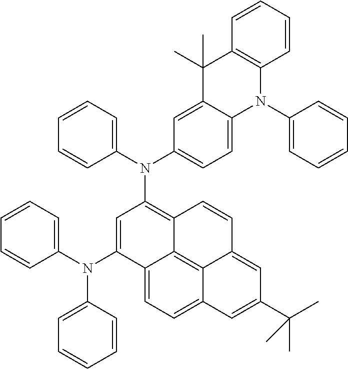 [SMILES: CC(C)(C)c1cc2ccc3c(N(c4ccccc4)c4ccccc4)cc(N(c4ccccc4)c4ccc5c(c4)C(C)(C)c4ccccc4N5c4ccccc4)c4ccc(c1)c2c34] | 39 |
| 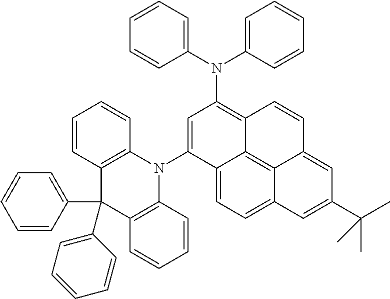 [SMILES: CC(C)(C)c1cc2ccc3c(N(c4ccccc4)c4ccccc4)cc(N4c5ccccc5C(c5ccccc5)(c5ccccc5)c5ccccc54)c4ccc(c1)c2c34] | 40 |
| 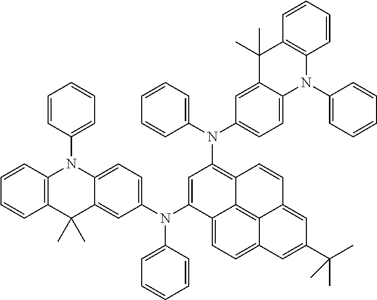 [SMILES: CC(C)(C)c1cc2ccc3c(N(c4ccccc4)c4ccc5c(c4)C(C)(C)c4ccccc4N5c4ccccc4)cc(N(c4ccccc4)c4ccc5c(c4)C(C)(C)c4ccccc4N5c4ccccc4)c4ccc(c1)c2c34] | 41 |
| 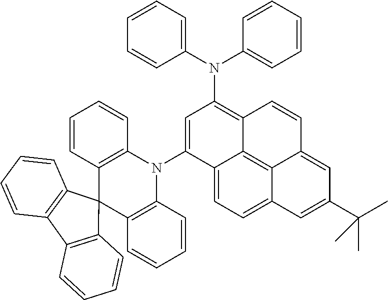 [SMILES: CC(C)(C)c1cc2ccc3c(N(c4ccccc4)c4ccccc4)cc(N4c5ccccc5C5(c6ccccc6-c6ccccc65)c5ccccc54)c4ccc(c1)c2c34] | 42 |
| 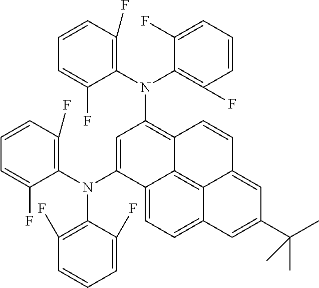 [SMILES: CC(C)(C)c1cc2ccc3c(N(c4c(F)cccc4F)c4c(F)cccc4F)cc(N(c4c(F)cccc4F)c4c(F)cccc4F)c4ccc(c1)c2c34] | 43 |
| 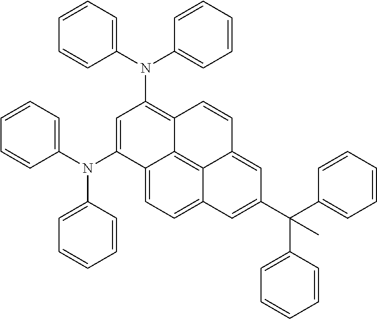 [SMILES: CC(c1ccccc1)(c1ccccc1)c1cc2ccc3c(N(c4ccccc4)c4ccccc4)cc(N(c4ccccc4)c4ccccc4)c4ccc(c1)c2c34] | 44 |
| 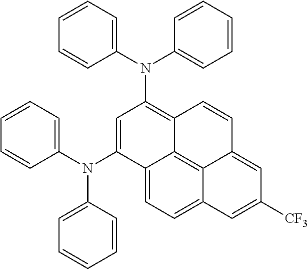 [SMILES: FC(F)(F)c1cc2ccc3c(N(c4ccccc4)c4ccccc4)cc(N(c4ccccc4)c4ccccc4)c4ccc(c1)c2c34] | 45 |
| 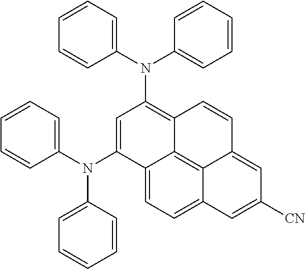 [SMILES: N#Cc1cc2ccc3c(N(c4ccccc4)c4ccccc4)cc(N(c4ccccc4)c4ccccc4)c4ccc(c1)c2c34] | 46 |
| 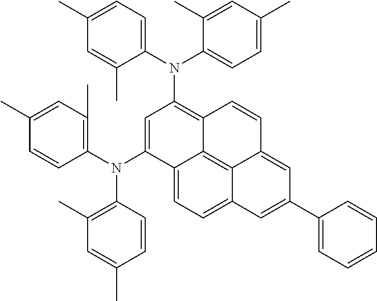 [SMILES: Cc1ccc(N(c2ccc(C)cc2C)c2cc(N(c3ccc(C)cc3C)c3ccc(C)cc3C)c3ccc4cc(-c5ccccc5)cc5ccc2c3c54)c(C)c1] | 47 |
| 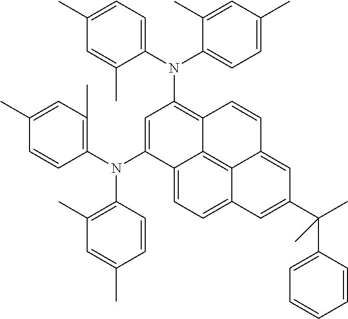 [SMILES: Cc1ccc(N(c2ccc(C)cc2C)c2cc(N(c3ccc(C)cc3C)c3ccc(C)cc3C)c3ccc4cc(C(C)(C)c5ccccc5)cc5ccc2c3c54)c(C)c1] | 48 |
| 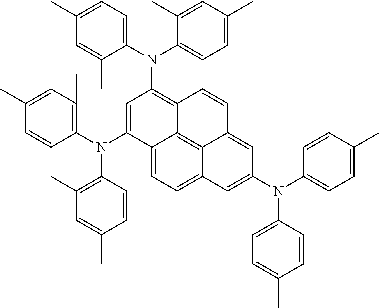 | 49 |
| 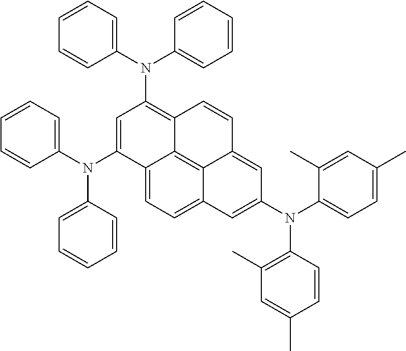 [SMILES: Cc1ccc(N(c2cc3ccc4c(N(c5ccccc5)c5ccccc5)cc(N(c5ccccc5)c5ccccc5)c5ccc(c2)c3c45)c2ccc(C)cc2C)c(C)c1] | 50 |
| 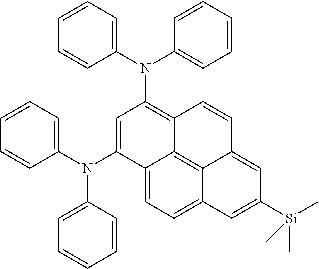 [SMILES: C[Si](C)(C)c1cc2ccc3c(N(c4ccccc4)c4ccccc4)cc(N(c4ccccc4)c4ccccc4)c4ccc(c1)c2c34] | 51 |
| 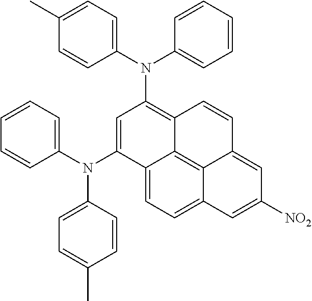 [SMILES: Cc1ccc(N(c2ccccc2)c2cc(N(c3ccccc3)c3ccc(C)cc3)c3ccc4cc([N+](=O)[O-])cc5ccc2c3c54)cc1] | 52 |
| 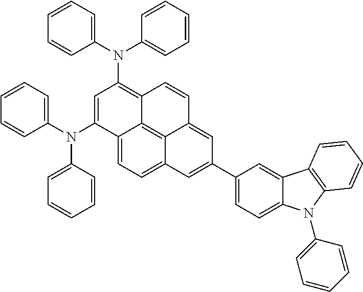 [SMILES: c1ccc(N(c2ccccc2)c2cc(N(c3ccccc3)c3ccccc3)c3ccc4cc(-c5ccc6c(c5)c5ccccc5n6-c5ccccc5)cc5ccc2c3c54)cc1] | 53 |
| 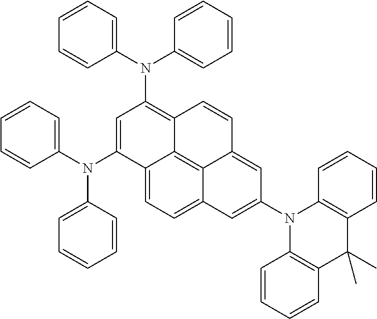 [SMILES: CC1(C)c2ccccc2N(c2cc3ccc4c(N(c5ccccc5)c5ccccc5)cc(N(c5ccccc5)c5ccccc5)c5ccc(c2)c3c45)c2ccccc21] | 54 |
| 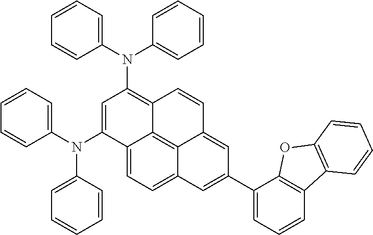 [SMILES: c1ccc(N(c2ccccc2)c2cc(N(c3ccccc3)c3ccccc3)c3ccc4cc(-c5cccc6c5oc5ccccc56)cc5ccc2c3c54)cc1] | 55 |
| 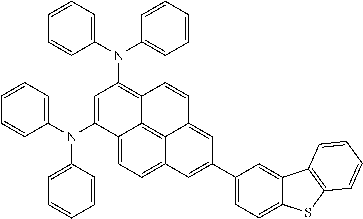 [SMILES: c1ccc(N(c2ccccc2)c2cc(N(c3ccccc3)c3ccccc3)c3ccc4cc(-c5ccc6sc7ccccc7c6c5)cc5ccc2c3c54)cc1] | 56 |
| 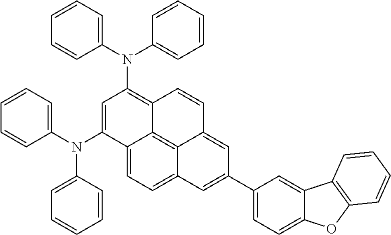 [SMILES: c1ccc(N(c2ccccc2)c2cc(N(c3ccccc3)c3ccccc3)c3ccc4cc(-c5ccc6oc7ccccc7c6c5)cc5ccc2c3c54)cc1] | 57 |
| 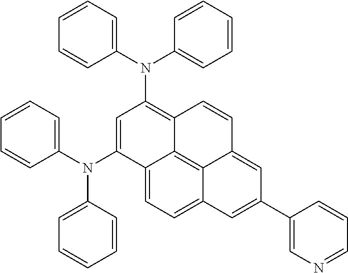 [SMILES: c1ccc(N(c2ccccc2)c2cc(N(c3ccccc3)c3ccccc3)c3ccc4cc(-c5cccnc5)cc5ccc2c3c54)cc1] | 58 |
| 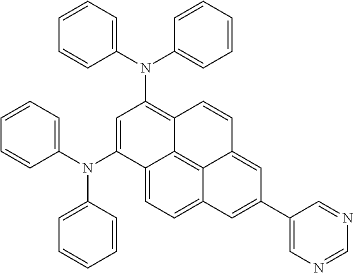 [SMILES: c1ccc(N(c2ccccc2)c2cc(N(c3ccccc3)c3ccccc3)c3ccc4cc(-c5cncnc5)cc5ccc2c3c54)cc1] | 59 |
| 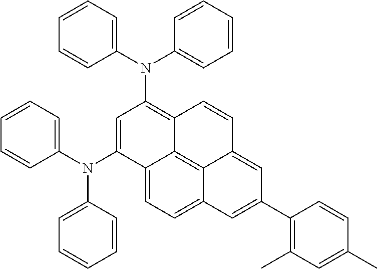 [SMILES: Cc1ccc(-c2cc3ccc4c(N(c5ccccc5)c5ccccc5)cc(N(c5ccccc5)c5ccccc5)c5ccc(c2)c3c45)c(C)c1] | 60 |
| 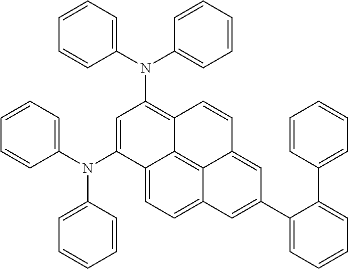 [SMILES: c1ccc(-c2ccccc2-c2cc3ccc4c(N(c5ccccc5)c5ccccc5)cc(N(c5ccccc5)c5ccccc5)c5ccc(c2)c3c45)cc1] | 61 |
| 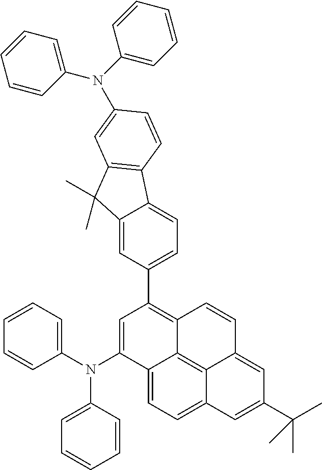 [SMILES: CC(C)(C)c1cc2ccc3c(-c4ccc5c(c4)C(C)(C)c4cc(N(c6ccccc6)c6ccccc6)ccc4-5)cc(N(c4ccccc4)c4ccccc4)c4ccc(c1)c2c34] | 62 |
| 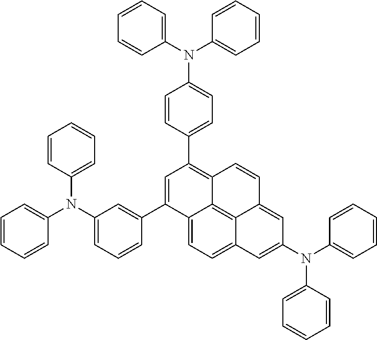 [SMILES: c1ccc(N(c2ccccc2)c2ccc(-c3cc(-c4cccc(N(c5ccccc5)c5ccccc5)c4)c4ccc5cc(N(c6ccccc6)c6ccccc6)cc6ccc3c4c65)cc2)cc1] | 63 |
| 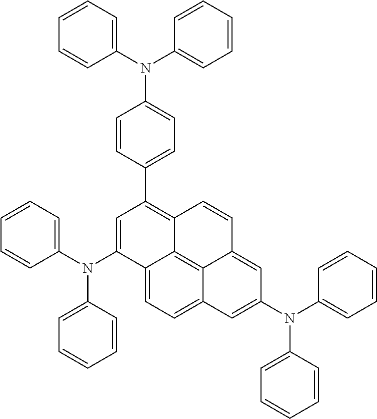 [SMILES: c1ccc(N(c2ccccc2)c2ccc(-c3cc(N(c4ccccc4)c4ccccc4)c4ccc5cc(N(c6ccccc6)c6ccccc6)cc6ccc3c4c65)cc2)cc1] | 64 |
| 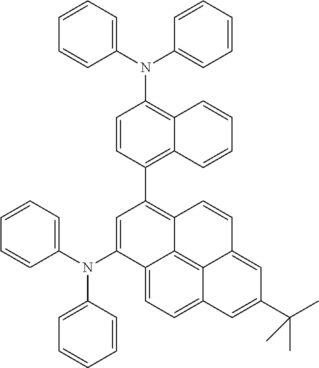 [SMILES: CC(C)(C)c1cc2ccc3c(-c4ccc(N(c5ccccc5)c5ccccc5)c5ccccc45)cc(N(c4ccccc4)c4ccccc4)c4ccc(c1)c2c34] | 65 |
| 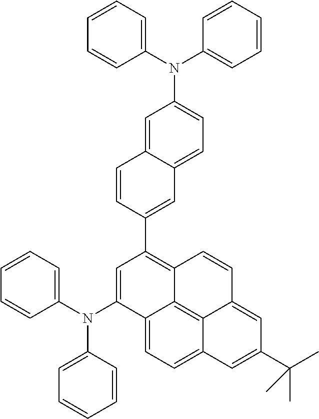 [SMILES: CC(C)(C)c1cc2ccc3c(-c4ccc5cc(N(c6ccccc6)c6ccccc6)ccc5c4)cc(N(c4ccccc4)c4ccccc4)c4ccc(c1)c2c34] | 66 |
| 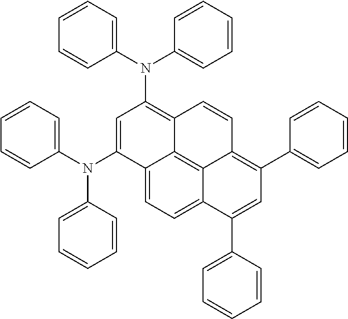 [SMILES: c1ccc(-c2cc(-c3ccccc3)c3ccc4c(N(c5ccccc5)c5ccccc5)cc(N(c5ccccc5)c5ccccc5)c5ccc2c3c54)cc1] | 67 |
| 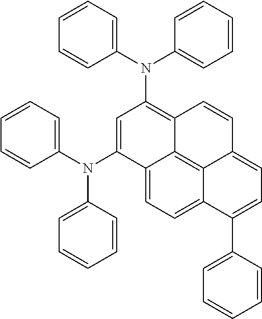 [SMILES: c1ccc(-c2ccc3ccc4c(N(c5ccccc5)c5ccccc5)cc(N(c5ccccc5)c5ccccc5)c5ccc2c3c45)cc1] | 68 |
| 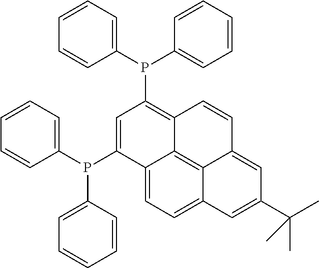 [SMILES: CC(C)(C)c1cc2ccc3c(P(c4ccccc4)c4ccccc4)cc(P(c4ccccc4)c4ccccc4)c4ccc(c1)c2c34] | 69 |
| 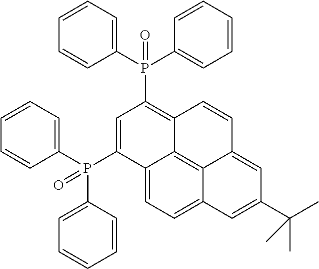 [SMILES: CC(C)(C)c1cc2ccc3c(P(=O)(c4ccccc4)c4ccccc4)cc(P(=O)(c4ccccc4)c4ccccc4)c4ccc(c1)c2c34] | 70 |
| 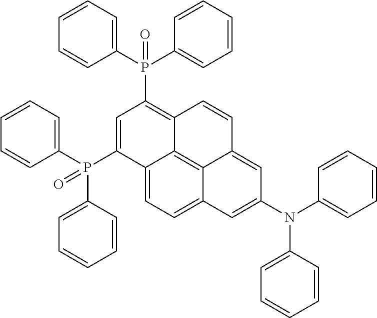 [SMILES: O=P(c1ccccc1)(c1ccccc1)c1cc(P(=O)(c2ccccc2)c2ccccc2)c2ccc3cc(N(c4ccccc4)c4ccccc4)cc4ccc1c2c43] | 71 |
| 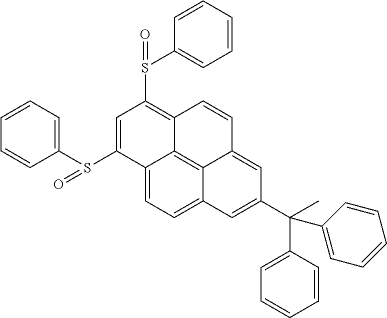 [SMILES: CC(c1ccccc1)(c1ccccc1)c1cc2ccc3c(S(=O)c4ccccc4)cc(S(=O)c4ccccc4)c4ccc(c1)c2c34] | 72 |
| 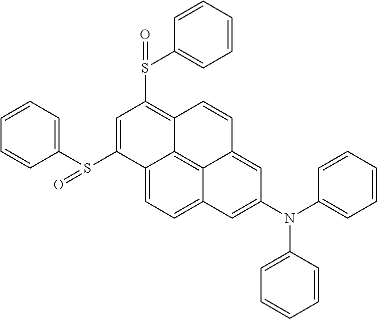 [SMILES: O=S(c1ccccc1)c1cc(S(=O)c2ccccc2)c2ccc3cc(N(c4ccccc4)c4ccccc4)cc4ccc1c2c43] | 73 |
| 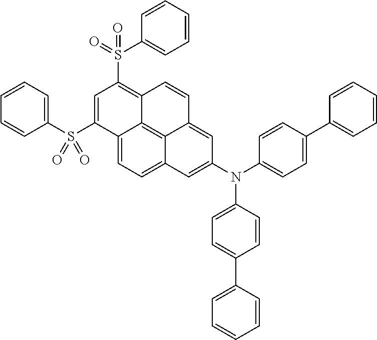 [SMILES: O=S(=O)(c1ccccc1)c1cc(S(=O)(=O)c2ccccc2)c2ccc3cc(N(c4ccc(-c5ccccc5)cc4)c4ccc(-c5ccccc5)cc4)cc4ccc1c2c43] | 74 |
| 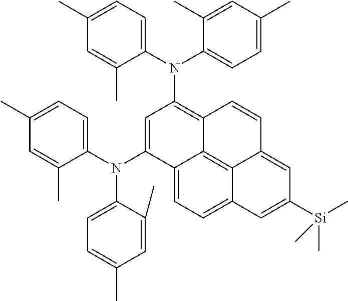 | 75 |
| 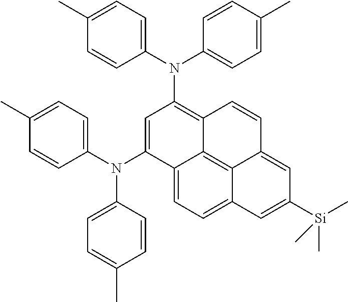 | 76 |
| 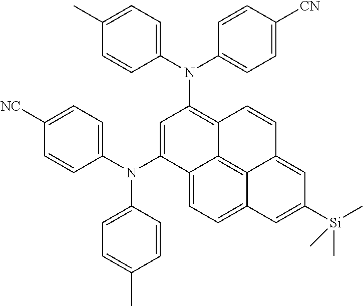 [SMILES: Cc1ccc(N(c2ccc(C#N)cc2)c2cc(N(c3ccc(C)cc3)c3ccc(C#N)cc3)c3ccc4cc([Si](C)(C)C)cc5ccc2c3c54)cc1] | 77 |
| 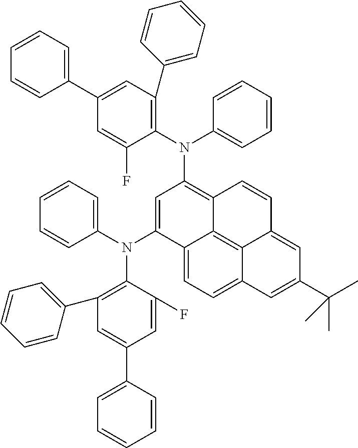 [SMILES: CC(C)(C)c1cc2ccc3c(N(c4ccccc4)c4c(F)cc(-c5ccccc5)cc4-c4ccccc4)cc(N(c4ccccc4)c4c(F)cc(-c5ccccc5)cc4-c4ccccc4)c4ccc(c1)c2c34] | 78 |
| 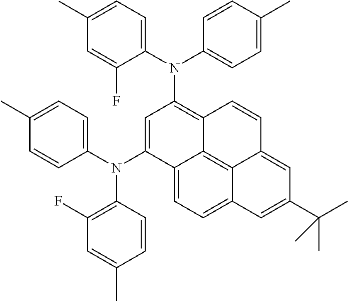 [SMILES: Cc1ccc(N(c2ccc(C)cc2F)c2cc(N(c3ccc(C)cc3)c3ccc(C)cc3F)c3ccc4cc(C(C)(C)C)cc5ccc2c3c54)cc1] | 79 |
| 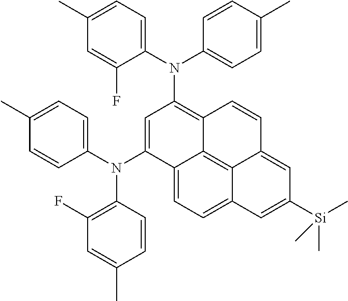 | 80 |

The compounds of the formula (I) according to the invention can be prepared by known organochemical synthesis processes. These include, for example, bromination, Suzuki coupling and Hartwig-Buchwald coupling, inter alia.

The person skilled in the art in the area of organic synthesis and in the area of functional materials for organic electroluminescent devices will be able to deviate from the illustrative synthetic routes shown below and/or modify individual steps in a suitable manner if such action is advantageous.

Scheme 1 below shows the synthesis of a pyrene derivative which is dihalogen-substituted in the 1,3-position and which is additionally substituted in the 7-position by an alkyl group. This compound represents an important intermediate in the synthesis of the compounds according to the invention (for the synthesis cf. Angew. Chem. Int. Ed. 2008, 41, 10175).

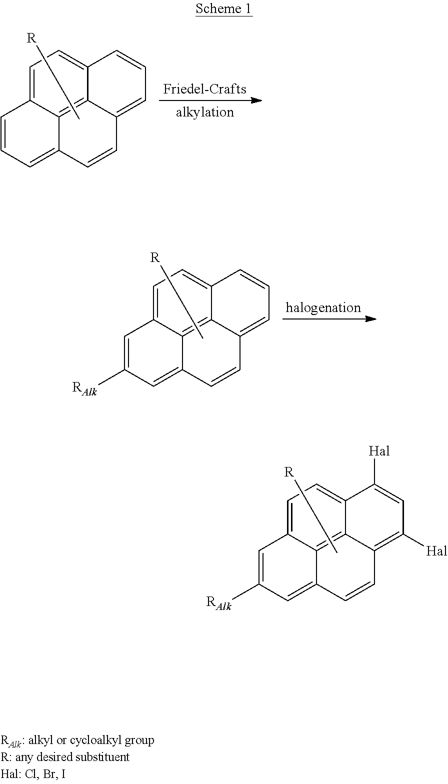

To this end, firstly pyrene is monoalkylated selectively in the 7-position in a Friedel-Crafts reaction. A halogen substituent is subsequently introduced in each of the 1- and 3-positions of the pyrene in a halogenation reaction, preferably a bromination reaction.

Starting from the intermediate from Scheme 1, Scheme 2 shows the synthesis of compounds according to the invention which are substituted by a diarylamino group in each of the 1- and 3-positions of the pyrene skeleton.

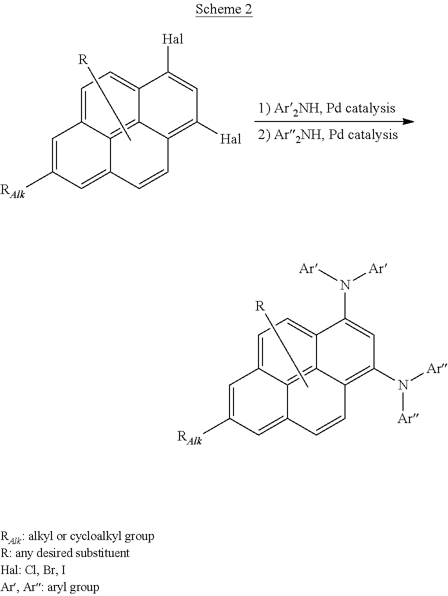

To this end, the dihalogenated compound can be reacted sequentially firstly with a first arylamino group in a first Buchwald coupling and subsequently with a second arylamino group in a second Buchwald coupling. In this way, two different diarylamino groups can be introduced. Alternatively, the reaction can also be carried out in one step with simultaneous introduction of two identical diarylamino groups in the 1- and 3-position of the pyrene.

Again starting from the intermediate from Scheme 1, Scheme 3 shows the synthesis of a pyrene derivative according to the invention which carries an arylamino group in the 1-position and carries an arylamino-substituted aryl group in the 3-position.

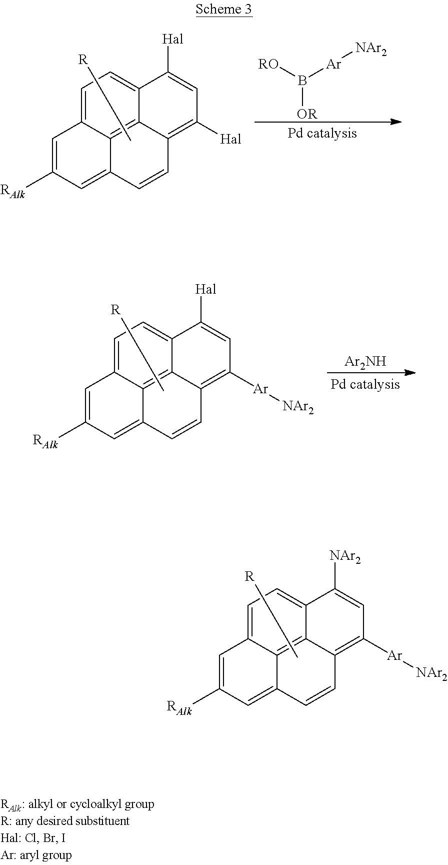

To this end, firstly the aryl group is coupled to the di-halogen-substituted intermediate in a Suzuki reaction. The diarylamino group is subsequently introduced by a Buchwald coupling.

The two reaction steps can also be carried out in the reverse sequence.

Furthermore, as shown in Scheme 4, pyrene derivatives according to the invention which carry two diarylamino-substituted aryl groups in the 1- and 3-position can also be prepared from the di-halogen-substituted intermediate from Scheme 1 by double Suzuki reaction.

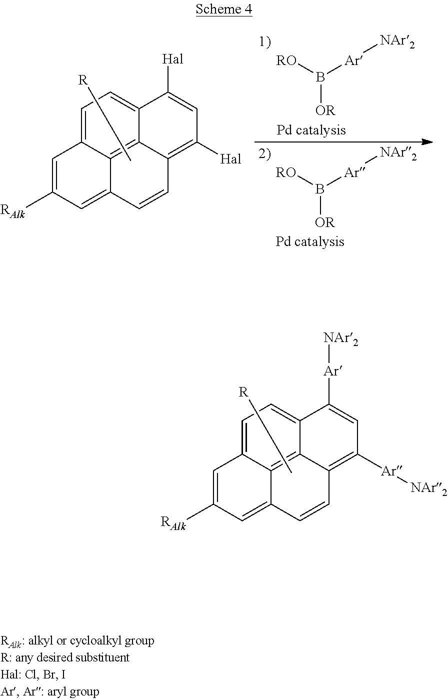

The invention thus furthermore relates to a process for the preparation of a compound of the formula (I), characterised in that one or more aryl and/or arylamino groups are introduced on the pyrene skeleton by means of organometallic coupling reaction, preferably Suzuki and/or Buchwald reaction.

The compounds according to the invention described above, in particular compounds which are substituted by reactive leaving groups, such as bromine, iodine, chlorine, boronic acid or boronic acid ester, can be used as monomers for the preparation of corresponding oligomers, dendrimers or polymers. The oligomerisation or polymerisation here is preferably carried out via the halogen functionality or the boronic acid functionality.

The invention therefore furthermore relates to oligomers, polymers or dendrimers comprising one or more compounds of the formula (I), where the bond(s) to the polymer, oligomer or dendrimer may be localised at any desired positions in formula (I) which are substituted by R². Depending on the linking of the compound of the formula (I), the compound is part of a side chain of the oligomer or polymer or part of the main chain. An oligomer in the sense of this invention is taken to mean a compound which is built up from at least three monomer units. A polymer in the sense of the invention is taken to mean a compound which is built up from at least ten monomer units. The polymers, oligomers or dendrimers according to the invention may be conjugated, partially conjugated or non-conjugated. The oligomers or polymers according to the invention may be linear, branched or dendritic. In the structures linked in a linear manner, the units of the formula (I) may be linked directly to one another or linked to one another via a divalent group, for example via a substituted or unsubstituted alkylene group, via a heteroatom or via a divalent aromatic or heteroaromatic group. In branched and dendritic structures, three or more units of the formula (I) may, for example, be linked via a trivalent or polyvalent group, for example via a trivalent or polyvalent aromatic or heteroaromatic group, to give a branched or dendritic oligomer or polymer.

The same preferences as described above for compounds of the formula (I) apply to the recurring units of the formula (I) in oligomers, dendrimers and polymers.

For the preparation of the oligomers or polymers, the monomers according to the invention are homopolymerised or copolymerised with further monomers. Suitable and preferred comonomers are selected from fluorenes (for example in accordance with EP 842208 or WO 00/22026), spirobifluorenes (for example in accordance with EP 707020, EP 894107 or WO 06/061181), para-phenylenes (for example in accordance with WO 92/18552), carbazoles (for example in accordance with WO 04/070772 or WO 04/113468), thiophenes (for example in accordance with EP 1028136), dihydrophenanthrenes (for example in accordance with WO 05/014689 or WO 07/006,383), cis- and trans-indenofluorenes (for example in accordance with WO 04/041901 or WO 04/113412), ketones (for example in accordance with WO 05/040302), phenanthrenes (for example in accordance with WO 05/104264 or WO 07/017,066) or also a plurality of these units. The polymers, oligomers and dendrimers usually also contain further units, for example emitting (fluorescent or phosphorescent) units, such as, for example, vinyltriarylamines (for example in accordance with WO 07/068,325) or phosphorescent metal complexes (for example in accordance with WO 06/003000), and/or charge-transport units, in particular those based on triarylamines.

The polymers, oligomers and dendrimers according to the invention have advantageous properties, in particular long lifetimes, high efficiencies, low operating voltage and good colour coordinates.

The polymers and oligomers according to the invention are generally prepared by polymerisation of one or more types of monomer, at least one monomer of which results in recurring units of the formula (I) in the polymer. Suitable polymerisation reactions are known to the person skilled in the art and are described in the literature. Particularly suitable and preferred polymerisation reactions which result in C—C or C—N links are the following:

(A) SUZUKI polymerisation;

(B) YAMAMOTO polymerisation;

(C) STILLE polymerisation; and

(D) HARTWIG-BUCHWALD polymerisation.

The way in which the polymerisation can be carried out by these methods and the way in which the polymers can then be separated off from the reaction medium and purified is known to the person skilled in the art and is described in detail in the literature, for example in WO 03/048225, WO 2004/037887 and WO 2004/037887.

The present invention thus also relates to a process for the preparation of the polymers, oligomers and dendrimers according to the invention, which is characterised in that they are prepared by SUZUKI polymerisation, YAMAMOTO polymerisation, STILLE polymerisation or HARTWIG-BUCHWALD polymerisation. The dendrimers according to the invention can be prepared by processes known to the person skilled in the art or analogously thereto. Suitable processes are described in the literature, such as, for example, in Frechet, Jean M. J.; Hawker, Craig J., “Hyper-branched polyphenylene and hyperbranched polyesters: new soluble, three-dimensional, reactive polymers”, Reactive & Functional Polymers (1995), 26(1-3), 127-36; Janssen, H. M.; Meijer, E. W., “The synthesis and characterization of dendritic molecules”, Materials Science and Technology (1999), 20 (Synthesis of Polymers), 403-458; Tomalia, Donald A., “Dendrimer molecules”, Scientific American (1995), 272(5), 62-6; WO 02/067343 A1 and WO 2005/026144 A1.

The processing of the compounds according to the invention from the liquid phase, for example by spin coating or by printing processes, requires formulations of the compounds according to the invention. These formulations can be, for example, solutions, dispersions or mini-emulsions. It may be preferred to use mixtures of two or more solvents for this purpose. Suitable and preferred solvents are, for example, toluene, anisole, o-, m- or p-xylene, methyl benzoate, dimethylanisole, mesitylene, tetralin, veratrol, THF, methyl-THF, THP, chlorobenzene, dioxane or mixtures of these solvents.

The invention therefore furthermore relates to a formulation, in particular a solution, dispersion or mini-emulsion, comprising at least one compound of the formula (I) or at least one polymer, oligomer or dendrimer containing at least one unit of the formula (I) and at least one solvent, preferably an organic solvent. The way in which solutions of this type can be prepared is known to the person skilled in the art and is described, for example, in WO 2002/072714, WO 2003/019694 and the literature cited therein.

The compounds of the formula (I) according to the invention are suitable for use in electronic devices, in particular in organic electroluminescent devices (OLEDs). Depending on the substitution, the compounds are employed in various functions and layers.

In a preferred embodiment of the invention, the compounds of the formula (I) are employed as emitter materials in an emission layer. In this case, the group Y is preferably equal to —N(Ar¹)—. However, the compounds of the formula (I) can also be employed in other layers and/or functions, for example as matrix materials in an emission layer or as hole-transport materials in a hole-transport layer. In the latter case, the group Y is preferably equal to —N(Ar¹)—. Furthermore, the use as electron-transport material in an electron-transport layer is also possible. In this case, the group Y is preferably equal to —P(═O)(Ar¹)—, —S(═O)— or —S(═O)₂—.

The invention therefore furthermore relates to the use of the compounds of the formula (I) according to the invention in electronic devices. The electronic devices here are preferably selected from the group consisting of organic integrated circuits (O-ICs), organic field-effect transistors (O-FETs), organic thin-film transistors (O-TFTs), organic light-emitting transistors (O-LETs), organic solar cells (O-SCs), organic optical detectors, organic photoreceptors, organic field-quench devices (O-FQDs), light-emitting electrochemical cells (LECs), organic laser diodes (O-lasers) and particularly preferably selected from organic electroluminescent devices (OLEDs).

According to a preferred embodiment of the invention, the compounds of the formula (I) are employed in an emitting layer. In this case, the group Y is preferably equal to —N(Ar¹)—. They can either be employed here as emitter material (emitting dopant) or as matrix material for an emitter material. The compounds of the formula (I) are particularly preferably used as emitter material.

If the compound of the formula (I) is employed as emitter material (dopant) in an emitting layer, it is preferably employed in combination with a matrix material. A matrix material is taken to mean the component in a system comprising matrix and dopant which is present in the higher proportion in the system. In the case of a system comprising a matrix material and a plurality of dopants, the matrix material is taken to mean the component whose proportion in the mixture is the highest.

The proportion of the compound of the formula (I) in the mixture of the emitting layer in the case of use as emitter material is between 0.1 and 50.0% by vol., preferably between 0.5 and 20.0% by vol., particularly preferably between 1.0 and 10.0% by vol. Correspondingly, the proportion of the matrix material is between 50.0 and 99.9% by vol., preferably between 80.0 and 99.5% by vol., particularly preferably between 90.0 and 99.0% by vol.

In general, suitable for use as matrix materials in combination with emitter materials of the formula (I) are the preferred matrix materials mentioned in one of the following sections.

In a further embodiment of the present invention, the compounds of the formula (I) are employed as matrix material in combination with one or more dopants, preferably phosphorescent dopants.

A dopant is taken to mean the component whose proportion in the mixture is the smaller in a system comprising a matrix material and a dopant. Correspondingly, a matrix material is taken to mean the component whose proportion in the mixture is the greater in a system comprising a matrix material and a dopant.

The proportion of the matrix material in the emitting layer is in this case between 50.0 and 99.9% by vol., preferably between 80.0 and 99.5% by vol. and particularly preferably between 85.0 and 97.0% by vol. Correspondingly, the proportion of the dopant is between 0.1 and 50.0% by vol., preferably between 0.5 and 20.0% by vol. and particularly preferably between 3.0 and 15.0% by vol.

An emitting layer of an organic electroluminescent device may also comprise systems comprising a plurality of matrix materials (mixed-matrix systems) and/or a plurality of dopants. In this case too, the dopants are generally the materials whose proportion in the system is the smaller and the matrix materials are the materials whose proportion in the system is the greater. In individual cases, however, the proportion of an individual matrix material in the system may be smaller than the proportion of an individual dopant.

In a preferred embodiment of the invention, the compounds of the formula (I) are used as a component of mixed-matrix systems. The mixed-matrix systems preferably comprise two or three different matrix materials, particularly preferably two different matrix materials. The two different matrix materials here may be present in a ratio of 1:10 to 1:1, preferably in a ratio of 1:4 to 1:1.

The mixed-matrix systems may comprise one or more dopants. The dopant compound or the dopant compounds together have, in accordance with the invention, a proportion of 0.1 to 50.0% by vol. in the mixture as a whole and preferably a proportion of 0.5 to 20.0% by vol. in the mixture as a whole. Correspondingly, the matrix components together have a proportion of 50.0 to 99.9% by vol. in the mixture as a whole and preferably a proportion of 80.0 to 99.5% by vol. in the mixture as a whole.

Mixed-matrix systems are preferably employed in phosphorescent organic electroluminescent devices.

Particularly suitable matrix materials, which can be employed in combination with the compounds according to the invention as matrix components of a mixed-matrix system, are aromatic ketones, aromatic phosphine oxides or aromatic sulfoxides or sulfones, for example in accordance with WO 04/013080, WO 04/093207, WO 06/005627 or WO 10/006,680, triarylamines, carbazole derivatives, for example CBP (N,N-biscarbazolyl-biphenyl) or the carbazole derivatives disclosed in WO 05/039246, US 2005/0069729, JP 2004/288381, EP 1205527 or WO 08/086,851, indolocarbazole derivatives, for example in accordance with WO 07/063,754 or WO 08/056,746, azacarbazole derivatives, for example in accordance with EP 1617710, EP 1617711, EP 1731584, JP 2005/347160, bipolar matrix materials, for example in accordance with WO 07/137,725, silanes, for example in accordance with WO 05/111172, azaboroles or boronic esters, for example in accordance with WO 06/117052, triazine derivatives, for example in accordance with WO 10/015,306, WO 07/063,754 or WO 08/056,746, zinc complexes, for example in accordance with EP 652273 or WO 09/062,578, diazasilole or tetraazasilole derivatives, for example in accordance with WO 10/054,729, diazaphosphole derivatives, for example in accordance with WO 10/054,730, or indenocarbazole derivatives, for example in accordance with WO 2010/136109.

Preferred phosphorescent dopants for use in mixed-matrix systems comprising the compounds according to the invention are the phosphorescent dopants mentioned in a following table.

In a further preferred embodiment of the invention, the compounds of the formula (I) are employed as hole-transport material. In this case, the group Y is preferably equal to —N(Ar¹)—. The compounds are then preferably employed in a hole-transport layer and/or in a hole-injection layer. A hole-injection layer in the sense of this invention is a layer which is directly adjacent to the anode. A hole-transport layer in the sense of this invention is a layer which is located between the hole-injection layer and the emission layer. The hoe-transport layer may be directly adjacent to the emission layer. If the compounds of the formula (I) are used as hole-transport material, it may be preferred for them to be doped with electron-acceptor compounds, for example with F₄-TCNQ or with compounds as described in EP 1476881 or EP 1596445. In a further preferred embodiment of the invention, a compound of the formula (I) is used as hole-transport material in combination with a hexaazatriphenylene derivative, as described in US 2007/0092755. The hexaazatriphenylene derivative is particularly preferably employed in its own layer here.

Thus, preference is given, for example, to the following structure: anode-hexaazatriphenylene derivative-hole-transport layer, where the hole-transport layer comprises one or more compounds of the formula (I). It is likewise possible to use a plurality of successive hole-transport layers in this structure, where at least one hole-transport layer comprises at least one compound of the formula (I). The following structure is likewise preferred: anode-hole-transport layer-hexaazatriphenylene derivative-hole-transport layer, where at least one of the two hole-transport layers comprises one or more compounds of the formula (I). It is likewise possible in this structure for a plurality of successive hole-transport layers to be used instead of one hole-transport layer, where at least one hole-transport layer comprises at least one compound of the formula (I).

If the compound of the formula (I) is employed as hole-transport material in a hole-transport layer, the compound can be employed as pure material, i.e. in a proportion of 100%, in the hole-transport layer or it can be employed in combination with one or more further compounds in the hole-transport layer.

In a further preferred embodiment of the present invention, the compounds of the formula (I) are employed as electron-transport material, preferably in an electron-transport layer. In this case, the group Y is preferably equal to —P(═O)(Ar¹)—, —S(═O)— or —S(═O)₂—.

On use of the compounds of the formula (I) as electron-transport materials, it may be preferred for the compounds to be employed in combination with a further electron-transport material. Particularly suitable electron-transport materials which can be employed in combination with the compounds according to the invention are, for example, the electron-transport materials shown as preferred in one of the following tables or the materials disclosed in Y. Shirota et al., Chem. Rev. 2007, 107(4), 953-1010.

If the compound of the formula (I) and one of the electron-transport materials mentioned above are present in the form of a mixture, the ratio of the compound of the formula (I) to the electron-transport material is preferably 20:80 to 80:20, particularly preferably 30:70 to 70:30 and very particularly preferably 30:70 to 50:50, in each case based on the volume.

If the compounds of the formula (I) are employed as electron-transport material in an organic electroluminescent device, they can, in accordance with the invention, be employed in combination with an organic or inorganic alkali-metal compound. “In combination with an organic alkali-metal compound” here means that the compounds of the formula (I) and the alkali-metal compound are either in the form of a mixture in one layer or separately in two successive layers. In a preferred embodiment of the invention, the compounds of the formula (I) and the organic alkali-metal compound are in the form of a mixture in one layer.

An organic alkali-metal compound in the sense of this invention is intended to be taken to mean a compound which contains at least one alkali metal, i.e. lithium, sodium, potassium, rubidium or caesium, and which furthermore contains at least one organic ligand. Suitable organic alkali-metal compounds are, for example, the compounds disclosed in WO 07/050,301, WO 07/050,334 and EP 1144543. These are incorporated into the present application by way of reference.

The invention likewise relates to electronic devices comprising at least one compound of the formula (I). The electronic devices here are preferably selected from the devices mentioned above. Particular preference is given to organic electroluminescent devices comprising anode, cathode and at least one emitting layer, characterised in that at least one organic layer, which may be an emitting layer, a hole-transport layer or another layer, comprises at least one compound of the formula (I).

Apart from cathode, anode and the emitting layer, the organic electroluminescent device may also comprise further layers. These are selected, for example, from in each case one or more hole-injection layers, hole-trans-port layers, hole-blocking layers, electron-transport layers, electron-injection layers, electron-blocking layers, exciton-blocking layers, charge-generation layers (IDMC 2003, Taiwan; Session 21 OLED (5), T. Matsumoto, T. Nakada, J. Endo, K. Mori, N. Kawamura, A. Yokoi, J. Kido, Multiphoton Organic EL Device Having Charge Generation Layer), coupling-out layers and/or organic or inorganic p/n junctions. However, it should be pointed out that each of these layers does not necessarily have to be present and the choice of layers is always dependent on the compounds used and in particular also on whether the electroluminescent device is fluorescent or phosphorescent.

The organic electroluminescent device may also comprise a plurality of emitting layers. These emission layers in this case particularly preferably have in total a plurality of emission maxima between 380 nm and 750 nm, resulting overall in white emission, i.e. various emitting compounds which are able to fluoresce or phosphoresce and which emit blue and yellow, orange or red light are used in the emitting layers. Particular preference is given to three-layer systems, i.e. systems having three emitting layers, where one or more of these layers may comprise a compound of the formula (I) and where the three layers exhibit blue, green and orange or red emission (for the basic structure see, for example, WO 05/011013). Emitters which have broad-band emission bands and thus exhibit white emission are likewise suitable for white emission in such systems. Alternatively and/or additionally, the compounds according to the invention may also be present in a hole-transport layer or in another layer in such systems.

The functional materials preferably employed in the electronic devices comprising one or more compounds according to the invention are indicated below.

Suitable phosphorescent dopants (=triplet emitters) are, in particular, compounds which emit light, preferably in the visible region, on suitable excitation and in addition contain at least one atom having an atomic number greater than 20, preferably greater than 38 and less than 84, particularly preferably greater than 56 and less than 80. The phosphorescent emitters used are preferably compounds which contain copper, molybdenum, tungsten, rhenium, ruthenium, osmium, rhodium, iridium, palladium, platinum, silver, gold or europium, in particular compounds which contain iridium, platinum or copper.

For the purposes of the present invention, all luminescent iridium, platinum or copper complexes are regarded as phosphorescent compounds.

Examples of the emitters described above are revealed by the applications WO 00/70655, WO 01/41512, WO 02/02714, WO 02/15645, EP 1191613, EP 1191612, EP 1191614, WO 05/033244, WO 05/019373 and US 2005/0258742. In general, all phosphorescent complexes as used in accordance with the prior art for phosphorescent OLEDs and as are known to the person skilled in the art in the area of organic electroluminescent devices are suitable. The person skilled in the art will also be able to employ further phosphorescent complexes without inventive step in combination with the compounds of the formula (I) according to the invention in organic electroluminescent devices.

Examples of suitable phosphorescent emitter compounds are furthermore revealed by the following table:

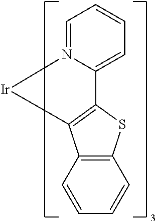

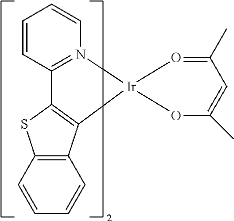

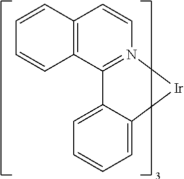

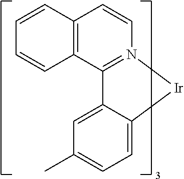

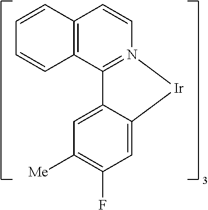

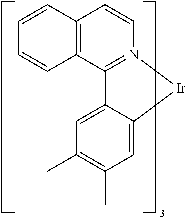

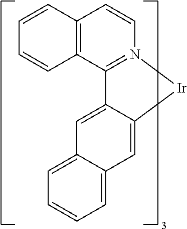

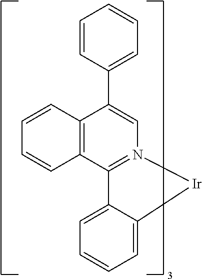

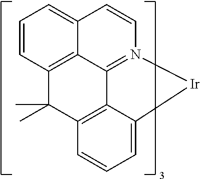

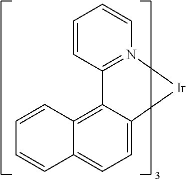

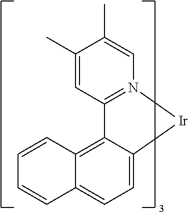

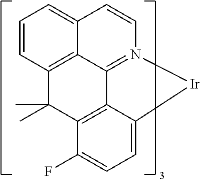

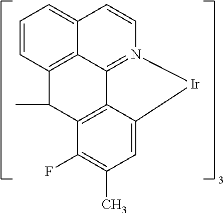

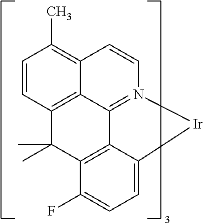

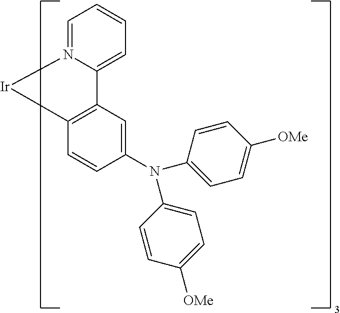

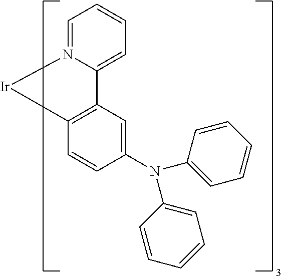

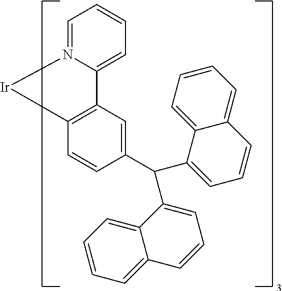

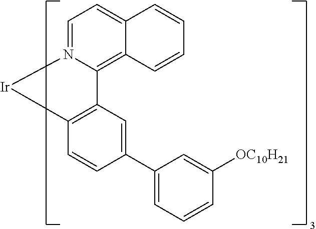

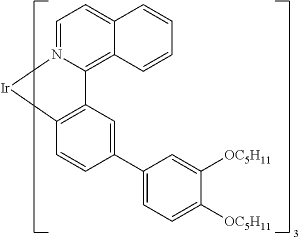

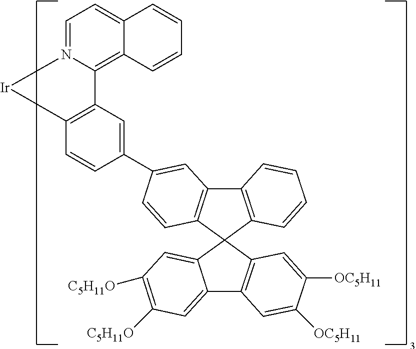

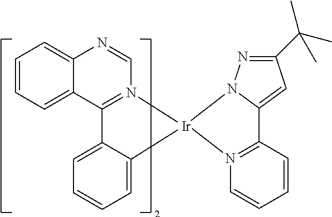

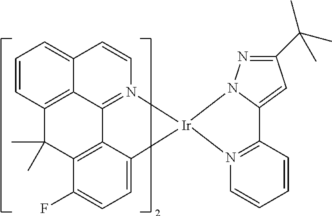

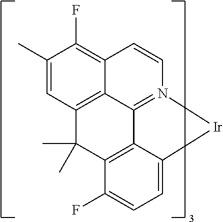

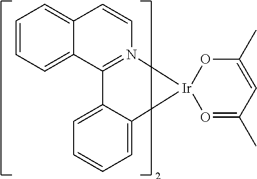

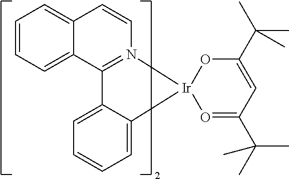

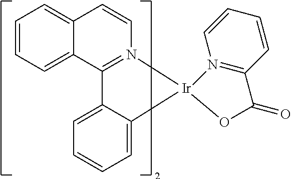

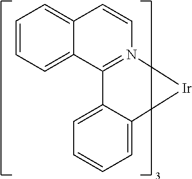

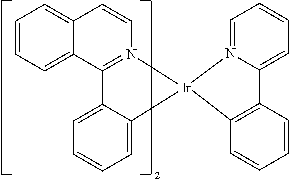

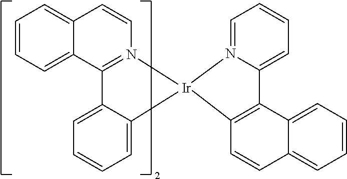

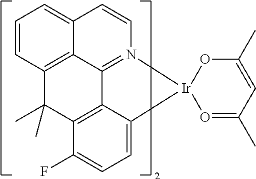

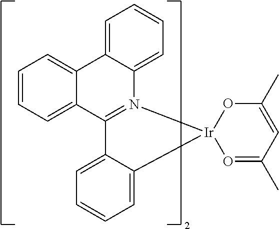

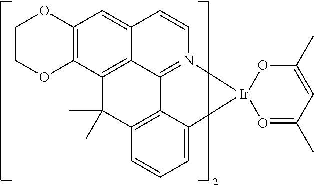

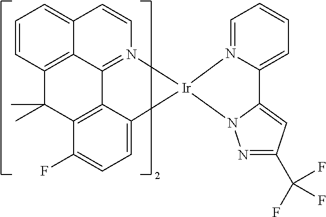

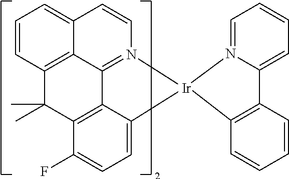

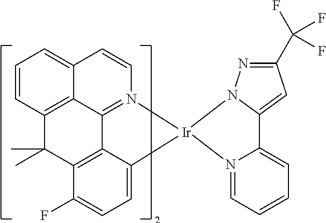

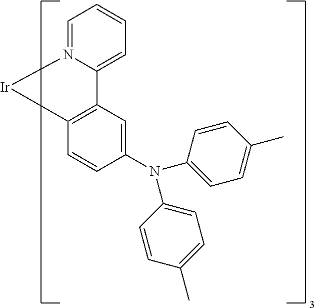

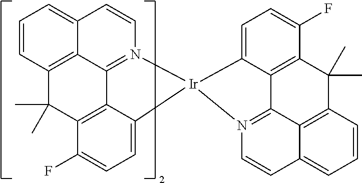

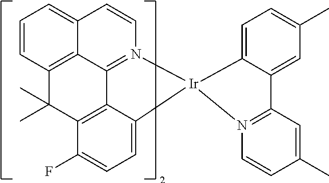

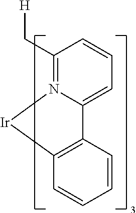

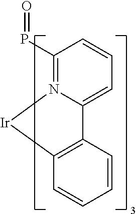

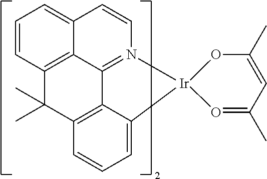

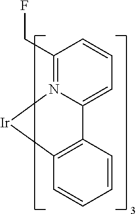

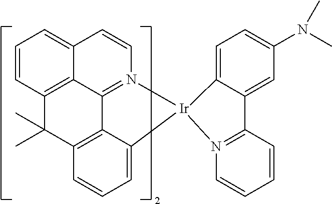

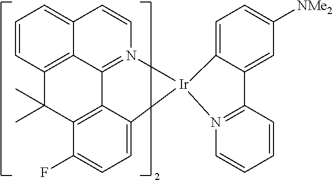

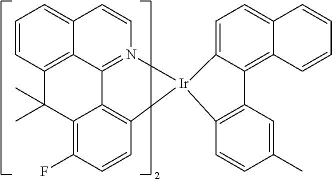

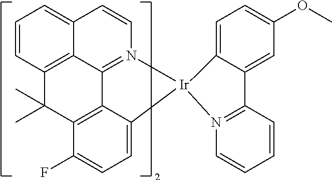

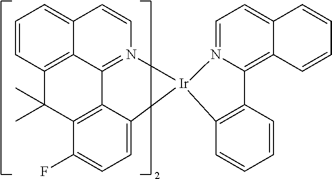

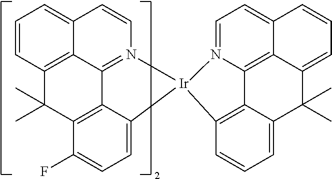

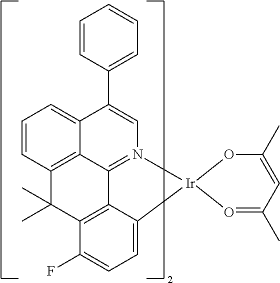

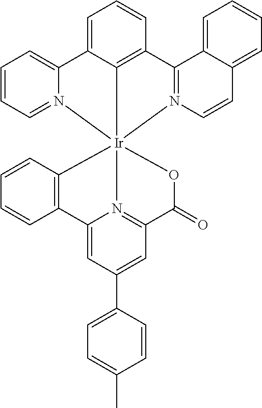

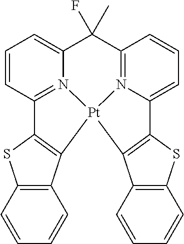

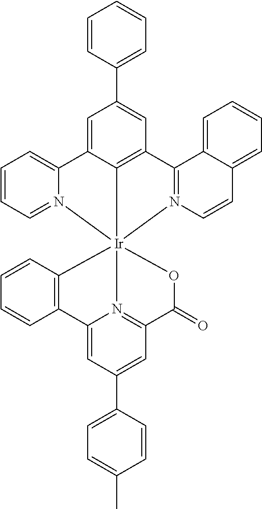

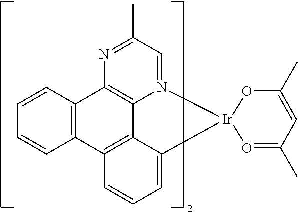

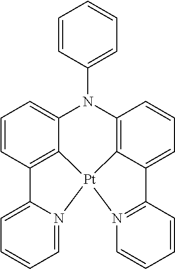

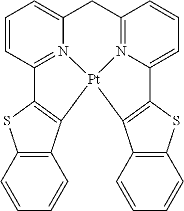

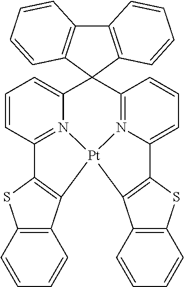

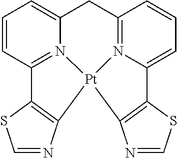

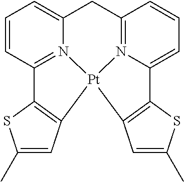

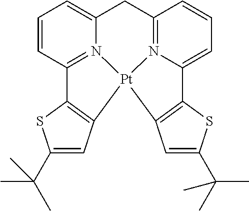

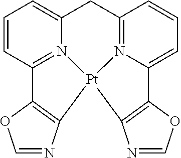

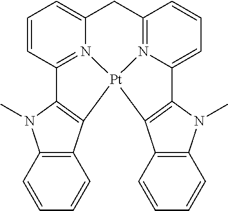

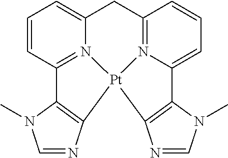

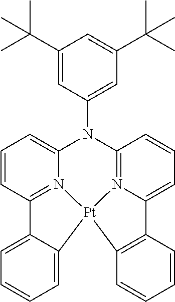

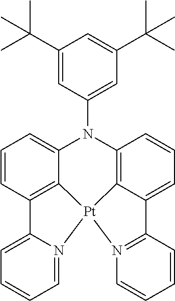

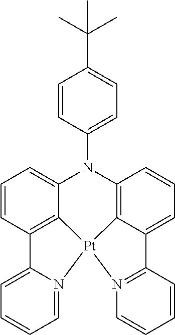

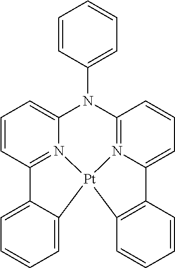

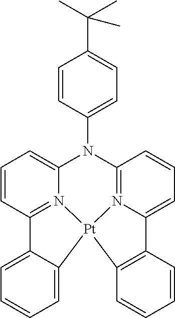

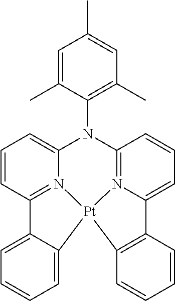

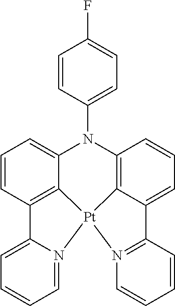

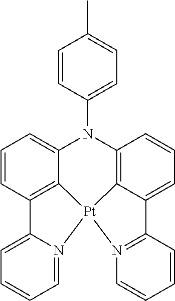

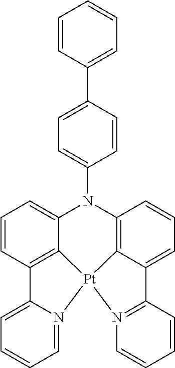

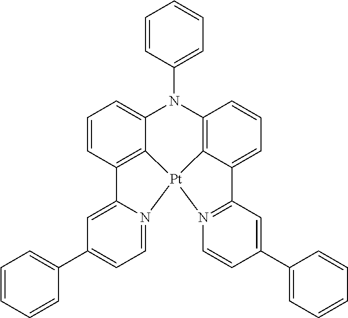

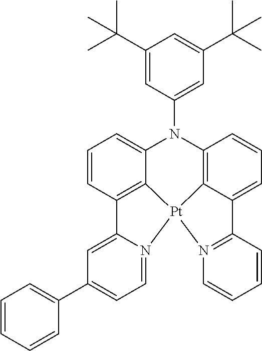

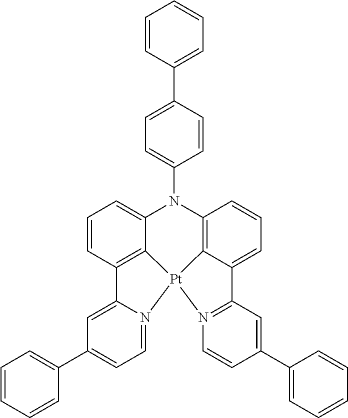

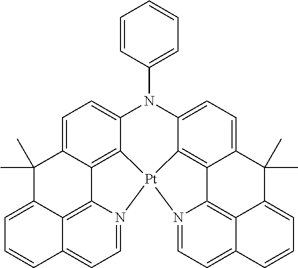

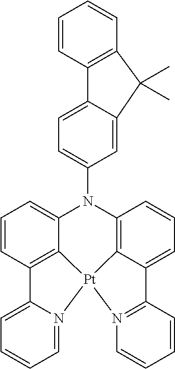

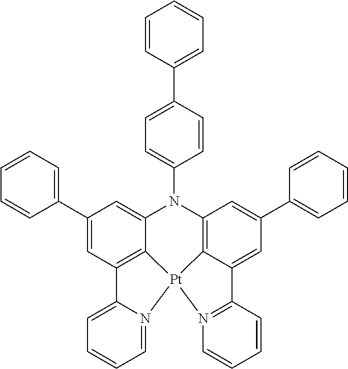

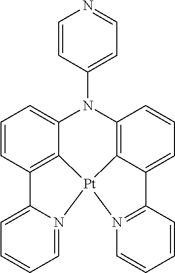

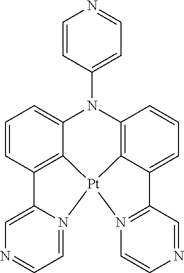

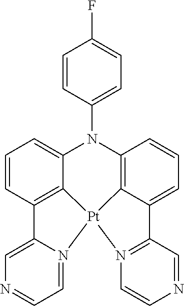

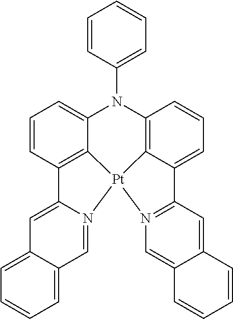

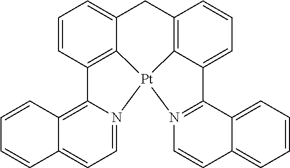

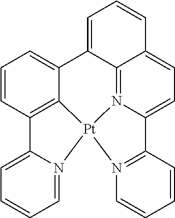

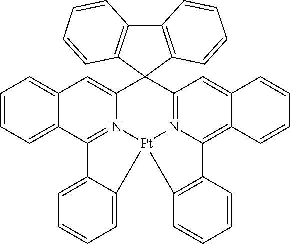

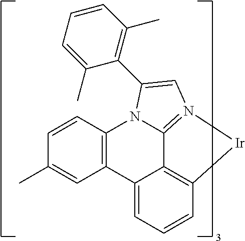

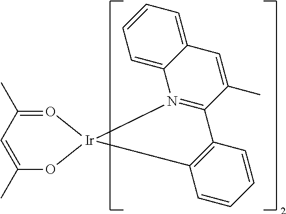

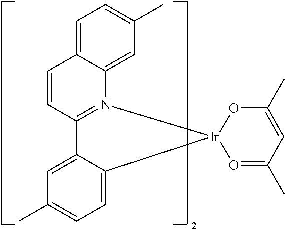

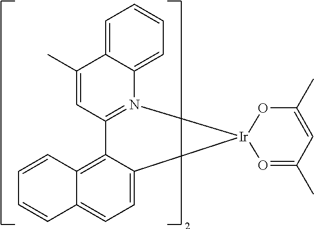

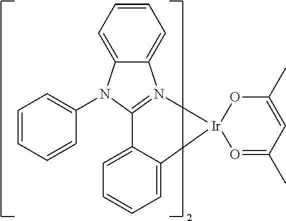

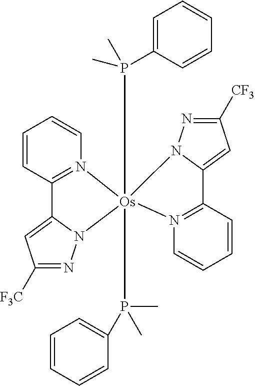

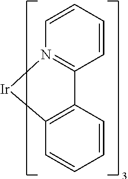

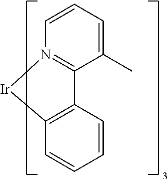

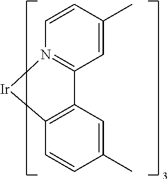

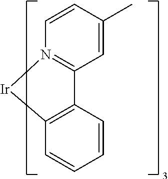

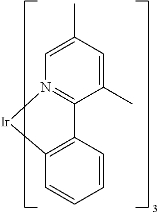

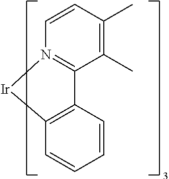

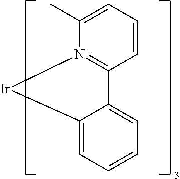

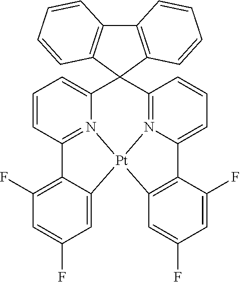

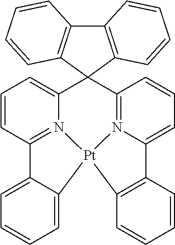

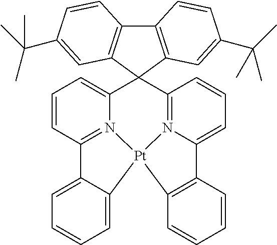

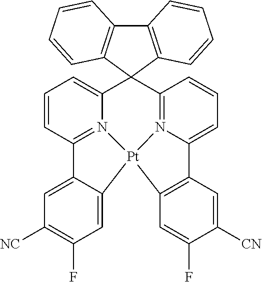

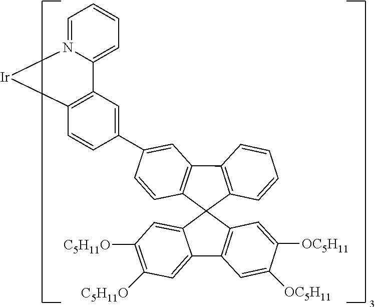

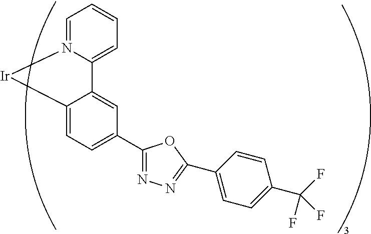

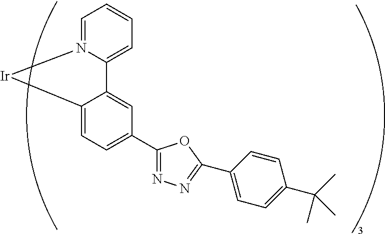

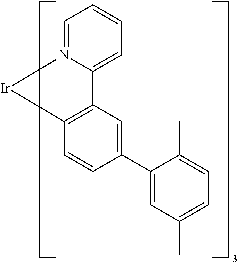

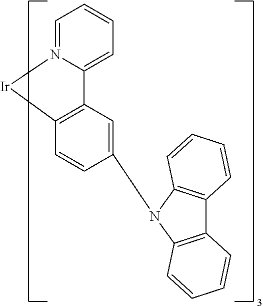

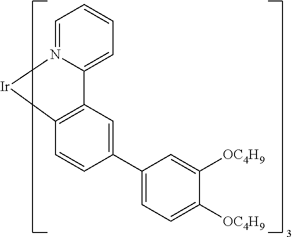

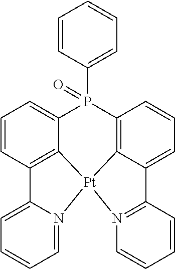

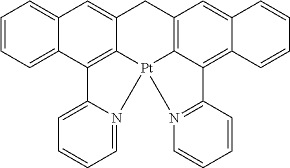

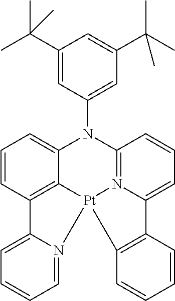

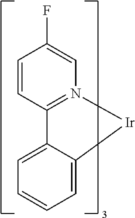

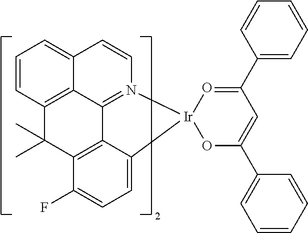

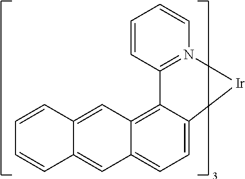

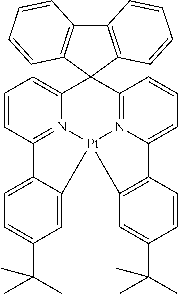

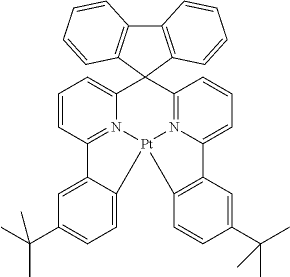

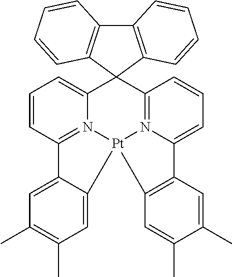

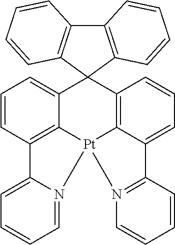

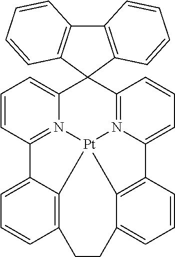

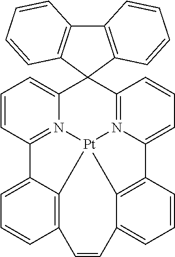

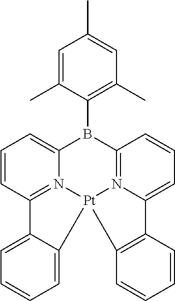

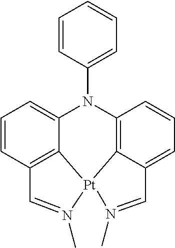

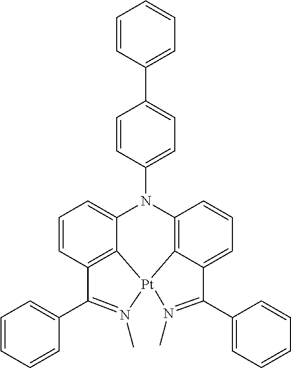

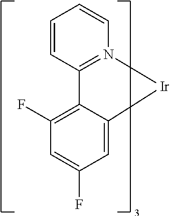

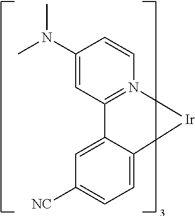

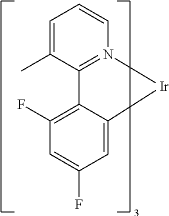

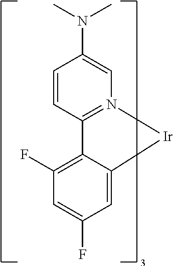

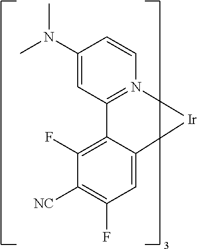

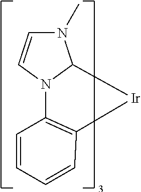

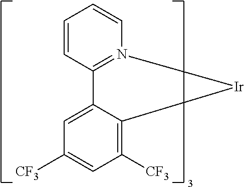

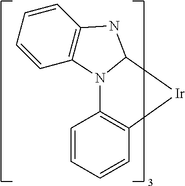

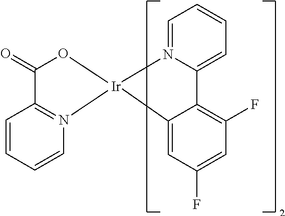

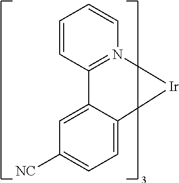

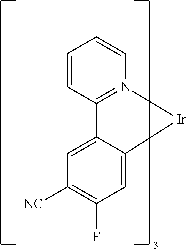

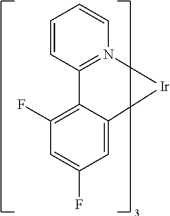

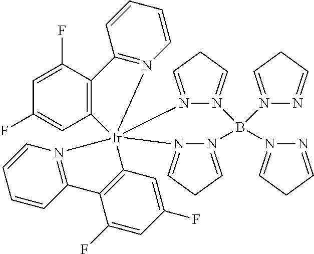

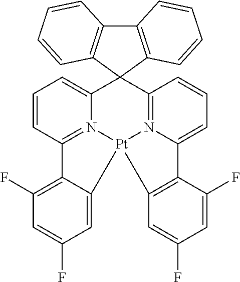

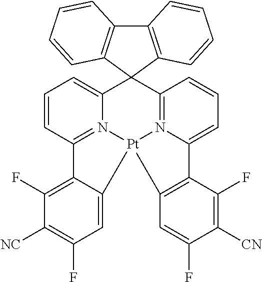

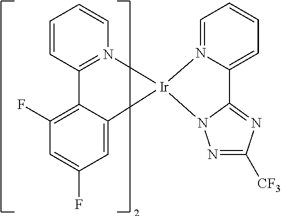

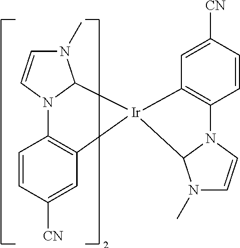

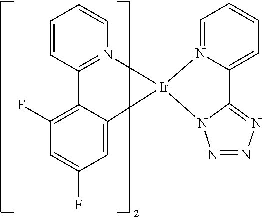

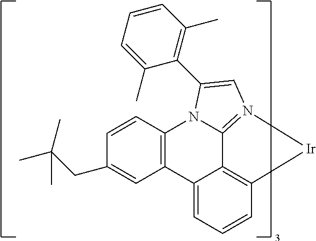

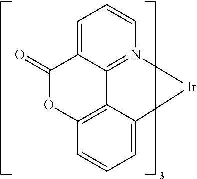

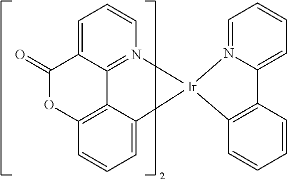

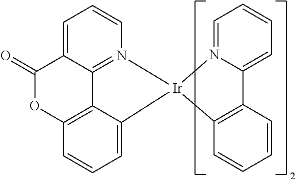

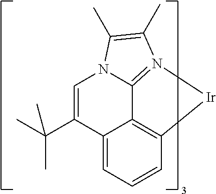

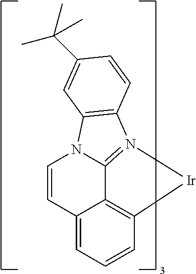

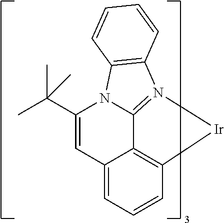

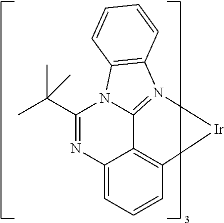

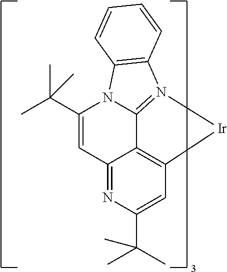

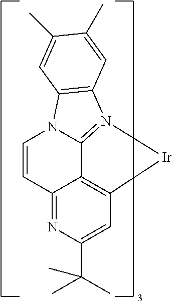

Preferred fluorescent dopants, apart from the compounds of the formula (I), are selected from the class of the arylamines. An arylamine or aromatic amine in the sense of this invention is taken to mean a compound which contains three substituted or unsubstituted aromatic or heteroaromatic ring systems bonded directly to the nitrogen. At least one of these aromatic or heteroaromatic ring systems is preferably a condensed ring system, particularly preferably having at least 14 aromatic ring atoms. Preferred examples thereof are aromatic anthracenamines, aromatic anthracenediamines, aromatic pyrenamines, aromatic pyrenediamines, aromatic chrysenamines, aromatic chrysenediamines or aromatic phenanthrenediamines. An aromatic anthracenamine is taken to mean a compound in which one diarylamino group is bonded directly to an anthracene group, preferably in the 9-position. An aromatic anthracenediamine is taken to mean a compound in which two diarylamino groups are bonded directly to an anthracene group, preferably in the 9,10-position. Aromatic pyrenamines, pyrenediamines, chrysenamines and chrysenediamines are defined analogously thereto, where the diarylamino groups are preferably bonded to the pyrene in the 1-position or in the 1,6-position. Further preferred fluorescent dopants are selected from indenofluorenamines or indenofluorenediamines, for example in accordance with WO 06/122630, benzoindenofluorenamines or benzoindenofluorenediamines, for example in accordance with WO 08/006,449, and dibenzoindenofluorenamines or dibenzoindenofluorenediamines, for example in accordance with WO 07/140,847. Examples of fluorescent dopants from the class of the styrylamines are substituted or unsubstituted tristilbenamines or the fluorescent dopants described in WO 06/000388, WO 06/058737, WO 06/000389, WO 07/065,549 and WO 07/115,610. Preference is furthermore given to the condensed hydrocarbons disclosed in WO 2010/012328.

Suitable matrix materials, preferably for use in combination with fluorescent dopants and particularly preferably in combination with the compounds of the formula (I), are materials from various classes of substance. Preferred compounds in this case are selected from the classes of the oligoarylenes (for example 2,2′,7,7-tetraphenylspirobifluorene in accordance with EP 676461 or dinaphthylanthracene), in particular the oligoarylenes containing condensed aromatic groups, the oligoarylenevinylenes (for example DPVBi or spiro-DPVBi in accordance with EP 676461), the polypodal metal complexes (for example in accordance with WO 04/081017), the hole-conducting compounds (for example in accordance with WO 04/058911), the electron-conducting compounds, in particular ketones, phosphine oxides, sulfoxides, etc. (for example in accordance with WO 05/084081 and WO 05/084082), the atropisomers (for example in accordance with WO 06/048268), the boronic acid derivatives (for example in accordance with WO 06/117052) or the benzanthracenes (for example in accordance with WO 08/145,239). Suitable matrix materials are furthermore preferably the compounds according to the invention. Particularly preferred matrix materials are selected from the classes of the oligoarylenes, comprising naphthalene, anthracene, benzanthracene and/or pyrene or atropisomers of these compounds, the oligoarylenevinylenes, the ketones, the phosphine oxides and the sulfoxides. Very particularly preferred matrix materials are selected from the classes of the oligoarylenes, comprising anthracene, benzanthracene, benzophenanthrene and/or pyrene or atropisomers of these compounds. An oligoarylene in the sense of this invention is intended to be taken to mean a compound in which at least three aryl or arylene groups are bonded to one another.

Suitable matrix materials, preferably for fluorescent dopants, are, for example, the materials depicted in the following table, and derivatives of these materials, as disclosed in WO 04/018587, WO 08/006,449, U.S. Pat. No. 5,935,721, US 2005/0181232, JP 2000/273056, EP 681019, US 2004/0247937 and US 2005/0211958.

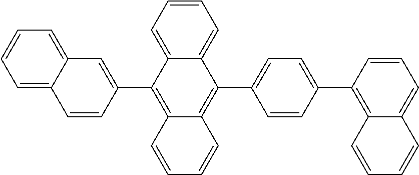 [SMILES: c1ccc2cc(-c3c4ccccc4c(-c4ccc(-c5cccc6ccccc56)cc4)c4ccccc34)ccc2c1]

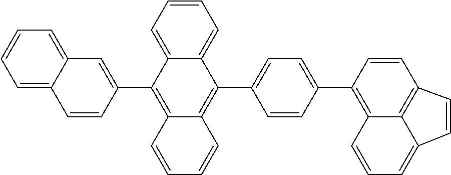 [SMILES: C1=Cc2ccc(-c3ccc(-c4c5ccccc5c(-c5ccc6ccccc6c5)c5ccccc45)cc3)c3cccc1c23]

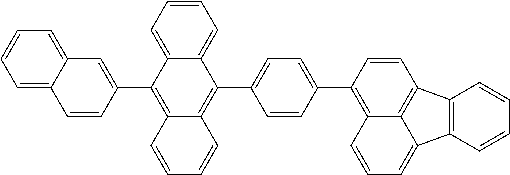 [SMILES: c1ccc2c(c1)-c1cccc3c(-c4ccc(-c5c6ccccc6c(-c6ccc7ccccc7c6)c6ccccc56)cc4)ccc-2c13]

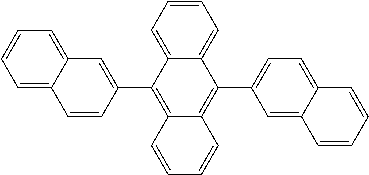 [SMILES: c1ccc2cc(-c3c4ccccc4c(-c4ccc5ccccc5c4)c4ccccc34)ccc2c1]

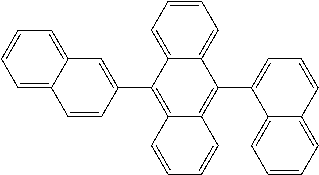 [SMILES: c1ccc2cc(-c3c4ccccc4c(-c4cccc5ccccc45)c4ccccc34)ccc2c1]

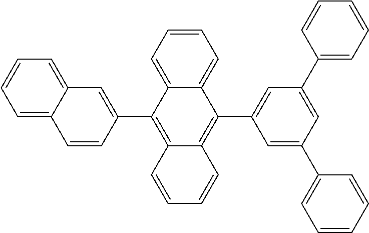 [SMILES: c1ccc(-c2cc(-c3ccccc3)cc(-c3c4ccccc4c(-c4ccc5ccccc5c4)c4ccccc34)c2)cc1]

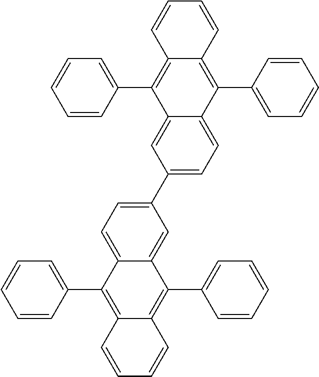 [SMILES: c1ccc(-c2c3ccccc3c(-c3ccccc3)c3cc(-c4ccc5c(-c6ccccc6)c6ccccc6c(-c6ccccc6)c5c4)ccc23)cc1]

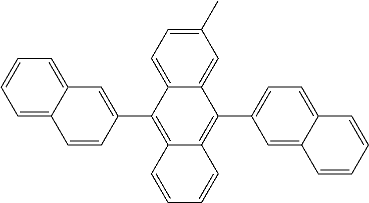 [SMILES: Cc1ccc2c(-c3ccc4ccccc4c3)c3ccccc3c(-c3ccc4ccccc4c3)c2c1]

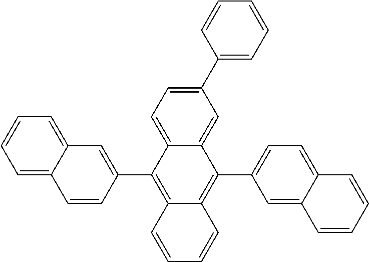 [SMILES: c1ccc(-c2ccc3c(-c4ccc5ccccc5c4)c4ccccc4c(-c4ccc5ccccc5c4)c3c2)cc1]

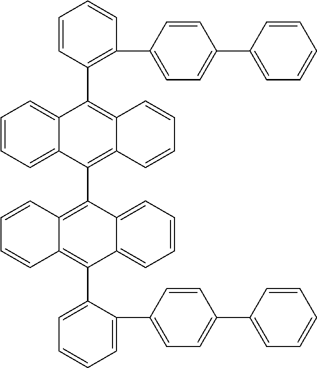 [SMILES: c1ccc(-c2ccc(-c3ccccc3-c3c4ccccc4c(-c4c5ccccc5c(-c5ccccc5-c5ccc(-c6ccccc6)cc5)c5ccccc45)c4ccccc34)cc2)cc1]

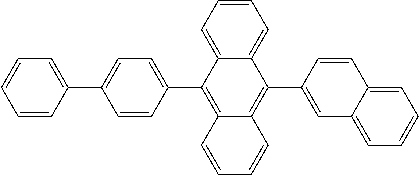 [SMILES: c1ccc(-c2ccc(-c3c4ccccc4c(-c4ccc5ccccc5c4)c4ccccc34)cc2)cc1]

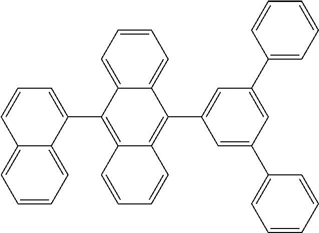 [SMILES: c1ccc(-c2cc(-c3ccccc3)cc(-c3c4ccccc4c(-c4cccc5ccccc45)c4ccccc34)c2)cc1]

| | |
|---|---|
| 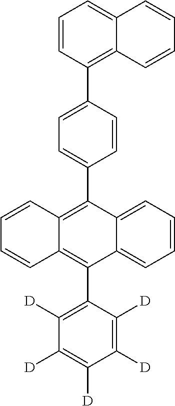 [SMILES: [2H]c1c([2H])c([2H])c(-c2c3ccccc3c(-c3ccc(-c4cccc5ccccc45)cc3)c3ccccc23)c([2H])c1[2H]] | 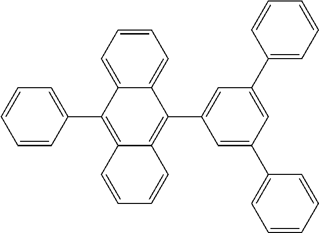 [SMILES: c1ccc(-c2cc(-c3ccccc3)cc(-c3c4ccccc4c(-c4ccccc4)c4ccccc34)c2)cc1] |

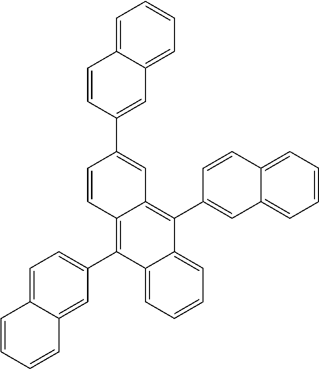 [SMILES: c1ccc2cc(-c3ccc4c(-c5ccc6ccccc6c5)c5ccccc5c(-c5ccc6ccccc6c5)c4c3)ccc2c1]

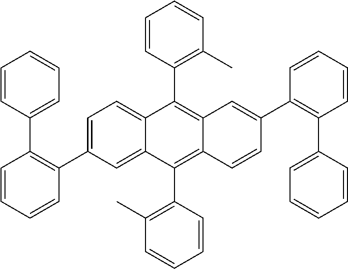 [SMILES: Cc1ccccc1-c1c2ccc(-c3ccccc3-c3ccccc3)cc2c(-c2ccccc2C)c2ccc(-c3ccccc3-c3ccccc3)cc12]

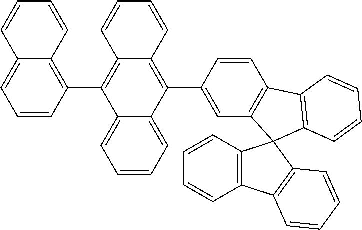 [SMILES: c1ccc2c(c1)-c1ccccc1C21c2ccccc2-c2ccc(-c3c4ccccc4c(-c4cccc5ccccc45)c4ccccc34)cc21]

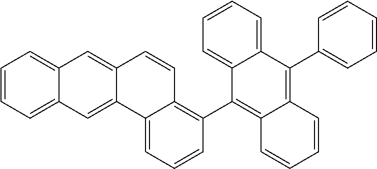 [SMILES: c1ccc(-c2c3ccccc3c(-c3cccc4c3ccc3cc5ccccc5cc34)c3ccccc23)cc1]

| | |
|---|---|
| 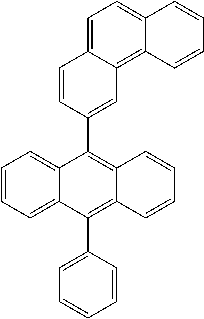 [SMILES: c1ccc(-c2c3ccccc3c(-c3ccc4ccc5ccccc5c4c3)c3ccccc23)cc1] | 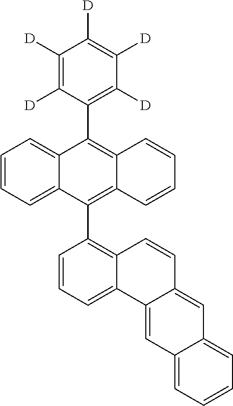 [SMILES: [2H]c1c([2H])c([2H])c(-c2c3ccccc3c(-c3cccc4c3ccc3cc5ccccc5cc34)c3ccccc23)c([2H])c1[2H]] |

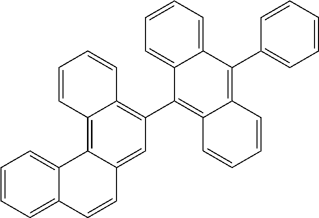 [SMILES: c1ccc(-c2c3ccccc3c(-c3cc4ccc5ccccc5c4c4ccccc34)c3ccccc23)cc1]

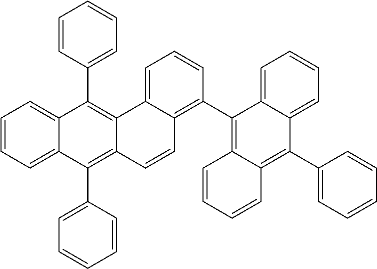 [SMILES: c1ccc(-c2c3ccccc3c(-c3cccc4c3ccc3c(-c5ccccc5)c5ccccc5c(-c5ccccc5)c34)c3ccccc23)cc1]

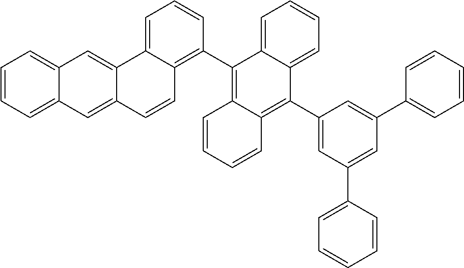 [SMILES: c1ccc(-c2cc(-c3ccccc3)cc(-c3c4ccccc4c(-c4cccc5c4ccc4cc6ccccc6cc45)c4ccccc34)c2)cc1]

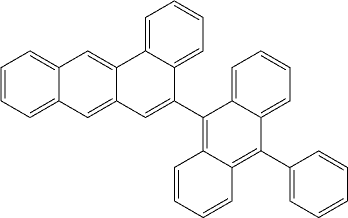 [SMILES: c1ccc(-c2c3ccccc3c(-c3cc4cc5ccccc5cc4c4ccccc34)c3ccccc23)cc1]

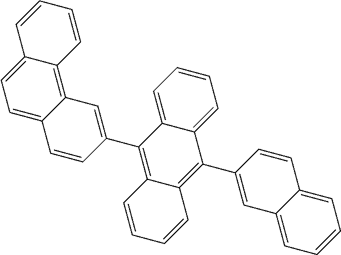 [SMILES: c1ccc2cc(-c3c4ccccc4c(-c4ccc5ccc6ccccc6c5c4)c4ccccc34)ccc2c1]

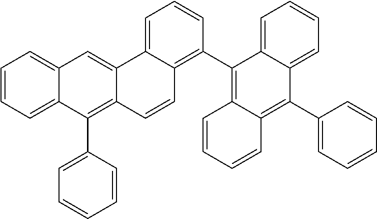 [SMILES: c1ccc(-c2c3ccccc3c(-c3cccc4c3ccc3c(-c5ccccc5)c5ccccc5cc34)c3ccccc23)cc1]

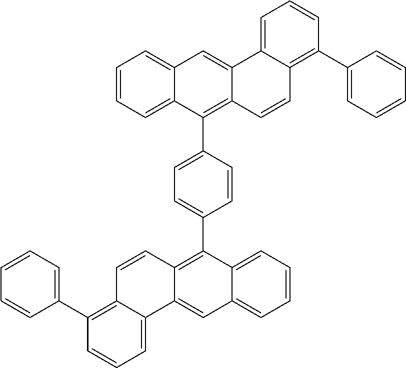 [SMILES: c1ccc(-c2cccc3c2ccc2c(-c4ccc(-c5c6ccccc6cc6c5ccc5c(-c7ccccc7)cccc56)cc4)c4ccccc4cc23)cc1]

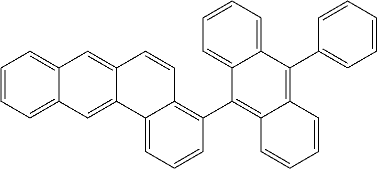 [SMILES: c1ccc(-c2c3ccccc3c(-c3cccc4c3ccc3cc5ccccc5cc34)c3ccccc23)cc1]

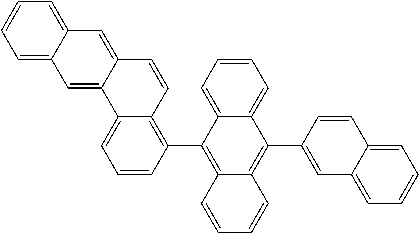 [SMILES: c1ccc2cc(-c3c4ccccc4c(-c4cccc5c4ccc4cc6ccccc6cc45)c4ccccc34)ccc2c1]

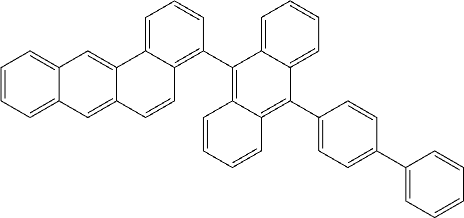 [SMILES: c1ccc(-c2ccc(-c3c4ccccc4c(-c4cccc5c4ccc4cc6ccccc6cc45)c4ccccc34)cc2)cc1]

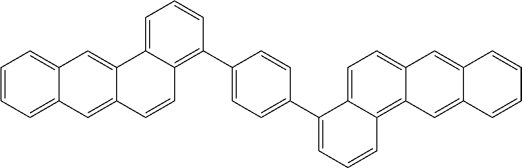 [SMILES: c1ccc2cc3c(ccc4c(-c5ccc(-c6cccc7c6ccc6cc8ccccc8cc67)cc5)cccc43)cc2c1]

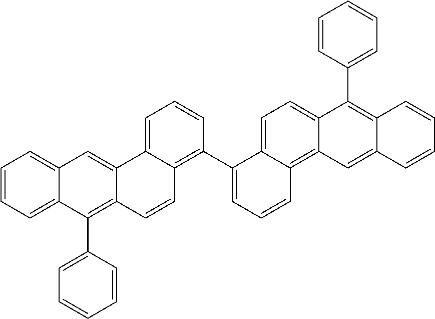 [SMILES: c1ccc(-c2c3ccccc3cc3c2ccc2c(-c4cccc5c4ccc4c(-c6ccccc6)c6ccccc6cc45)cccc23)cc1]

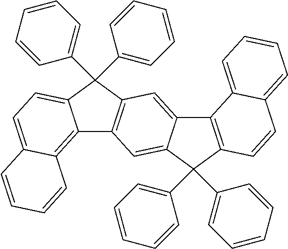 [SMILES: c1ccc(C2(c3ccccc3)c3cc4c(cc3-c3c2ccc2ccccc32)C(c2ccccc2)(c2ccccc2)c2ccc3ccccc3c2-4)cc1]

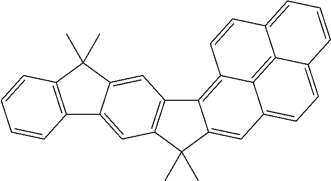 [SMILES: CC1(C)c2ccccc2-c2cc3c(cc21)-c1c(cc2ccc4cccc5ccc1c2c45)C3(C)C]

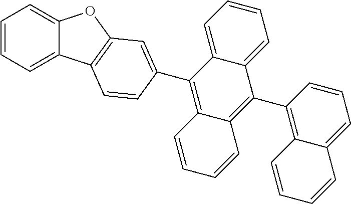 [SMILES: c1ccc2c(-c3c4ccccc4c(-c4ccc5c(c4)oc4ccccc45)c4ccccc34)cccc2c1]

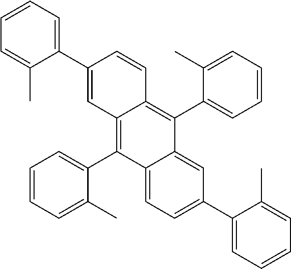 [SMILES: Cc1ccccc1-c1ccc2c(-c3ccccc3C)c3cc(-c4ccccc4C)ccc3c(-c3ccccc3C)c2c1]

| | |
|---|---|
| 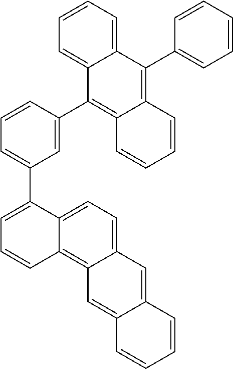 [SMILES: c1ccc(-c2c3ccccc3c(-c3cccc(-c4cccc5c4ccc4cc6ccccc6cc45)c3)c3ccccc23)cc1] | 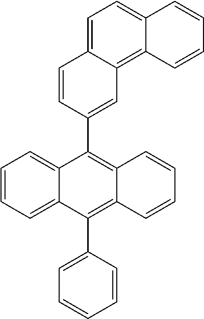 [SMILES: c1ccc(-c2c3ccccc3c(-c3ccc4ccc5ccccc5c4c3)c3ccccc23)cc1] |
| 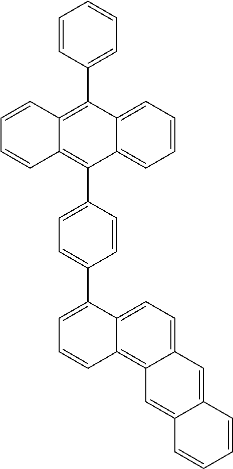 [SMILES: c1ccc(-c2c3ccccc3c(-c3ccc(-c4cccc5c4ccc4cc6ccccc6cc45)cc3)c3ccccc23)cc1] | 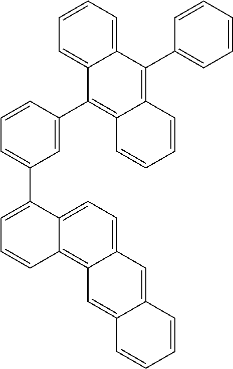 [SMILES: c1ccc(-c2c3ccccc3c(-c3cccc(-c4cccc5c4ccc4cc6ccccc6cc45)c3)c3ccccc23)cc1] |

Besides the compounds of the formula (I), suitable charge-transport materials, as can be used in the hole-injection or hole-transport layer or in the electron-transport layer of the organic electroluminescent device according to the invention, are, for example, the compounds disclosed in Y. Shirota et al., Chem. Rev. 2007, 107(4), 953-1010, or other materials as are employed in these layers in accordance with the prior art.

Examples of preferred hole-transport materials which can be used in a hole-transport or hole-injection layer in the electroluminescent device according to the invention are indenofluorenamines and derivatives (for example in accordance with WO 06/122630 or WO 06/100896), the amine derivatives disclosed in EP 1661888, hexaazatriphenylene derivatives (for example in accordance with WO 01/049806), amine derivatives with condensed aromatic rings (for example in accordance with U.S. Pat. No. 5,061,569), the amine derivatives disclosed in WO 95/09147, monobenzoindenofluorenamines (for example in accordance with WO 08/006,449) or dibenzoindenofluorenamines (for example in accordance with WO 07/140,847). Hole-transport and hole-injection materials which are furthermore suitable are derivatives of the compounds depicted above, as disclosed in JP 2001/226331, EP 676461, EP 650955, WO 01/049806, U.S. Pat. No. 4,780,536, WO 98/30071, EP 891121, EP 1661888, JP 2006/253445, EP 650955, WO 06/073054 and U.S. Pat. No. 5,061,569. The compounds of the formula (I) can also be used as hole-transport materials.

Suitable hole-transport or hole-injection materials are furthermore, for example, the materials shown in the following table.

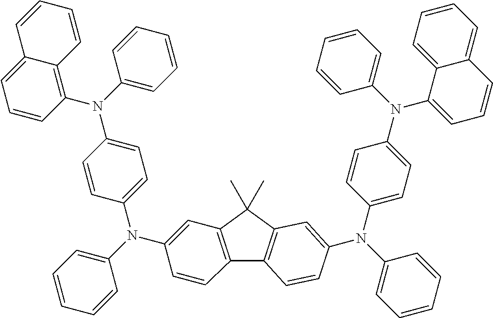 [SMILES: CC1(C)c2cc(N(c3ccccc3)c3ccc(N(c4ccccc4)c4cccc5ccccc45)cc3)ccc2-c2ccc(N(c3ccccc3)c3ccc(N(c4ccccc4)c4cccc5ccccc45)cc3)cc21]

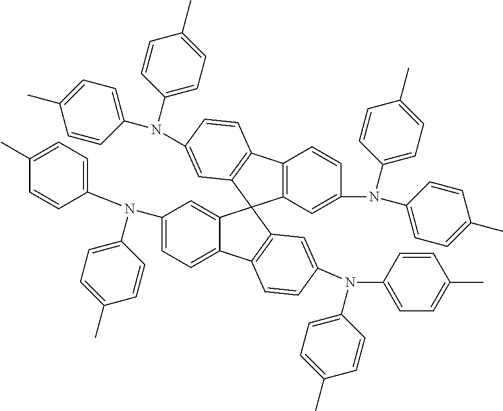

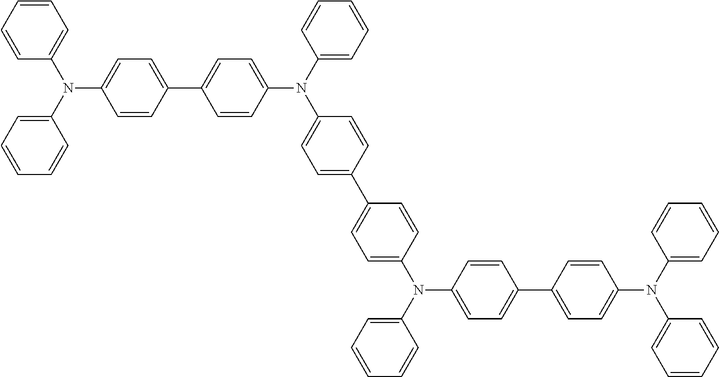 [SMILES: c1ccc(N(c2ccccc2)c2ccc(-c3ccc(N(c4ccccc4)c4ccc(-c5ccc(N(c6ccccc6)c6ccc(-c7ccc(N(c8ccccc8)c8ccccc8)cc7)cc6)cc5)cc4)cc3)cc2)cc1]

| | |
|---|---|
| 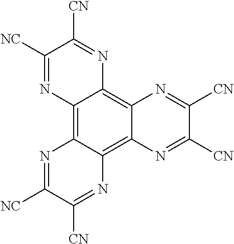 [SMILES: N#Cc1nc2c3nc(C#N)c(C#N)nc3c3nc(C#N)c(C#N)nc3c2nc1C#N] | 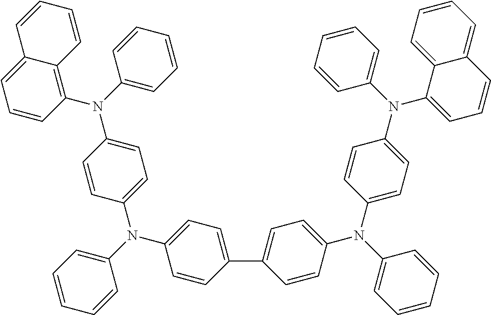 [SMILES: c1ccc(N(c2ccc(-c3ccc(N(c4ccccc4)c4ccc(N(c5ccccc5)c5cccc6ccccc56)cc4)cc3)cc2)c2ccc(N(c3ccccc3)c3cccc4ccccc34)cc2)cc1] |

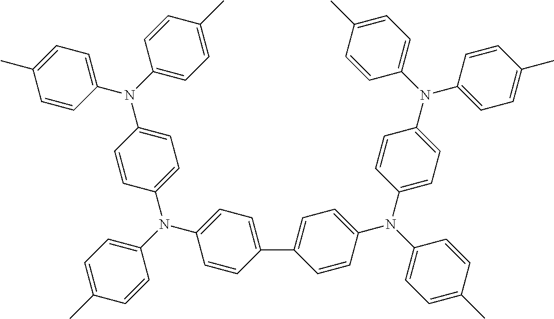

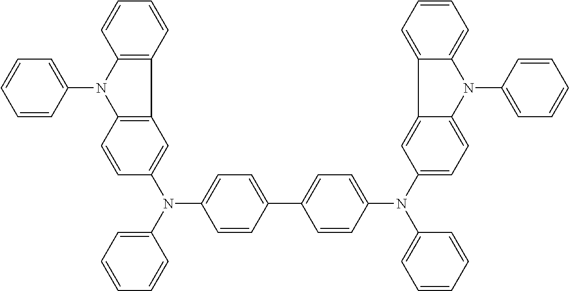 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

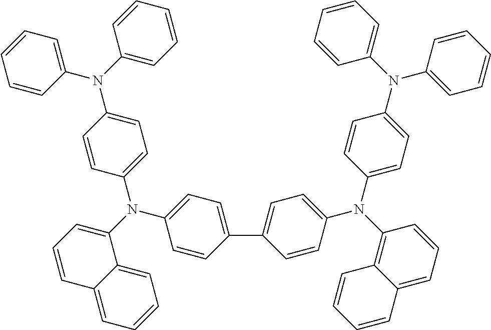 [SMILES: c1ccc(N(c2ccccc2)c2ccc(N(c3ccc(-c4ccc(N(c5ccc(N(c6ccccc6)c6ccccc6)cc5)c5cccc6ccccc56)cc4)cc3)c3cccc4ccccc34)cc2)cc1]

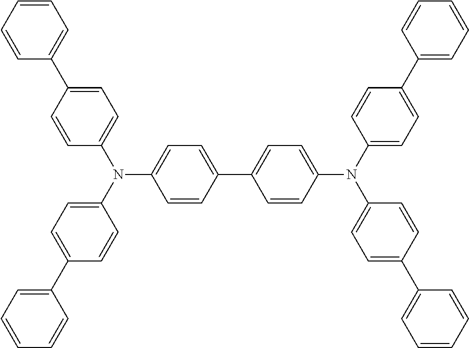 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1]

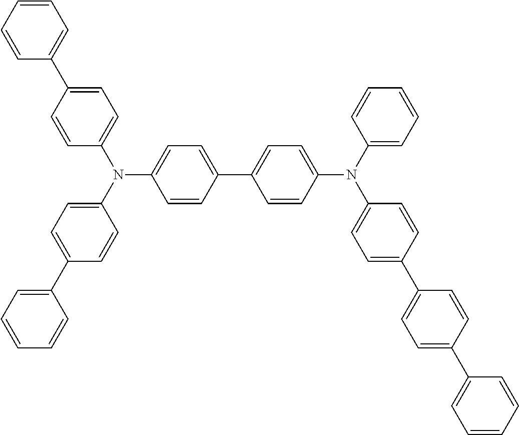 [SMILES: c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

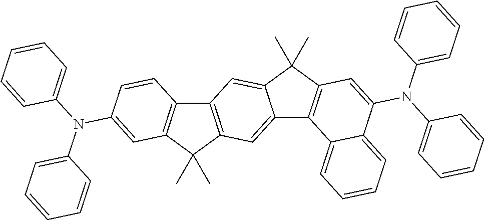 [SMILES: CC1(C)c2cc(N(c3ccccc3)c3ccccc3)ccc2-c2cc3c(cc21)-c1c(cc(N(c2ccccc2)c2ccccc2)c2ccccc12)C3(C)C]

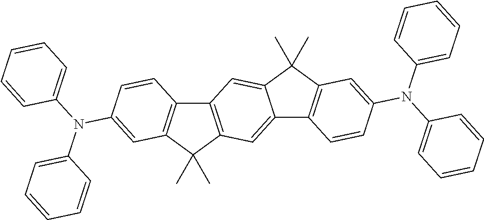 [SMILES: CC1(C)c2cc(N(c3ccccc3)c3ccccc3)ccc2-c2cc3c(cc21)-c1ccc(N(c2ccccc2)c2ccccc2)cc1C3(C)C]

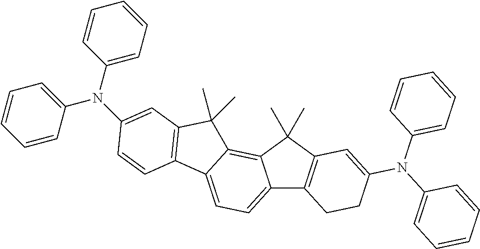 [SMILES: CC1(C)C2=C(CCC(N(c3ccccc3)c3ccccc3)=C2)c2ccc3c(c21)C(C)(C)c1cc(N(c2ccccc2)c2ccccc2)ccc1-3]

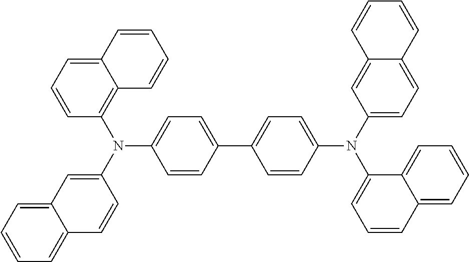 [SMILES: c1ccc2cc(N(c3ccc(-c4ccc(N(c5ccc6ccccc6c5)c5cccc6ccccc56)cc4)cc3)c3cccc4ccccc34)ccc2c1]

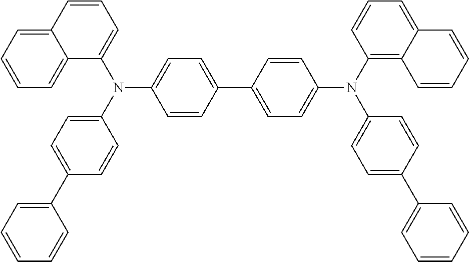 [SMILES: c1ccc(-c2ccc(N(c3ccc(-c4ccc(N(c5ccc(-c6ccccc6)cc5)c5cccc6ccccc56)cc4)cc3)c3cccc4ccccc34)cc2)cc1]

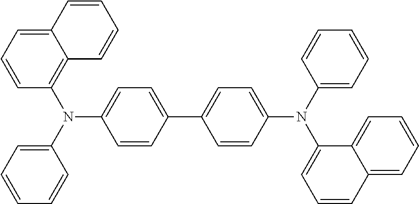 [SMILES: c1ccc(N(c2ccc(-c3ccc(N(c4ccccc4)c4cccc5ccccc45)cc3)cc2)c2cccc3ccccc23)cc1]

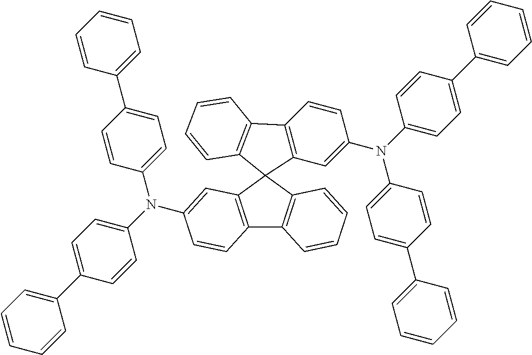 [SMILES: c1ccc(-c2ccc(N(c3ccc(-c4ccccc4)cc3)c3ccc4c(c3)C3(c5ccccc5-4)c4ccccc4-c4ccc(N(c5ccc(-c6ccccc6)cc5)c5ccc(-c6ccccc6)cc5)cc43)cc2)cc1]

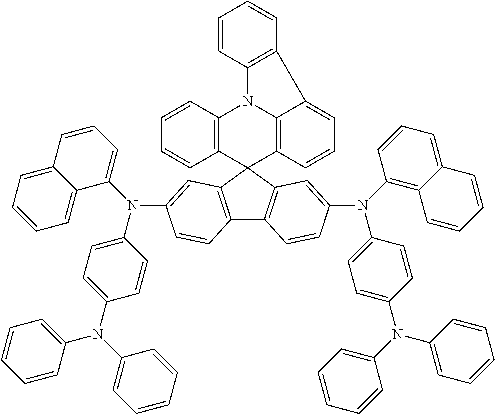 [SMILES: c1ccc(N(c2ccccc2)c2ccc(N(c3ccc4c(c3)C3(c5cc(N(c6ccc(N(c7ccccc7)c7ccccc7)cc6)c6cccc7ccccc67)ccc5-4)c4ccccc4-n4c5ccccc5c5cccc3c54)c3cccc4ccccc34)cc2)cc1]

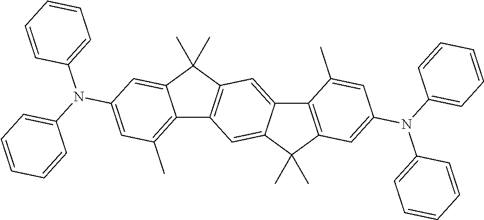 [SMILES: Cc1cc(N(c2ccccc2)c2ccccc2)cc2c1-c1cc3c(cc1C2(C)C)-c1c(C)cc(N(c2ccccc2)c2ccccc2)cc1C3(C)C]

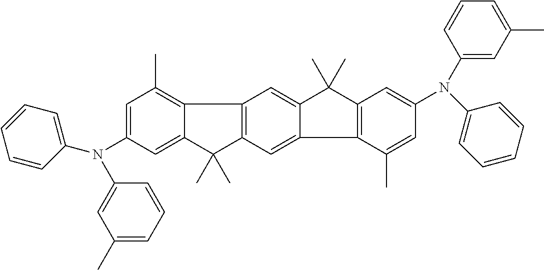 [SMILES: Cc1cccc(N(c2ccccc2)c2cc(C)c3c(c2)C(C)(C)c2cc4c(cc2-3)C(C)(C)c2cc(N(c3ccccc3)c3cccc(C)c3)cc(C)c2-4)c1]

Suitable electron-transport or electron-injection materials which can be used in the electroluminescent device according to the invention are, for example, the materials shown in the following table. Electron-transport and electron-injection materials which are furthermore suitable are, for example, AlQ₃, BAIQ, LiQ and LiF.

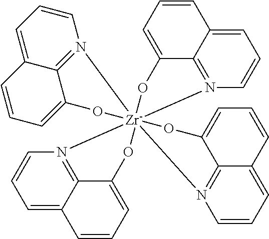

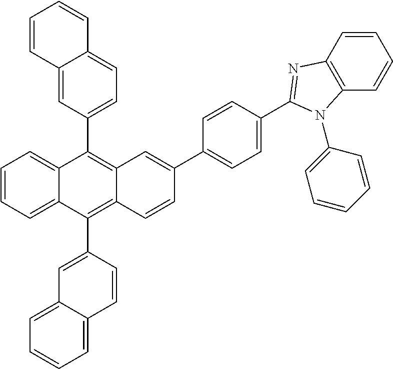 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1]

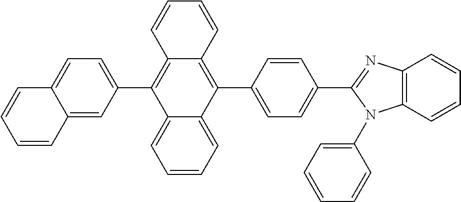 [SMILES: c1ccc(-n2c(-c3ccc(-c4c5ccccc5c(-c5ccc6ccccc6c5)c5ccccc45)cc3)nc3ccccc32)cc1]

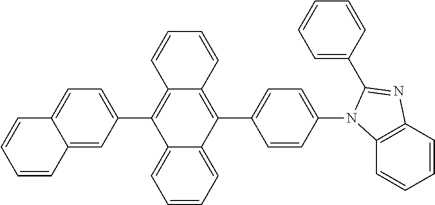 [SMILES: c1ccc(-c2nc3ccccc3n2-c2ccc(-c3c4ccccc4c(-c4ccc5ccccc5c4)c4ccccc34)cc2)cc1]

| | |
|---|---|
| 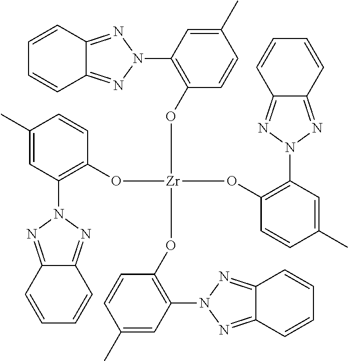 | 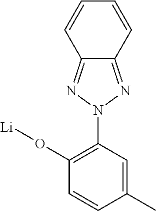 |

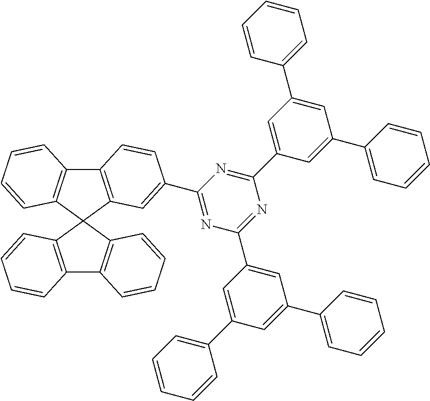 [SMILES: c1ccc(-c2cc(-c3ccccc3)cc(-c3nc(-c4cc(-c5ccccc5)cc(-c5ccccc5)c4)nc(-c4ccc5c(c4)C4(c6ccccc6-c6ccccc64)c4ccccc4-5)n3)c2)cc1]

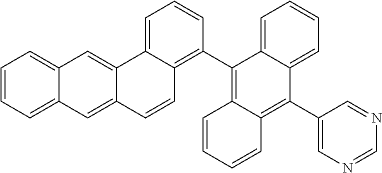 [SMILES: c1ccc2cc3c(ccc4c(-c5c6ccccc6c(-c6cncnc6)c6ccccc56)cccc43)cc2c1]

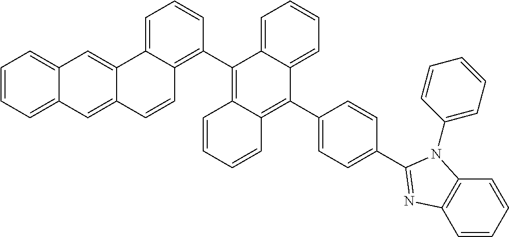 [SMILES: c1ccc(-n2c(-c3ccc(-c4c5ccccc5c(-c5cccc6c5ccc5cc7ccccc7cc56)c5ccccc45)cc3)nc3ccccc32)cc1]

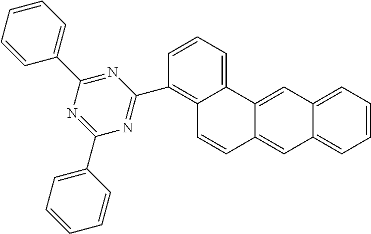 [SMILES: c1ccc(-c2nc(-c3ccccc3)nc(-c3cccc4c3ccc3cc5ccccc5cc34)n2)cc1]

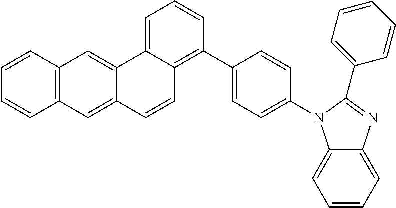 [SMILES: c1ccc(-c2nc3ccccc3n2-c2ccc(-c3cccc4c3ccc3cc5ccccc5cc34)cc2)cc1]

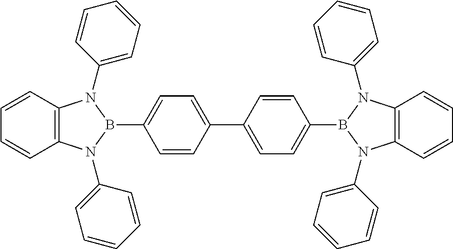 [SMILES: c1ccc(N2B(c3ccc(-c4ccc(B5N(c6ccccc6)c6ccccc6N5c5ccccc5)cc4)cc3)N(c3ccccc3)c3ccccc32)cc1]

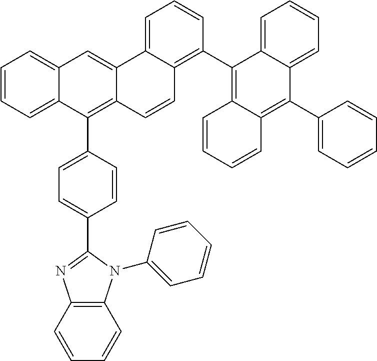 [SMILES: c1ccc(-c2c3ccccc3c(-c3cccc4c3ccc3c(-c5ccc(-c6nc7ccccc7n6-c6ccccc6)cc5)c5ccccc5cc34)c3ccccc23)cc1]

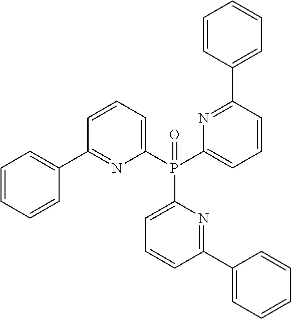 [SMILES: O=P(c1cccc(-c2ccccc2)n1)(c1cccc(-c2ccccc2)n1)c1cccc(-c2ccccc2)n1]

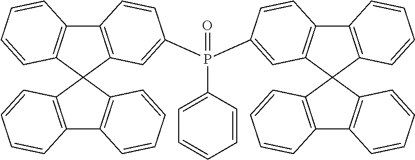 [SMILES: O=P(c1ccccc1)(c1ccc2c(c1)C1(c3ccccc3-c3ccccc31)c1ccccc1-2)c1ccc2c(c1)C1(c3ccccc3-c3ccccc31)c1ccccc1-2]

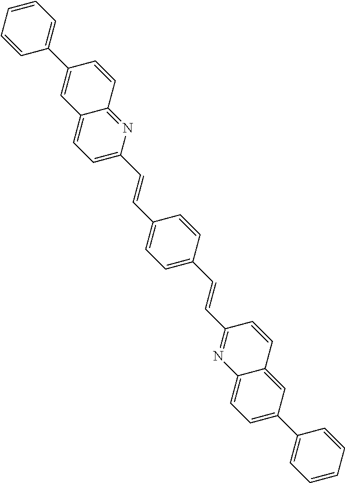 [SMILES: C(=C\c1ccc2cc(-c3ccccc3)ccc2n1)/c1ccc(/C=C/c2ccc3cc(-c4ccccc4)ccc3n2)cc1]

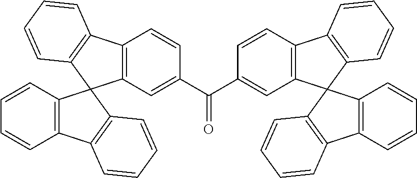 [SMILES: O=C(c1ccc2c(c1)C1(c3ccccc3-c3ccccc31)c1ccccc1-2)c1ccc2c(c1)C1(c3ccccc3-c3ccccc31)c1ccccc1-2]

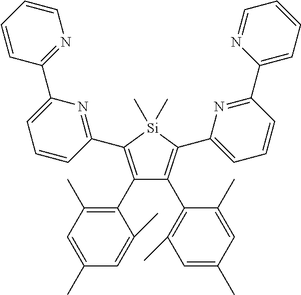 [SMILES: Cc1cc(C)c(C2=C(c3cccc(-c4ccccn4)n3)[Si](C)(C)C(c3cccc(-c4ccccn4)n3)=C2c2c(C)cc(C)cc2C)c(C)c1]

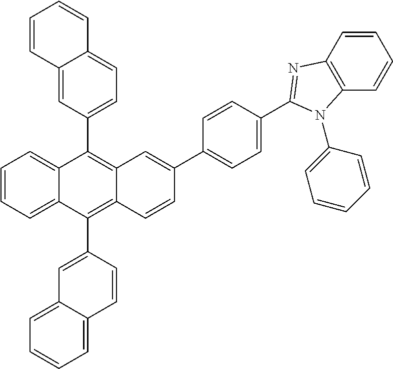 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1]

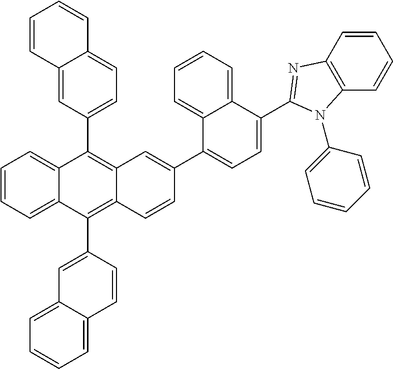 [SMILES: c1ccc(-n2c(-c3ccc(-c4ccc5c(-c6ccc7ccccc7c6)c6ccccc6c(-c6ccc7ccccc7c6)c5c4)c4ccccc34)nc3ccccc32)cc1]

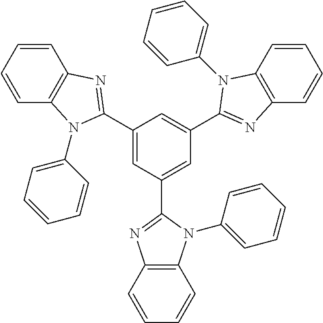 [SMILES: c1ccc(-n2c(-c3cc(-c4nc5ccccc5n4-c4ccccc4)cc(-c4nc5ccccc5n4-c4ccccc4)c3)nc3ccccc32)cc1]

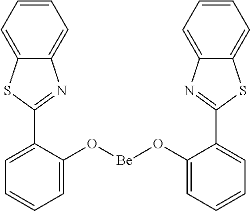

| | |
|---|---|
| 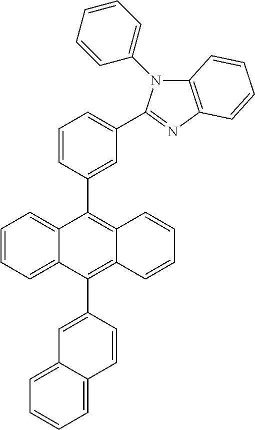 [SMILES: c1ccc(-n2c(-c3cccc(-c4c5ccccc5c(-c5ccc6ccccc6c5)c5ccccc45)c3)nc3ccccc32)cc1] | 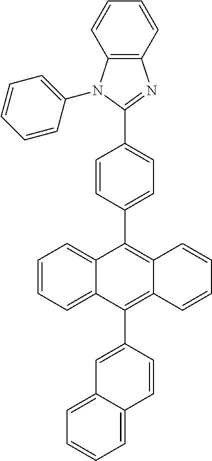 [SMILES: c1ccc(-n2c(-c3ccc(-c4c5ccccc5c(-c5ccc6ccccc6c5)c5ccccc45)cc3)nc3ccccc32)cc1] |

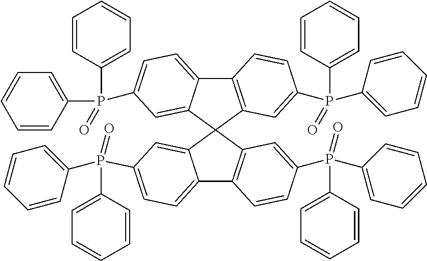 [SMILES: O=P(c1ccccc1)(c1ccccc1)c1ccc2c(c1)C1(c3cc(P(=O)(c4ccccc4)c4ccccc4)ccc3-2)c2cc(P(=O)(c3ccccc3)c3ccccc3)ccc2-c2ccc(P(=O)(c3ccccc3)c3ccccc3)cc21]

| | |
|---|---|
| 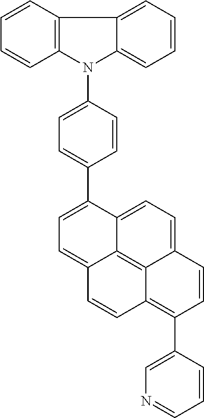 [SMILES: c1cncc(-c2ccc3ccc4c(-c5ccc(-n6c7ccccc7c7ccccc76)cc5)ccc5ccc2c3c54)c1] | 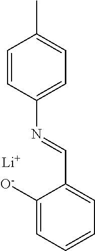 [SMILES: [Li+] ; Cc1ccc(/N=C/c2ccccc2[O-])cc1] |

The cathode of the organic electroluminescent device preferably comprises metals having a low work function, metal alloys or multilayered structures comprising various metals, such as, for example, alkaline-earth metals, alkali metals, main-group metals or lanthanoids (for example Ca, Ba, Mg, Al, In, Mg, Yb, Sm, etc.). Also suitable are alloys comprising an alkali metal or alkaline-earth metal and silver, for example an alloy comprising magnesium and silver. In the case of multilayered structures, further metals which have a relatively high work function, such as, for example, Ag or Al, can also be used in addition to the said metals, in which case combinations of the metals, such as, for example, Ca/Ag, Ba/Ag or Mg/Ag, are generally used. It may also be preferred to introduce a thin interlayer of a material having a high dielectric constant between a metallic cathode and the organic semiconductor. Suitable for this purpose are, for example, alkali metal fluorides or alkaline-earth metal fluorides, but also the corresponding oxides or carbonates (for example LiF, Li₂O, BaF₂, MgO, NaF, CsF, Cs₂CO₃, etc.). Furthermore, lithium quinolinate (LiQ) can be used for this purpose. The layer thickness of this layer is preferably between 0.5 and 5 nm.

The anode preferably comprises materials having a high work function. The anode preferably has a work function of greater than 4.5 eV vs. vacuum. Suitable for this purpose are on the one hand metals having a high redox potential, such as, for example, Ag, Pt or Au. On the other hand, metal/metal oxide electrodes (for example Al/Ni/NiOₓ, Al/PtOₓ) may also be preferred. For some applications, at least one of the electrodes must be transparent or partially transparent in order to facilitate either irradiation of the organic material (organic solar cells) or the coupling-out of light (OLEDs, O-lasers). Preferred anode materials here are conductive mixed metal oxides. Particular preference is given to indium tin oxide (ITO) or indium zinc oxide (IZO). Preference is furthermore given to conductive, doped organic materials, in particular conductive, doped polymers.

The device is appropriately (depending on the application) structured, provided with contacts and finally sealed, since the lifetime of the devices according to the invention is shortened in the presence of water and/or air.

In a preferred embodiment, the organic electroluminescent device according to the invention is characterised in that one or more layers are coated by means of a sublimation process, in which the materials are applied by vapour deposition in vacuum sublimation units at an initial pressure of less than 10⁻⁵ mbar, preferably less than 10⁻⁶ mbar. However, it is also possible here for the initial pressure to be even lower, for example less than 10⁻⁷ mbar.

Preference is likewise given to an organic electroluminescent device, characterised in that one or more layers are coated by means of the OVPD (organic vapour phase deposition) process or with the aid of carrier-gas sublimation, in which the materials are applied at a pressure of between 10⁻⁵ mbar and 1 bar. A special case of this process is the OVJP (organic vapour jet printing) process, in which the materials are applied directly through a nozzle and are thus structured (for example M. S. Arnold et al., Appl. Phys. Lett. 2008, 92, 053301).

Preference is furthermore given to an organic electroluminescent device, characterised in that one or more layers are produced from solution, such as, for example, by spin coating, or by means of any desired printing process, such as, for example, screen printing, flexographic printing, nozzle printing or offset printing, but particularly preferably LITI (light induced thermal imaging, thermal transfer printing) or ink-jet printing. Soluble compounds of the formula (I) are necessary for this purpose. High solubility can be achieved through suitable substitution of the compounds.

For the production of an organic electroluminescent device according to the invention, it is furthermore preferred to apply one or more layers from solution and one or more layers by a sublimation process.

The organic electroluminescent devices comprising one or more compounds of the formula (I) can be employed in accordance with the invention in displays, as light sources in lighting applications and as light sources in medical and/or cosmetic applications (for example light therapy).

On use of the compounds of the formula (I) in organic electroluminescent devices, one or more of the advantages indicated below can be achieved:
The devices have a long lifetime.
The devices have high energy efficiency
The devices have a low operating voltage
The devices emit deep-blue light with high colour purity

On use of the compounds according to the invention in the emitting layer of the device, an extension of the lifetime and an improvement in the energy efficiency, in particular, is achieved compared with the pyrene derivatives known in the prior art.

The following working examples serve to illustrate the above-mentioned advantages and to illustrate the invention, without the subject-matter of the invention being restricted to the contents of the examples.

### USE EXAMPLES

### A) Synthesis Examples

### Example 1

### 7-tert-Butyl-N,N,N′,N′-tetraphenylpyrene-1,3-diamine

### a) 1,3-Dibromo-7-tert-butylpyrene

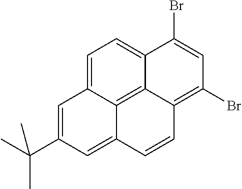 [SMILES: CC(C)(C)c1cc2ccc3c(Br)cc(Br)c4ccc(c1)c2c34]

100 g (495 mmol) of pyrene and 55.2 g (596 mmol) of tert-butyl chloride are initially introduced in 11 of dichloromethane at 0° C. 70.4 g (528 mmol) of AlCl₃ are subsequently added in portions. The reaction mixture is stirred at room temperature for 16 h. The reaction mixture is then poured into icewater, the organic phase is separated off, washed three times with 200 ml of water and subsequently evaporated to dryness. The residue 2-tert-butylpyrene is recrystallised from MeOH and from heptane. The yield of 2-tert-butylpyrene is 120 g (73%).

120 g (464.5 mmol) of 2-tert-butylpyrene are initially introduced in 1.5 l of dichloromethane. 21 ml (929 mmol) of Br₂ in 50 ml of dichloromethane are subsequently added dropwise at −78° C. with exclusion of light, and the mixture is stirred at this temperature for a further 2 h. After warming to room temperature, the precipitated solid is filtered off with suction and washed with heptane. The product is recrystallised from toluene. The yield of product is 97 g (50%), purity according to HPLC about 99.6%.

### b) 7-tert-Butyl-N,N,N′,N′-tetraphenylpyrene-1,3-diamine

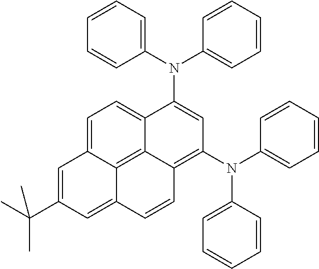 [SMILES: CC(C)(C)c1cc2ccc3c(N(c4ccccc4)c4ccccc4)cc(N(c4ccccc4)c4ccccc4)c4ccc(c1)c2c34]

20 g (48.06 mmol) of 1,3-dibromo-7-tert-butylpyrene, 17.9 g (105.7 mmol) of diphenylamine and 14.8 g of sodium tert-butoxide (153.8 mmol) are suspended in 500 ml of toluene. 270 mg (1.20 mmol) of Pd(OAc)₂ and 2.4 ml of a 1M tri-tert-butylphosphine solution are added to this suspension. The reaction mixture is heated under reflux for 2 h. After cooling, the organic phase is separated off, washed three times with 200 ml of water and subsequently evaporated to dryness. The residue is extracted with hot toluene, recrystallised from toluene and finally sublimed in a high vacuum. The purity is 99.9%.

The following compounds are prepared analogously to Example 1 based on step a) 1,3-dibromo-7-tert-butylpyrene:

### Example 2

### 7-tert-Butyl-N,N,N′,N′-tetra-p-tolylpyrene-1,3-diamine

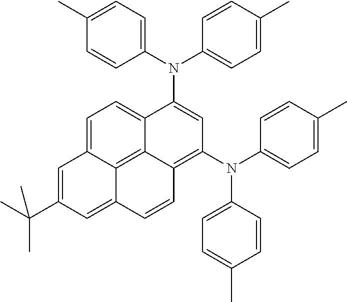 [SMILES: Cc1ccc(N(c2ccc(C)cc2)c2cc(N(c3ccc(C)cc3)c3ccc(C)cc3)c3ccc4cc(C(C)(C)C)cc5ccc2c3c54)cc1]

20 g (48.06 mmol) of 1,3-dibromo-7-tert-butylpyrene, 20.8 g (105.7 mmol) of di-p-tolylamine and 14.8 g of sodium tert-butoxide (153.8 mmol) are suspended in 500 ml of toluene. 270 mg (1.20 mmol) of Pd(OAc)₂ and 2.4 ml of a 1M tri-tert-butylphosphine solution are added to this suspension. The reaction mixture is heated under reflux for 2 h. After cooling, the organic phase is separated off, washed three times with 200 ml of water and subsequently evaporated to dryness. The residue is extracted with hot toluene, recrystallised from toluene and finally sublimed in a high vacuum. The purity is 99.9%.

### Example 3

### 7-tert-Butyl-N,N,N′,N′-tetrakis-(2,4-dimethylphenyl)pyrene-1,3-diamine

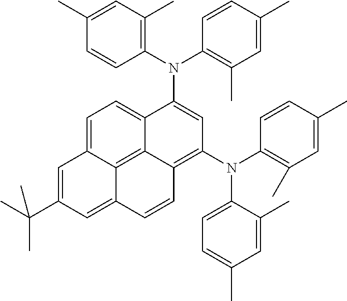 [SMILES: Cc1ccc(N(c2ccc(C)cc2C)c2cc(N(c3ccc(C)cc3C)c3ccc(C)cc3C)c3ccc4cc(C(C)(C)C)cc5ccc2c3c54)c(C)c1]

7.5 g (18.02 mmol) of 1,3-dibromo-7-tert-butylpyrene, 8.65 g (39.65 mmol) of bis-(2,4-dimethylphenyl)amine and 5.54 g of sodium tert-butoxide are suspended in 200 ml of toluene. 101 mg (0.45 mmol) of Pd(OAc)₂ and 0.90 ml of a 1M tri-tert-butylphosphine solution are added to this suspension. The reaction mixture is heated under reflux for 2 h. After cooling, the organic phase is separated off, washed three times with 100 ml of water and subsequently evaporated to dryness. The residue is extracted with hot toluene, recrystallised from toluene and finally sublimed in a high vacuum. The purity is 99.9%.

### Example 4

### 7-tert-Butyl-N,N′di-p-tolyl-N,N′-di-p-benzonitriledipyrene-1,3-diamine

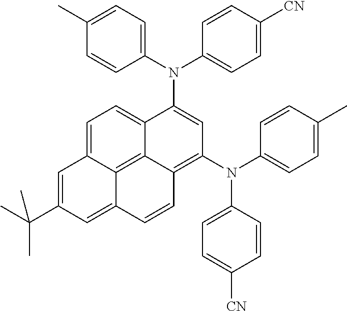 [SMILES: Cc1ccc(N(c2ccc(C#N)cc2)c2cc(N(c3ccc(C)cc3)c3ccc(C#N)cc3)c3ccc4cc(C(C)(C)C)cc5ccc2c3c54)cc1]

20 g (48.06 mmol) of 1,3-dibromo-7-tert-butylpyrene, 26.15 g (105.7 mmol) of 4-p-tolylaminobenzonitrile and 14.8 g of sodium tert-butoxide (153.8 mmol) are suspended in 500 ml of toluene. 270 mg (1.20 mmol) of Pd(OAc)₂ and 2.4 ml of a 1M tri-tert-butylphosphine solution are added to this suspension. The reaction mixture is heated under reflux for 2 h. After cooling, the organic phase is separated off, washed three times with 200 ml of water and subsequently evaporated to dryness. The residue is extracted with hot toluene, recrystallised from toluene and finally sublimed in a high vacuum. The purity is 99.9%.

### Example 5

### 7-tert-Butyl-1,3-bis-(4-diphenylphenylamine)

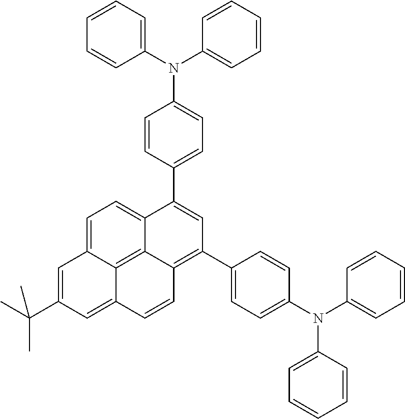 [SMILES: CC(C)(C)c1cc2ccc3c(-c4ccc(N(c5ccccc5)c5ccccc5)cc4)cc(-c4ccc(N(c5ccccc5)c5ccccc5)cc4)c4ccc(c1)c2c34]

20 g (48.06 mmol) of 1,3-dibromo-7-tert-butylpyrene, 26.15 g (105.7 mmol) of diphenyl-[4-(4,4,5,5-tetramethyl-1,3,2-dioxaborolan-2-yl)phenyl]amine and 37 ml of a 2N Na₂CO₃ solution are suspended in 500 ml of dimethoxyethane/dimethyl ether. 1.03 g (1.20 mmol) of Pd(PPh₃)₄ are added to this suspension. The reaction mixture is heated under reflux for 4 h. After cooling, the precipitated solid is filtered off with suction, washed with water and ethanol and dried. The residue is extracted with hot toluene, recrystallised from toluene and finally sublimed in a high vacuum. The product is obtained in a yield of 28.6 g (80%) and in a purity of 99.9%.

### Example 6

### 7-tert-Butyl-N,N′-bis-(2-fluoro-4-methylphenyl)-N,N′-di-p-tolylpyrene-1,3-diamine

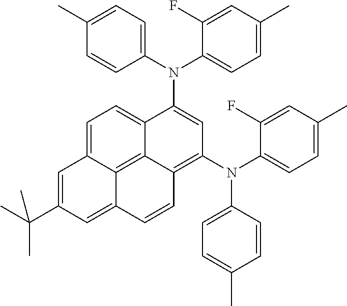 [SMILES: Cc1ccc(N(c2ccc(C)cc2F)c2cc(N(c3ccc(C)cc3)c3ccc(C)cc3F)c3ccc4cc(C(C)(C)C)cc5ccc2c3c54)cc1]

23 g (55.3 mmol) of 1,3-dibromo-7-tert-butylpyrene, 26.17 g (122 mmol) of (2-fluoro-4-methylphenyl)-p-tolylamine and 17.34 g of sodium tert-butoxide (176.9 mmol) are suspended in 800 ml of toluene. 310 mg (1.38 mmol) of Pd(OAc)₂ and 2.8 ml of a 1M tri-tert-butylphosphine solution are added to this suspension. The reaction mixture is heated under reflux for 2 h. After cooling, the organic phase is separated off, washed three times with 400 ml of water and subsequently evaporated to dryness. The residue is extracted with hot toluene, recrystallised from toluene and finally sublimed in a high vacuum. The purity is 99.9%.

### B) Device Examples

### Production of the OLEDs

OLEDs according to the invention and OLEDs in accordance with the prior art are produced by a general process in accordance with WO 04/058911, which is adapted to the circumstances described here (layer-thickness variation, materials).

In Examples V1 to V6 and E1 to E12 below (see Tables 1 and 2), the data for various OLEDs are presented. Glass plates coated with structured ITO (indium tin oxide) in a thickness of 150 nm are coated with 20 nm of PEDOT (poly(3,4-ethylenedioxy-2,5-thiophene), applied by spin coating from water; purchased from H. C. Starck, Goslar, Germany) for improved processing. These coated glass plates form the substrates to which the OLEDs are applied. The OLEDs basically have the following layer structure: substrate/optional hole-injection layer (HIL)/hole-transport layer (HTL)/optional interlayer (IL)/electron-blocking layer (EBL)/emission layer (EML)/optional hole-blocking layer (HBL)/electron-transport layer (ETL)/optional electron-injection layer and finally a cathode. The cathode is formed by an aluminium layer with a thickness of 100 nm. The precise structure of the OLEDs is shown in Table 1. The materials required for the production of the OLEDs are shown in Table 3.

All materials are applied by thermal vapour deposition in a vacuum chamber. The emission layer here always consists of at least one matrix material (host material) and an emitting dopant (emitter), to which the matrix material or materials is (are) admixed by co-evaporation in a certain proportion by volume. An expression such as H1(95%):SEBV1(5%) here means that the material SEBV1 is present in the layer in a proportion by volume of 5% and H1 is present in the layer in a proportion of 95%. Analogously, the electron-transport layer may also consist of a mixture of two materials.

The OLEDs are characterised by standard methods. To this end, the electroluminescence spectra, the current efficiency (measured in cd/A), the power efficiency (measured in Im/W) and the external quantum efficiency (EQE, measured in percent) as a function of the luminous density, calculated from current/voltage/luminous density characteristic lines (IUL characteristic lines), and the lifetime are determined. The electroluminescence spectra are determined at a luminous density of 1000 cd/m², and the CIE 1931 x and y colour coordinates are calculated therefrom. The lifetime LT70 @ 50 mA in Table 2 is defined as the time after which the luminous density has dropped to 70% on operation with constant current of 50 mA/cm². The values for the lifetime can be converted into a value for other initial luminous densities with the aid of conversion formulae known to the person skilled in the art.

The data for the various OLEDs are summarized in Table 2. Examples V1-V6 are comparative examples in accordance with the prior art, Examples E1-E12 show data of OLEDs comprising materials according to the invention.

Some of the examples are explained in greater detail below in order to illustrate the advantages of the compounds according to the invention. However, it should be pointed out that this only represents a selection of the data shown in Table 2. As revealed by the table, significant improvements compared with the prior art are also achieved on use of the compounds according to the invention which are not mentioned in greater detail, in some cases in all parameters, but in some cases only an improvement in efficiency or voltage or lifetime is observed. However, the improvement of one of the said parameters is already a significant advance, since various applications require optimisation with respect to different parameters.

Use of Compounds According to the Invention as Dopants in Fluorescent OLEDs

On use as dopants in OLEDs, the materials according to the invention give rise to significant improvements compared with the prior art in all parameters, especially with respect to lifetime and efficiency. Thus, devices E1 and E2 have a significantly extended lifetime compared with comparative device V1 at the same time as virtually the same colour, efficiency and the same operating voltage. Device E9 according to the invention has virtually the same colour, better efficiency and a longer lifetime compared with comparative device V5. Devices E5 and E6 according to the invention also have longer lifetimes than the comparative devices.

TABLE 1
Structure of the OLEDs

| | IL | HTL | EBL | EML | ETL | EIL |
|---|---|---|---|---|---|---|
| | Thickness/ | Thickness/ | Thickness/ | Thickness/ | Thickness/ | Thickness/ |
| Ex. | nm | nm | nm | nm | nm | nm |
| V1 | HIL1 | HTM1 | NPB | H1(95%):SEBV1(5%) | ETM1(50%):LiQ(50%) | |
| | 5 nm | 140 nm | 20 nm | 20 nm | 30 nm | |
| V2 | HIL1 | HTM1 | NPB | H1(95%):SEBV1(5%) | Alq | LiF |
| | 5 nm | 140 nm | 20 nm | 30 nm | 20 nm | 1 nm |
| V3 | HIL1 | HTM1 | NPB | H1(95%):SEBV2(5%) | ETM1(50%):LiQ(50%) | |
| | 5 nm | 140 nm | 20 nm | 20 nm | 30 nm | |
| V4 | HIL1 | HTM1 | NPB | H1(95%):SEBV2(5%) | Alq | LiF |
| | 5 nm | 140 nm | 20 nm | 30 nm | 20 nm | 1 nm |
| V5 | HIL1 | HTM1 | NPB | H1(95%):SEBV3(5%) | ETM1(50%):LiQ(50%) | |
| | 5 nm | 140 nm | 20 nm | 20 nm | 30 nm | |
| V6 | HIL1 | HTM1 | NPB | H1(95%):SEBV4(5%) | ETM1(50%):LiQ(50%) | |
| | 5 nm | 140 nm | 20 nm | 20 nm | 30 nm | |
| E1 | HIL1 | HTM1 | NPB | H1(95%):SEB1(5%) | ETM1(50%):LiQ(50%) | |
| | 5 nm | 140 nm | 20 nm | 20 nm | 30 nm | |
| E2 | HIL1 | HTM1 | NPB | H1(95%):SEB1(3%) | ETM1(50%):LiQ(50%) | |
| | 5 nm | 140 nm | 20 nm | 20 nm | 30 nm | |
| E3 | HIL1 | HTM1 | NPB | H1(95%):SEB1(1%) | ETM1(50%):LiQ(50%) | |
| | 5 nm | 140 nm | 20 nm | 20 nm | 30 nm | |
| E4 | HIL1 | HTM1 | NPB | H1(95%):SEB1(5%) | Alq | LiF |
| | 5 nm | 140 nm | 20 nm | 20 nm | 20 nm | 1 nm |
| E5 | HIL1 | HTM1 | NPB | H1(95%):SEB2(5%) | ETM1(50%):LiQ(50%) | |
| | 5 nm | 140 nm | 20 nm | 20 nm | 30 nm | |
| E6 | HIL1 | HTM1 | NPB | H1(95%):SEB2(3%) | ETM1(50%):LiQ(50%) | |
| | 5 nm | 140 nm | 20 nm | 20 nm | 30 nm | |
| E7 | HIL1 | HTM1 | NPB | H1(95%):SEB2(1%) | ETM1(50%):LiQ(50%) | |
| | 5 nm | 140 nm | 20 nm | 20 nm | 30 nm | |
| E8 | HIL1 | HTM1 | NPB | H1(95%):SEB2(5%) | Alq | LiF |
| | 5 nm | 140 nm | 20 nm | 20 nm | 20 nm | 1 nm |
| E9 | HIL1 | HTM1 | NPB | H1(95%):SEB3(5%) | ETM1(50%):LiQ(50%) | |
| | 5 nm | 140 nm | 20 nm | 20 nm | 30 nm | |
| E10 | HIL1 | HTM1 | NPB | H1(95%):SEB3(3%) | ETM1(50%):LiQ(50%) | |
| | 5 nm | 140 nm | 20 nm | 20 nm | 30 nm | |
| E11 | HIL1 | HTM1 | NPB | H1(95%):SEB3(1%) | ETM1(50%):LiQ(50%) | |
| | 5 nm | 140 nm | 20 nm | 20 nm | 30 nm | |
| E12 | HIL1 | HTM1 | NPB | H1(95%):SEB3(5%) | Alq | LiF |
| | 5 nm | 140 nm | 20 nm | 20 nm | 20 nm | 1 nm |

TABLE 2
Data of the OLEDs

| | Quantum | | | | |
|---|---|---|---|---|---|
| | efficiency | Voltage | CIE | | LT70 |
| | @ 1000 cd/m2 | @ 1000 cd/m2 | @ 1000 cd/m² | | @ 50 mA/cm² |
| Ex. | % | [V] | x | y | [h] |
| V1 | 5.9% | 4.7 | 0.144 | 0.126 | 50 |
| V2 | 3.5% | 6.4 | 0.149 | 0.131 | 75 |
| V3 | 5.3% | 4.4 | 0.105 | 0.220 | 35 |
| V4 | 3.4% | 6.2 | 0.106 | 0.241 | 40 |
| V5 | 5.2% | 4.6 | 0.131 | 0.169 | 35 |
| V6 | 5.4% | 5.0 | 0.171 | 0.110 | 35 |
| E1 | 5.6% | 4.6 | 0.137 | 0.135 | 90 |
| E2 | 5.2% | 4.7 | 0.138 | 0.128 | 90 |
| E3 | 5.3% | 4.9 | 0.139 | 0.109 | 80 |
| E4 | 3.7% | 6.3 | 0.141 | 0.140 | 110 |
| E5 | 5.6% | 4.7 | 0.129 | 0.199 | 55 |
| E6 | 5.5% | 4.6 | 0.130 | 0.186 | 55 |
| E7 | 5.1% | 4.6 | 0.131 | 0.160 | 50 |
| E8 | 3.6% | 6.2 | 0.128 | 0.202 | 80 |
| E9 | 5.7% | 4.7 | 0.132 | 0.168 | 55 |
| E10 | 5.5% | 4.7 | 0.133 | 0.157 | 55 |
| E11 | 5.2% | 4.8 | 0.133 | 0.132 | 50 |
| E12 | 3.8% | 6.4 | 0.134 | 0.172 | 70 |

TABLE 3
Structural formulae of the materials for the OLEDs
Structures of the materials used

| | |
|---|---|
| 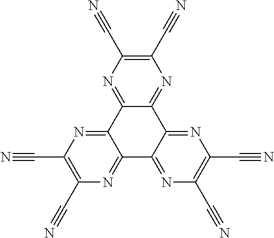 [SMILES: N#Cc1nc2c3nc(C#N)c(C#N)nc3c3nc(C#N)c(C#N)nc3c2nc1C#N] | 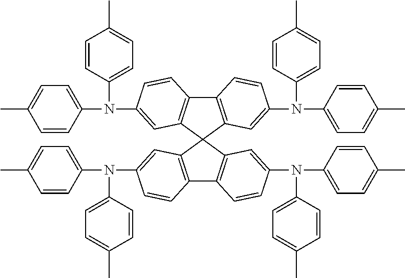 |
| HIL1 | HT 1 |
| 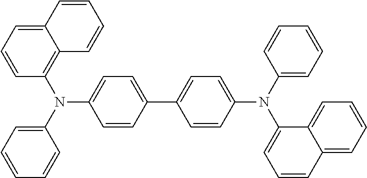 [SMILES: c1ccc(N(c2ccc(-c3ccc(N(c4ccccc4)c4cccc5ccccc45)cc3)cc2)c2cccc3ccccc23)cc1] | 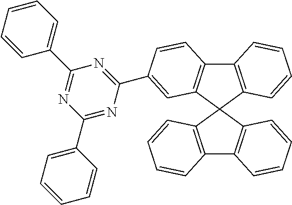 [SMILES: c1ccc(-c2nc(-c3ccccc3)nc(-c3ccc4c(c3)C3(c5ccccc5-c5ccccc53)c3ccccc3-4)n2)cc1] |
| NPB | ETM |
| 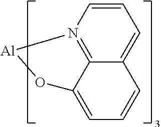 | 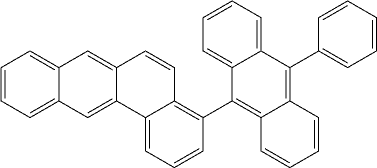 [SMILES: c1ccc(-c2c3ccccc3c(-c3cccc4c3ccc3cc5ccccc5cc34)c3ccccc23)cc1] |
| Alq₃ | H1 |
| 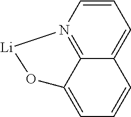 | 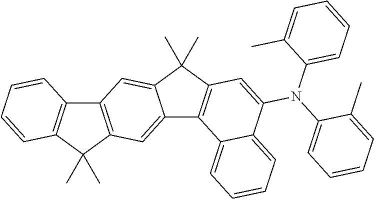 [SMILES: Cc1ccccc1N(c1ccccc1C)c1cc2c(c3ccccc13)-c1cc3c(cc1C2(C)C)-c1ccccc1C3(C)C] |
| LiQ | SEBV |
| 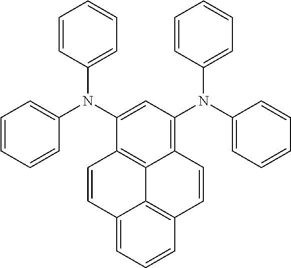 [SMILES: c1ccc(N(c2ccccc2)c2cc(N(c3ccccc3)c3ccccc3)c3ccc4cccc5ccc2c3c54)cc1] | 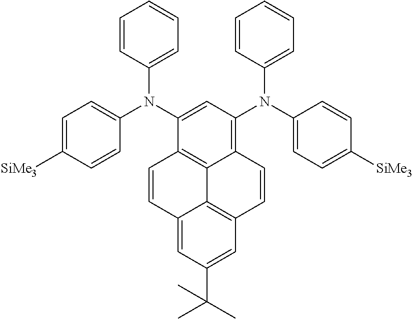 [SMILES: CC(C)(C)c1cc2ccc3c(N(c4ccccc4)c4ccc([Si](C)(C)C)cc4)cc(N(c4ccccc4)c4ccc([Si](C)(C)C)cc4)c4ccc(c1)c2c34] |
| SEBV | SEBV |
| 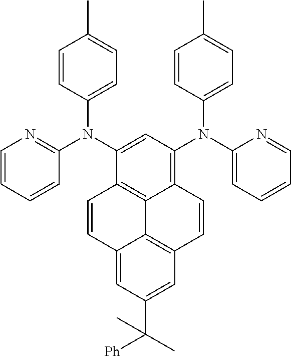 [SMILES: Cc1ccc(N(c2ccccn2)c2cc(N(c3ccc(C)cc3)c3ccccn3)c3ccc4cc(C(C)(C)c5ccccc5)cc5ccc2c3c54)cc1] | 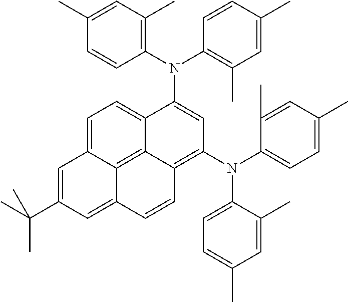 [SMILES: Cc1ccc(N(c2ccc(C)cc2C)c2cc(N(c3ccc(C)cc3C)c3ccc(C)cc3C)c3ccc4cc(C(C)(C)C)cc5ccc2c3c54)c(C)c1] |
| SEBV | SEB |
| 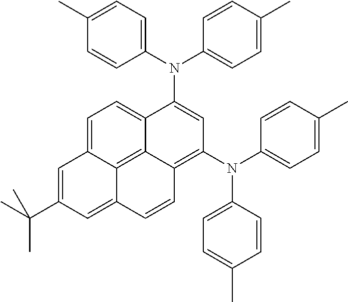 [SMILES: Cc1ccc(N(c2ccc(C)cc2)c2cc(N(c3ccc(C)cc3)c3ccc(C)cc3)c3ccc4cc(C(C)(C)C)cc5ccc2c3c54)cc1] | 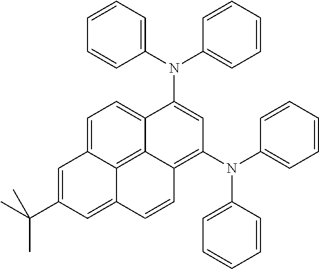 [SMILES: CC(C)(C)c1cc2ccc3c(N(c4ccccc4)c4ccccc4)cc(N(c4ccccc4)c4ccccc4)c4ccc(c1)c2c34] |
| SEB | SEB |

1-14. (canceled)

15. A compound of the formula (I), 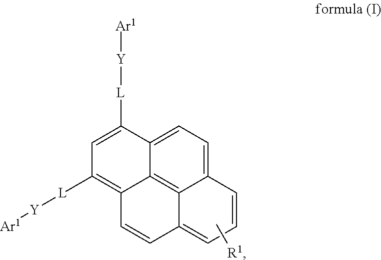
where the following applies to the symbols occurring:
Y is on each occurrence, identically or differently, —N(Ar¹)—, —P(Ar¹)—, —P(═O)(Ar¹)—, —S—, —S(═O)— or —S(═O)₂—;
L is on each occurrence, identically or differently, a single bond or a group Ar²;
Ar¹ is on each occurrence, identically or differently, an aromatic ring system having 6 to 30 aromatic ring atoms or a heteroaromatic ring system having 5 to 30 aromatic ring atoms, which is optionally substituted by one or more radicals R², where two groups Ar¹ which are bonded to the same group Y is optionally connected to one another via a single bond or a divalent group selected from —C(R²)₂—, —R²C═CR², —Si(R²)₂—, —C(═O)—, —C(═NR²)—, —O—, —S— or —NR²—, and where the groups Ar¹ are not substituted by a radical containing B, Si, Ge or P, and where furthermore Ar¹ does not represent a heteroaryl group containing one or more nitrogen atoms in the aromatic ring;
Ar² is on each occurrence, identically or differently, an aromatic ring system having 6 to 30 aromatic ring atoms, which is optionally substituted by one or more radicals R², or a heteroaromatic ring system having 5 to 30 aromatic ring atoms, which is optionally substituted by one or more radicals R²;
R¹ is on each occurrence, identically or differently, F, D, C(═O)R³, CN, Si(R³)₃, N(R³)₂, NO₂, a straight-chain alkyl or alkoxy group having 1 to 20 C atoms or a branched or cyclic alkyl or alkoxy group having 3 to 20 C atoms or an alkenyl or alkynyl group having 2 to 20 C atoms, where the above-mentioned groups may each be substituted by one or more radicals R³ and where one or more adjacent or non-adjacent CH₂ groups in the above-mentioned groups is optionally replaced by Si(R³)₂, C═O, C═NR³, —C(═O)O—, —C(═O)NR³—, NR³, —O—, —S—, SO or SO₂ and where one or more H atoms in the above-mentioned groups is optionally replaced by D, F, Cl, Br, I, CN or NO₂, or an aryl group having 6 to 20 aromatic ring atoms, which is optionally substituted by one or more radicals R³, or a heteroaryl group having 5 to 20 aromatic ring atoms, which is optionally substituted by one or more radicals R³, where R¹ is bonded at one or more of positions 6, 7 and 8 of the pyrene and where 1, 2 or 3 groups R¹ are present, and where furthermore, for R¹═N(R³)₂, this radical R¹ cannot be bonded at one or more of the two positions 6 and 8 of the pyrene;
R² is on each occurrence, identically or differently, H, D, F, Cl, Br, I, B(OR³)₂, CHO, C(═O)R³, CR³═C(R³)₂, CN, C(═O)OR³, C(═O)N(R³)₂, Si(R³)₃, N(R³)₂, NO₂, P(═O)(R³)₂, OSO₂R³, OR³, S(═O)R³, S(═O)₂R³, a straight-chain alkyl, alkoxy or thioalkyl group having 1 to 20 C atoms or a branched or cyclic alkyl, alkoxy or thioalkyl group having 3 to 20 C atoms or an alkenyl or alkynyl group having 2 to 20 C atoms, where the above-mentioned groups may each be substituted by one or more radicals R³ and where one or more adjacent or non-adjacent CH₂ groups in the above-mentioned groups is optionally replaced by —R³C═CR³—, —C≡C—, Si(R³)₂, Ge(R³)₂, Sn(R³)₂, C═O, C═S, C═Se, C═NR³, —C(═O)O—, —C(═O)NR³—, NR³, P(═O)(R³), —O—, —S—, SO or SO₂ and where one or more H atoms in the above-mentioned groups is optionally replaced by D, F, Cl, Br, I, CN or NO₂, or an aromatic or heteroaromatic ring system having 5 to 60 aromatic ring atoms, which may in each case be substituted by one or more radicals R³, or an aryloxy or heteroaryloxy group having 5 to 60 aromatic ring atoms, which is optionally substituted by one or more radicals R³, where two or more radicals R² is optionally linked to one another and may form an aliphatic, heteroaliphatic, aromatic or heteroaromatic ring;
R³ is on each occurrence, identically or differently, H, D, F, Cl, Br, I, B(OR⁴)₂, CHO, C(═O)R⁴, CR⁴═C(R⁴)₂, CN, C(═O)OR⁴, C(═O)N(R⁴)₂, Si(R⁴)₃, N(R⁴)₂, NO₂, P(═O)(R⁴)₂, OSO₂R⁴, OR⁴, S(═O)R⁴, S(═O)₂R⁴, a straight-chain alkyl, alkoxy or thioalkyl group having 1 to 20 C atoms or a branched or cyclic alkyl, alkoxy or thioalkyl group having 3 to 20 C atoms or an alkenyl or alkynyl group having 2 to 20 C atoms, where the above-mentioned groups may each be substituted by one or more radicals R⁴ and where one or more adjacent or non-adjacent CH₂ groups in the above-mentioned groups is optionally replaced by —R⁴C═CR⁴—, —C≡C—, Si(R⁴)₂, Ge(R⁴)₂, Sn(R⁴)₂, C═O, C═S, C═Se, C═NR⁴, —C(═O)O—, —C(═O)NR⁴—, NR⁴, P(═O)(R⁴), —O—, —S—, SO or SO₂ and where one or more H atoms in the above-mentioned groups is optionally replaced by D, F, Cl, Br, I, CN or NO₂, or an aromatic or heteroaromatic ring system having 5 to 60 aromatic ring atoms, which may in each case be substituted by one or more radicals R⁴, or an aryloxy or heteroaryloxy group having 5 to 60 aromatic ring atoms, which is optionally substituted by one or more radicals R⁴, where two or more radicals R³ is optionally linked to one another and may form an aliphatic, heteroaliphatic, aromatic or heteroaromatic ring;
R⁴ is on each occurrence, identically or differently, H, D, F or an aliphatic, aromatic and/or heteroaromatic organic radical having 1 to 20 C atoms, in which, in addition, one or more H atoms is optionally replaced by D or F; two or more substituents R⁴ here may also be linked to one another and form an aliphatic, heteroaliphatic, aromatic or heteroaromatic ring;
where furthermore the pyrene is optionally substituted at all free positions by one or more radicals R².

16. The compound according to claim 15, wherein the group Y is selected on each occurrence, identically or differently, from —N(Ar¹)— and —P(Ar¹)—.

17. The compound according to claim 15, wherein Ar¹ represents an aromatic ring system having 6 to 20 aromatic ring atoms, which is optionally substituted by one or more radicals R², where two groups Ar¹ which are bonded to the same group Y is optionally connected to one another via a single bond or a divalent group selected from —C(R²)₂—, —C(═O)—, —O—, —S— or —NR²—, and where furthermore Ar¹ is not substituted by a radical containing B, Si, Ge or P.

18. The compound according to claim 15, wherein a group R¹ is bonded in the 7-position on the pyrene.

19. The compound according to claim 15, wherein R¹ is selected on each occurrence, identically or differently, from a straight-chain alkyl group having 1 to 10 C atoms or a branched or cyclic alkyl group having 3 to 10 C atoms, where the above-mentioned groups may each be substituted by one or more radicals R³ and where one or more adjacent or non-adjacent CH₂ groups in the above-mentioned groups is optionally replaced by C═O, —C(═O)O—, —C(═O)NR³—, NR³, —O— or —S— and where one or more H atoms in the above-mentioned groups is optionally replaced by D, F or CN, or an aryl group having 6 to 10 aromatic ring atoms, which is optionally substituted by one or more radicals R³.

20. The compound according to claim 15, wherein Ar² is selected from divalent groups of the following formulae Ar²-1 to Ar²-19 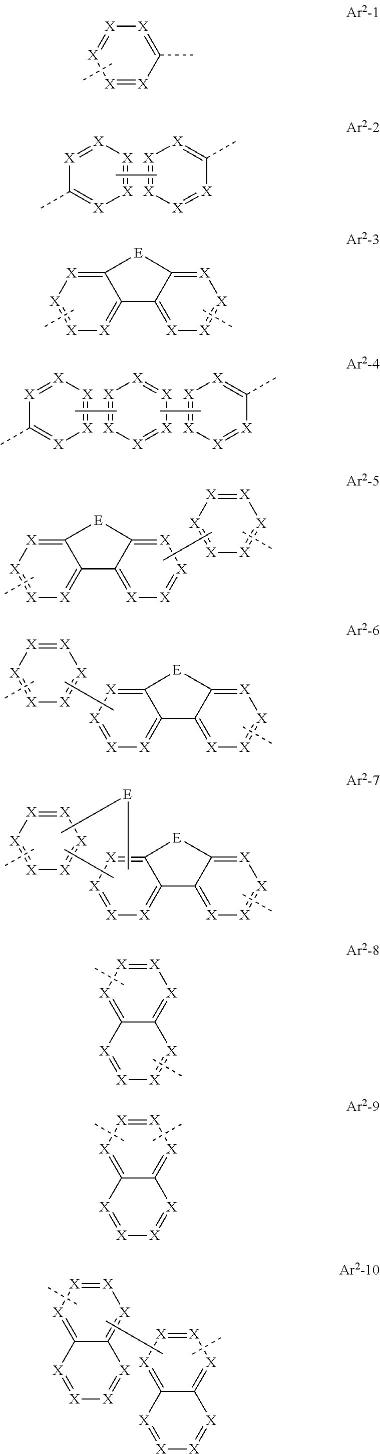 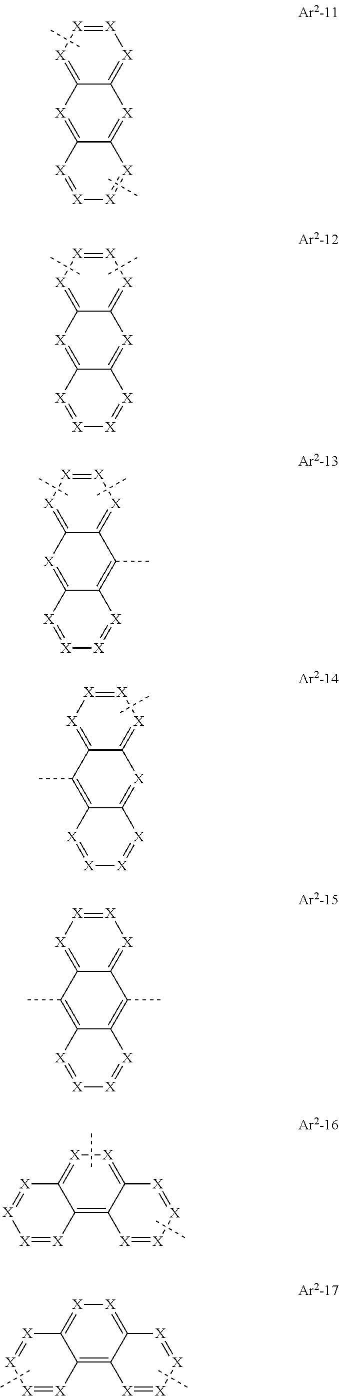 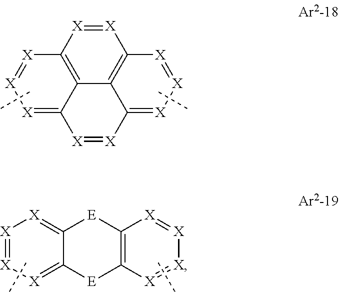
where
X is on each occurrence, identically or differently, CR² or N if no dashed or continuous line or a group E is bonded at the relevant position and is equal to C if a dashed or continuous line or a group E is bonded at the relevant position;
E is on each occurrence, identically or differently, a divalent group selected from —C(R²)₂—, —R²C═CR²—, —Si(R²)₂—, —C(═O)—, —O—, —S—, —S(═O)—, —S(═O)₂— and —NR²—;
where R² is as defined in claim 15;
and where the two bonds to the group Y and to the pyrene are represented by the two dashed lines, and where the left-hand dashed line denotes the bond from the group Ar² to the pyrene and the right-hand dashed line denotes the bond from the group Ar² to the group Y.

21. The compound according to claim 15, wherein the compound of the formula (I) conforms to one of the following formulae (I-1) to (I-10) 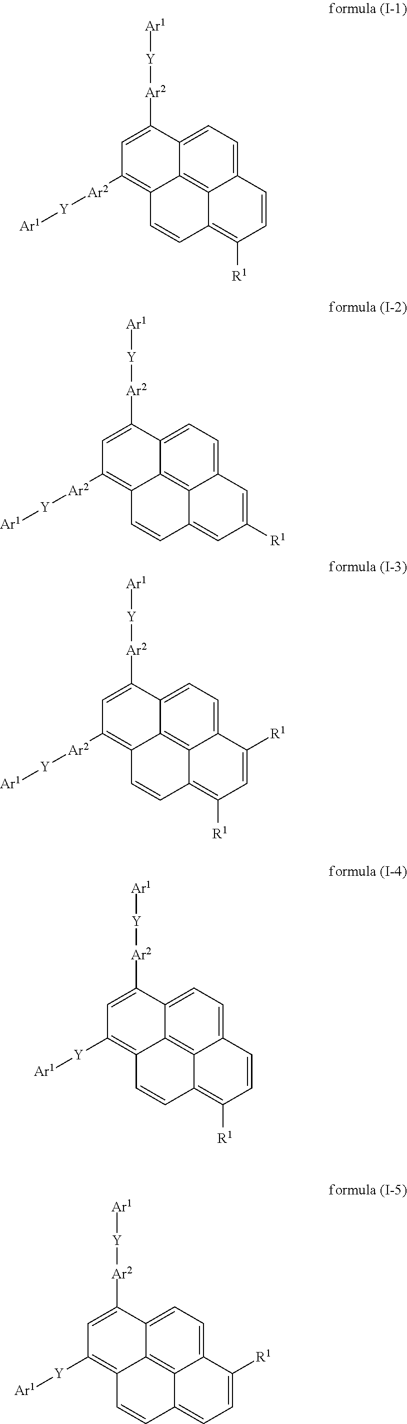 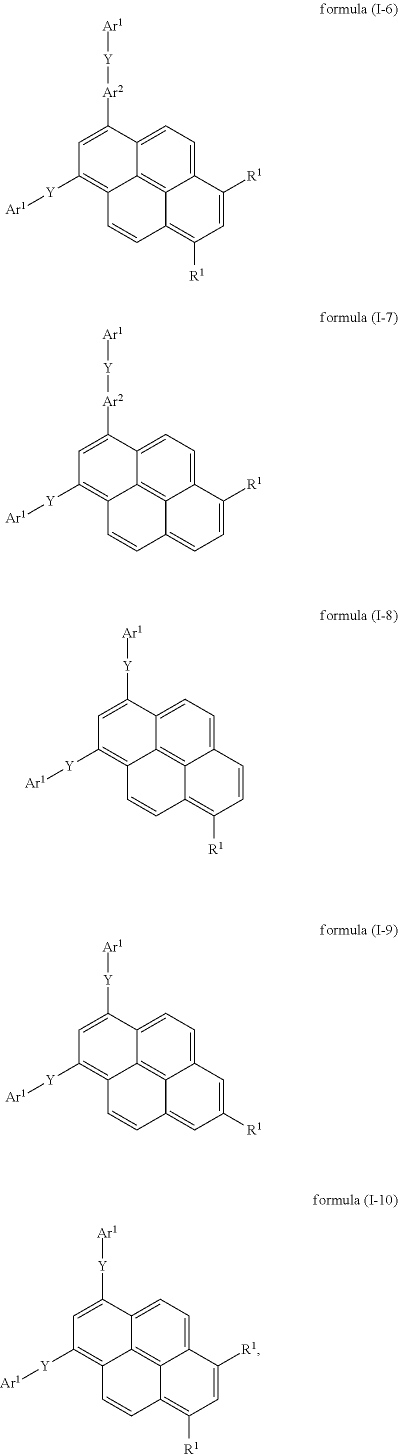
where the symbols occurring are as defined in claim 15 and furthermore the pyrene is optionally substituted at all free positions by one or more radicals R².

22. A process for the preparation of the compound according to claim 15, which comprises introducing one or more aryl and/or acylamino groups on the pyrene skeleton by means of organometallic coupling reaction.

23. An oligomer, polymer or dendrimer comprising one or more compounds according to claim 15, where the bond(s) to the polymer, oligomer or dendrimer is optionally localised at any position in formula (I) which are substituted by R².

24. A formulation comprising at least one compound of the formula (I) according to claim 15 and at least one solvent.

25. A formulation comprising at least one oligomer, polymer or dendrimer according to claim 23 and at least one solvent.

26. An electronic device comprising at least one compound according to claim 15.

27. An electronic device comprising at least one polymer, oligomer or dendrimer according to claim 23.

28. The electronic device according to claim 26, wherein the device is an organic integrated circuit, an organic field-effect transistor, an organic thin-film transistor, an organic light-emitting transistor, an organic solar cell, an organic optical detector, an organic photoreceptor, an organic field-quench device, a light-emitting electrochemical cell, an organic laser diode or an organic electroluminescent device.

29. An electronic device which comprises the compound according to claim 15 is employed as emitter material in an emitting layer and/or is employed as matrix material in an emitting layer and/or is employed as hole-transport material in a hole-transport layer and/or a hole-injection layer.

30. An electronic device which comprises the polymer, oligomer or dendrimer according to claim 23 is employed as emitter material in an emitting layer and/or is employed as matrix material in an emitting layer and/or is employed as hole-transport material in a hole-transport layer and/or a hole-injection layer.
